(19) United States
(12) Patent Application Publication
(10) Pub. No.: US 2025/0348001 A1
(43) Pub. Date: Nov. 13, 2025

(54) METHOD FOR PRODUCING LAMINATE AND METHOD FOR PRODUCING SEMICONDUCTOR ELEMENT

(71) Applicant: NISSAN CHEMICAL CORPORATION, Tokyo (JP)

(72) Inventors: Wataru SHIBAYAMA, Toyama (JP); Shuhei SHIGAKI, Toyama (JP); Satoshi TAKEDA, Toyama (JP); Yuki FURUKAWA, Toyama (JP); Taiki SAIJO, Toyama (JP)

(73) Assignee: NISSAN CHEMICAL CORPORATION, Tokyo (JP)

(21) Appl. No.: 18/880,972

(22) PCT Filed: Jul. 4, 2023
(86) PCT No.: PCT/JP2023/024742

§ 371 Date: Jan. 3, 2025

(30) Foreign Application Priority Data
Jul. 6, 2022 (JP) 2022-109245
Feb. 7, 2023 (JP) 2023-016655

(51) Int. Cl. G03F 7/075; G03F 7/004; G03F 7/11; G03F 7/16; G03F 7/20; H01L 21/027

(52) U.S. Cl. CPC G03F 7/0757; G03F 7/0048; G03F 7/0752; G03F 7/11; G03F 7/162; G03F 7/2004; G03F 7/2059; H01L 21/0274; H01L 21/0279

(57) ABSTRACT

A method for producing a laminate having a surface-modified layer and a semiconductor substrate includes: a first step of applying a surface modifier containing a polymer and a solvent to the semiconductor substrate, and then baking the semiconductor substrate to cross-link the polymer and to form a surface-modified layer precursor; and a second step of bringing the surface-modified layer precursor into contact with a thinning liquid to thin the surface-modified layer precursor and to form a surface-modified layer having a film thickness of 5 nm or less.

### TECHNICAL FIELD

The present invention relates to a method for producing a laminate, and preferably relates to a method for producing a laminate on which a resist pattern is formed. The present invention also relates to a method for producing a semiconductor element.

### BACKGROUND ART

In the related art, a lithography process using a resist composition has been performed in the production of semiconductor devices. The degree of integration of semiconductor devices is recently increased, and thus there is a need to miniaturize patterns of wiring or the like. With the miniaturization of patterns, light sources such as far-ultraviolet rays, vacuum ultraviolet rays, electron beams (EB), and X-rays, which have shorter wavelengths, have come to be used. In particular, short-wavelength light such as a KrF excimer laser (wavelength: 248 nm) or an ArF excimer laser (wavelength: 193 nm) has been recently adopted to form a resist pattern.

Along with this, the influence of irregular reflection of active rays from a semiconductor substrate and standing wave becomes a major problem. In order to solve this problem, a method of providing a bottom anti-reflective coating (BARC) between a resist and a semiconductor substrate has been widely studied. In respect of such an anti-reflective coating, many studies have been conducted on an organic anti-reflective coating formed from a composition containing a polymer having a light-absorbing group (chromophore) from the viewpoint of easy use and the like (e.g. Patent Literature 1).

Meanwhile, in respect of extreme ultraviolet rays (EUV, wavelength: 13.5 nm) and electron beams used for the microfabrication technique, there is no problem associated with the reflection from the semiconductor substrate, but there is a problem of resist pattern collapse due to pattern miniaturization. Consequently, a resist underlayer film having high adhesion with a resist has been studied.

### CITATION LIST

### Patent Literature

Patent Literature 1: JP 2008-501985 A

### SUMMARY OF INVENTION

### Technical Problem

A known resist underlayer film has a problem that etching defects such as side etching in an etching step are likely to occur. Therefore, in a case where the substrate surface can be modified with a surface-modified layer having a thin film thickness as compared with the known underlayer film, it can be expected that the adhesion of the photoresist is improved and the photoresist resolution in the advanced lithography process is improved without causing etching defects such as side etching.

However, it is not easy to uniformly form a thin surface-modified layer.

The present invention has been made in view of such circumstances, and the followings are required: a method for producing a laminate capable of forming a thin surface-modified layer; a method for producing a semiconductor element using the production method; and a laminate having a thin surface-modified layer.

### Solution to Problem

As a result of intensive studies to solve the above problem, the present inventors have found that the above problem can be solved, thereby completing the present invention having the following gist.

That is, the present invention includes the followings.

[1]A method for producing a laminate having a surface-modified layer and a semiconductor substrate, the method including:
a first step of applying a surface modifier containing a polymer and a solvent to the semiconductor substrate, and then baking the semiconductor substrate to cross-link the polymer and to form a surface-modified layer precursor; and
a second step of bringing the surface-modified layer precursor into contact with a thinning liquid to thin the surface-modified layer precursor and to form a surface-modified layer having a film thickness of 5 nm or less.

[2] The method for producing a laminate according to [1], wherein the polymer is a polysiloxane.

[3] The method for producing a laminate according to [2], wherein the polysiloxane contains a modified polysiloxane in which at least some of silanol groups are alcohol-modified or acetal-protected.

[4] The method for producing a laminate according to [2] or [3], wherein the polysiloxane contains at least one structure selected from a hydrocarbon group having 1 to 8 carbon atoms optionally substituted with a halogen atom, an aromatic ring having 6 to 30 carbon atoms optionally substituted with a halogen atom, an alkenyl group, an alkynyl group, a norbornene ring, a phenol group, a protected phenol group, an amino group, an amide group, a cyclic amide group, an imide group, a cyclic imide group, a sulfonyl group, a sulfonamide group, a nitro group, a cyano group, a thiocyanate group, an isocyanate group, a halogen group, a carboxylic acid group, a carboxylic acid ester group, a sulfonic acid group, a sulfonic acid ester group, a phosphoric acid group, a phosphoric acid ester group, an ammonium group, a phosphonium group, a sulfonium group, an epoxy group, a glycidoxy group, a cyclohexylepoxy group, a ring-opened epoxy group, a ring-opened glycidoxy group, a ring-opened cyclohexylepoxy group, a hydroxy group, a mercapto group, an acryloyloxy group, or a methacryloyloxy group.

[5] The method for producing a laminate according to [2] or [3], wherein the polysiloxane contains a group bonded to a silicon atom and having an ionic bond.

[6] The method for producing a laminate according to [5], wherein
the group having an ionic bond has an anionic group which is a group bonded to a silicon atom and a cation,
an anion in the anionic group is a sulfonate anion, a carboxylate anion, or a phosphate anion, and
the cation is a sulfonium cation, an iodonium cation, a phosphonium cation, a dihydroimidazole cation, or an ammonium cation.

[7] The method for producing a laminate according to [5], wherein
the group having an ionic bond has a cationic group which is a group bonded to a silicon atom and an anion,
a cation in the cationic group is a sulfonium cation, an iodonium cation, a phosphonium cation, a dihydroimidazole cation, or an ammonium cation, and
the anion is a sulfonate anion, a carboxylate anion, or a phosphate anion.

[8] The method for producing a laminate according to any one of [2] to [7], wherein the polysiloxane contains a Q unit.

[9] The method for producing a laminate according to any one of [1] to [8], wherein the solvent contains at least one selected from the group consisting of alcohols, alkylene glycol alkyl ethers, alkylene glycol monoalkyl ether carboxylic acid esters, and water.

[10] The method for producing a laminate according to any one of [1] to [9], wherein the surface modifier contains an acid.

[11] The method for producing a laminate according to any one of [1] to [10], wherein the surface modifier contains an acid generator.

[12] The method for producing a laminate according to any one of [1] to [11], wherein the thinning liquid is at least one selected from the group consisting of an organic solvent, water, an acidic solution, an alkaline aqueous solution, and a thinner used in a reducing resist consumption (RRC) step or an edge bead removing (EBR) step.

[13] The method for producing a laminate according to any one of [1] to [12], wherein the semiconductor substrate is a substrate of an inorganic or organic material or a substrate having a film of an inorganic or organic material.

[14] The method for producing a laminate according to [13], wherein the inorganic material is at least one selected from the group consisting of a metal, a metal oxide, a metal nitride, a metal carbide, a metal oxynitride, a metal oxycarbide, and a metal carbonitride.

[15] The method for producing a laminate according to [13], wherein the organic material is at least one selected from the group consisting of amorphous carbon, graphite, fullerene, carbon nanotube, diamond, diamond-like carbon, polyimide, and an organic film in which any one of them is doped or partially substituted with boron, oxygen, nitrogen, phosphorus, silicon, sulfur, or halogen.

[16] The method for producing a laminate according to any one of [1] to [15], wherein the laminate further includes a silicon-containing resist underlayer film.

[17] The method for producing a laminate according to any one of [1] to [16], wherein the second step is a step of spin-coating the surface-modified layer precursor with a thinning liquid to thin the surface-modified layer precursor and to form a surface-modified layer having a film thickness of 5 nm or less.

[18] The method for producing a laminate according to any one of [1] to [17], wherein the second step is a step of thinning the surface-modified layer precursor together with an RRC step or an EBR step to form a surface-modified layer having a film thickness of 5 nm or less.

[19] The method for producing a laminate according to any one of [1] to [18], wherein the laminate is used in EUV lithography or electron beam lithography.

[20]A method for producing a semiconductor element, including the steps of:
forming a resist film on the laminate formed by the method for producing a laminate according to any one of [1] to [19]; and
exposing and developing the resist film to form a resist pattern.

[21]A laminate including: a semiconductor substrate; and a surface-modified layer containing a cross-linked polymer and having a film thickness of 5 nm or less.

[22] The laminate according to [21], which is used in EUV lithography or electron beam lithography.

[23] The laminate according to [21] or [22], wherein the polymer is a polysiloxane.

[24] The laminate according to [23], wherein the polysiloxane contains a Q unit.

[25]A surface modifier including: a polymer; and a solvent, wherein
the surface modifier is used in the method for producing a laminate according to any one of [1] to [19].

### Advantageous Effects of Invention

According to the present invention, it is possible to provide a method for producing a laminate capable of forming a thin surface-modified layer, a method for producing a semiconductor element using the production method, and a laminate having a thin surface-modified layer.

### DESCRIPTION OF EMBODIMENTS

### (Method for Producing Laminate and Laminate)

The method for producing a laminate of the present invention includes a first step and a second step. The method for producing a laminate of the present invention may further include additional steps.

The first step is a step of applying a surface modifier containing a polymer and a solvent to a semiconductor substrate, and then baking the surface modifier to crosslink the polymer and to form a surface-modified layer precursor.

The second step is a step of bringing the surface-modified layer precursor into contact with a thinning liquid to thin the surface-modified layer precursor and to form a surface-modified layer having a film thickness of 5 nm or less.

The substrate is coated with the surface modifier containing a polymer and a solvent and then baked, and thus a film having a cross-linked polymer is formed. However, it is not easy to form a thin film (e.g. a film having a film thickness of 5 nm or less) without film defects such as pinholes and non-uniformity in application only by this step, and it is necessary to sufficiently control application conditions, baking conditions, and the like.

As a result of intensive studies on the method for producing a laminate capable of forming a thin surface-modified layer, the present inventors have found that a thin surface-modified layer can be formed by a first step of forming a layer (surface-modified layer precursor) having a film thickness thicker than a target film thickness and a second step of bringing the layer into contact with a thinning liquid to thin the layer, and have completed the present invention.

Cross-linking of the polymer in the first step makes it possible to prevent the surface-modified layer precursor from being excessively dissolved in the thinning liquid in the second step.

A laminate formed by the method for producing a laminate of the present invention includes a surface-modified layer and a semiconductor substrate.

The laminate of the present invention includes a semiconductor substrate and a surface-modified layer having a film thickness of 5 nm or less. The surface-modified layer contains a cross-linked polymer.

The laminate of the present invention is formed, for example, by the method for producing a laminate of the present invention.

The laminate formed by the method for producing a laminate of the present invention and the laminate of the present invention are suitably used in EUV (extreme ultraviolet, wavelength: 13.5 nm) lithography or electron beam lithography.

The laminate formed by the method for producing a laminate of the present invention and the laminate of the present invention may further have another layer or another film. The other layer is, for example, a silicon-containing resist underlayer film. The silicon-containing resist underlayer film is not particularly limited as long as it is a silicon-containing resist underlayer film used in a lithography process.

In the present invention, there is no clear distinction between the film and the layer.

The film thickness of the surface-modified layer is 5 nm or less, preferably 3 nm or less. The lower limit of the film thickness of the surface-modified layer is not particularly limited, and the film thickness of the surface-modified layer may be 0.1 nm or more or 0.2 nm or more.

In the present invention, the film thickness is measured as described below.

The film thickness is measured using an Ellipsometric Film Thickness Measurement System RE-3100 (manufactured by SCREEN Semiconductor Solutions Co., Ltd.).

### <First Step>

The first step is a step of forming a surface-modified layer precursor.

In the first step, the semiconductor substrate is coated with the surface modifier and then baked to cross-link the polymer and to form a surface-modified layer precursor.

The semiconductor substrate used in the first step is not particularly limited as long as it is, for example, a substrate used for producing a precision integrated circuit element.

Examples of the semiconductor substrate include an inorganic substrate, an organic substrate, a substrate having a film of an inorganic material, and a substrate having a film of an organic material.

Examples of the inorganic material include arsenic, a metal, a metal oxide, a metal nitride, a metal carbide, a metal oxynitride, a metal oxycarbide, and a metal carbonitride. These materials can be used singly or in combination of two or more kinds thereof.

Examples of the metal include silicon, germanium, titanium, tungsten, hafnium, zirconium, chromium, copper, aluminum, indium, gallium, palladium, iron, tantalum, iridium, molybdenum, and alloys of these metals.

Examples of the metal oxide include SiO₂ and TiO₂.

Examples of the metal nitride include SiN, TiN, and TaN.

Examples of the metal carbide include SiC and TiC.

Examples of the metal oxynitride include SiON and TiON.

Examples of the metal oxycarbide include SiOC and TiOC.

Examples of the metal carbonitride include SiCN and TiCN.

Examples of the organic material include amorphous carbon, graphite, fullerene, carbon nanotube, diamond, diamond-like carbon, and polyimide. These materials can be used singly or in combination of two or more kinds thereof. The organic materials described above may be doped or partially substituted with boron, oxygen, nitrogen, phosphorus, silicon, sulfur, or halogen.

Examples of the semiconductor substrate include a semiconductor substrate such as a silicon wafer coated with a silicon oxide film, a silicon nitride film, or a silicon oxynitride film, a silicon nitride substrate, a quartz substrate, a glass substrate (alkali-free glass, low alkali glass, and crystallized glass are included), a glass substrate on which an indium tin oxide (ITO) film or an indium zinc oxide (IZO) film is formed, a plastic (such as polyimide or PET) substrate, a low-dielectric constant material (low-k material) coated substrate, and a flexible substrate.

The method for applying the surface modifier to the semiconductor substrate is not particularly limited. For example, the surface modifier can be applied by an appropriate applying method such as a spinner or a coater.

The baking after applying the surface modifier to the semiconductor substrate can be performed using, for example, a heating means such as a hot plate.

The baking conditions are appropriately selected from a baking temperature of 40° C. to 400° C., or 80° C. to 250° C., and a baking time of 0.3 minutes to 60 minutes. Preferably, the baking temperature is 150° C. to 250° C., and the baking time is 0.5 minutes to 2 minutes.

By the baking process, the solvent in the surface modifier is evaporated and the polymer is cross-linked to form a layered surface-modified layer precursor. The cross-linking includes partial cross-linking.

The surface-modified layer precursor formed here has a film thickness of, for example, 1 nm to 1,000 nm, or 1 nm to 500 nm, or 1 nm to 300 nm, or 1 nm to 200 nm, or 1 to 150 nm.

### <<Surface Modifier>>

The surface modifier contains a polymer and a solvent. The surface modifier may further contain an additional component.

The present invention is also directed to the surface modifier used in the method for producing a laminate of the present invention.

### <<<Polymer>>>

The polymer is not particularly limited as long as it is a cross-linkable polymer, and can be appropriately selected depending on the purpose.

The polymer may form a cross-linked structure only between the polymers, or may form a cross-linked structure together with a crosslinking agent.

The weight-average molecular weight of the polymer is not particularly limited, and may be, for example, 500 to 1,000,000. From the viewpoint of preventing the precipitation in the surface modifier, the weight-average molecular weight is preferably 500,000 or less, more preferably 250,000 or less, and still more preferably 100,000 or less. From the viewpoint of the compatibility between storage stability and application property, the weight-average molecular weight may be preferably 500 or more, more preferably 600 or more.

### —Polysiloxane—

As the polymer, a polysiloxane is preferred from the viewpoint of sufficiently preventing resist pattern collapse in EUV lithography or electron beam lithography.

The polysiloxane is not particularly limited as long as it is a polymer having a siloxane bond.

The polysiloxane may include a modified polysiloxane in which some of silanol groups are modified, for example, a modified polysiloxane in which some of silanol groups are alcohol-modified or acetal-protected.

Further, the polysiloxane may contain, as an example, a hydrolysis condensate of a hydrolyzable silane, and may contain a modified polysiloxane in which at least some of silanol groups of the hydrolysis condensate are alcohol-modified or acetal-protected. The hydrolyzable silane corresponding to the hydrolysis condensate may contain one or two or more hydrolyzable silanes.

Further, the polysiloxane may have a structure having a cage-shaped, ladder-shaped, linear, or branched main chain. Furthermore, the polysiloxane to be used may be a commercially available polysiloxane.

In the present invention, the “hydrolysis condensate”, i.e. product of hydrolysis condensation, of the hydrolyzable silane includes a polyorganosiloxane polymer which is a condensate prepared through complete condensation, and a polyorganosiloxane polymer which is a partial hydrolysis condensate prepared through incomplete condensation. Such a partial hydrolysis condensate is a polymer prepared through hydrolysis and condensation of a hydrolyzable silane compound, as in the case of a condensate prepared through complete condensation. However, the partial hydrolysis condensate contains remaining Si—OH groups, due to partial or incomplete hydrolysis and condensation of the silane compound. Further, the surface modifier may contain an uncondensed hydrolysate (complete hydrolysate or partial hydrolysate) or a remaining monomer (hydrolyzable silane), in addition to the hydrolysis condensate.

In the present specification, the “hydrolyzable silane” may be simply referred to as “silane compound”.

In addition, in the present specification, the “polysiloxane” may be referred to as “hydrolysis condensate”.

Preferably, the polysiloxane contains at least one structure selected from a hydrocarbon group having 1 to 8 carbon atoms optionally substituted with a halogen atom, an aromatic ring having 6 to 30 carbon atoms optionally substituted with a halogen atom, an alkenyl group, an alkynyl group, a norbornene ring, a phenol group, a protected phenol group, an amino group, an amide group, a cyclic amide group, an imide group, a cyclic imide group, a sulfonyl group, a sulfonamide group, a nitro group, a cyano group, a thiocyanate group, an isocyanate group, a halogen group, a carboxylic acid group, a carboxylic acid ester group, a sulfonic acid group, a sulfonic acid ester group, a phosphoric acid group, a phosphoric acid ester group, an ammonium group, a phosphonium group, a sulfonium group, an epoxy group, a glycidoxy group, a cyclohexylepoxy group, a ring-opened epoxy group, a ring-opened glycidoxy group, a ring-opened cyclohexylepoxy group, a hydroxy group, a mercapto group, an acryloyloxy group, or a methacryloyloxy group.

When the polysiloxane includes these structures, collapse of resist patterns formed on the surface-modified layer in EUV lithography or electron beam lithography can be sufficiently prevented.

The ring-opened epoxy group represents a —CH(OH)—CH₂(OH) group.

In the present invention, examples of the halogen atom include a fluorine atom, a chlorine atom, a bromine atom, and an iodine atom.

The polysiloxane preferably contains a group bonded to a silicon atom and having an ionic bond.

The group having an ionic bond has, for example, an anionic group which is a group bonded to a silicon atom, and a cation. The group having an ionic bond is represented by, for example, Formula (I-1) below. The group having an ionic bond has, for example, a cationic group which is a group bonded to a silicon atom, and an anion. The group having an ionic bond is represented by, for example, the following Formula (I-2):

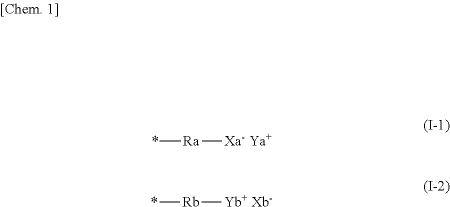

in Formula (I-1), an asterisk * represents a bonding hand bonded to a silicon atom, Ra represents a single bond or a divalent organic group, Xa⁻ represents a monovalent group having an anion, Ya⁺ represents a cation,
in Formula (I-2), an asterisk * represents a bonding hand bonded to a silicon atom, Rb represents a single bond or a divalent organic group, Yb⁺ represents a monovalent group having a cation, and Xb⁻ represents an anion.
Ra and Rb each are, for example, a divalent organic group having 1 to 10 carbon atoms.
Ra and Rb each may have a heteroatom. Examples of the heteroatom include an oxygen atom and a nitrogen atom.

Examples of the anion in the anionic group or an anion include a sulfonate anion, a carboxylate anion, and a phosphate anion.

Examples of the cation in the cationic group or a cation include a sulfonium cation, an iodonium cation, a phosphonium cation, a dihydroimidazole cation, and an ammonium cation.

The sulfonium cation is preferably a triarylsulfonium cation, a diarylmonoalkylsulfonium cation, a monoaryldialkylsulfonium, a trialkylsulfonium cation, or the like.

The iodonium cation is preferably a diaryliodonium cation.

The phosphonium cation is preferably a tetraarylphosphonium cation, a triarylmonoalkylphosphonium cation, a diaryldialkylphosphonium cation, a monoaryltrialkylsulfonium cation, or the like.

The ammonium cation is preferably a quaternary ammonium cation, a tertiary ammonium, a secondary ammonium, a primary ammonium, or the like.

Examples of the anionic group which is a group bonded to a silicon atom include the following groups:

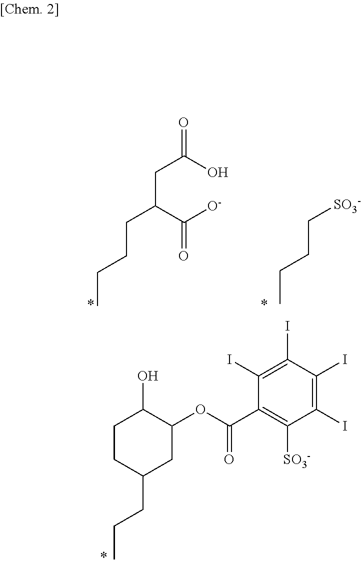

where each asterisk * represents a bonding hand bonded to a silicon atom.

Examples of the cationic group which is a group bonded to a silicon atom include the following groups:

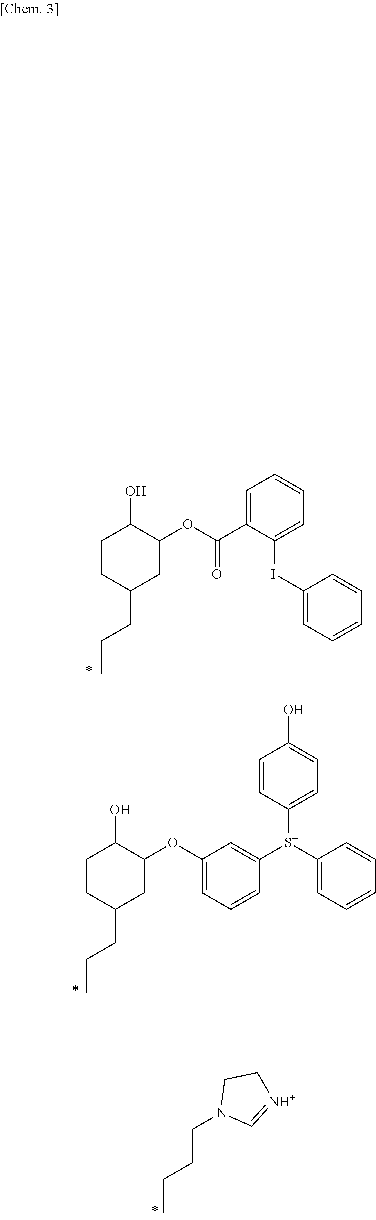

where each asterisk * represents a bonding hand bonded to a silicon atom.

Examples of the anion include the following anions:

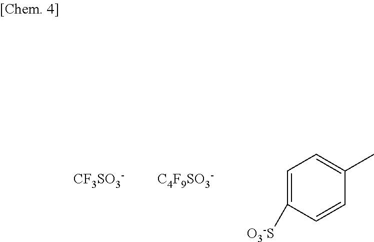

Examples of the cation include the following cations:

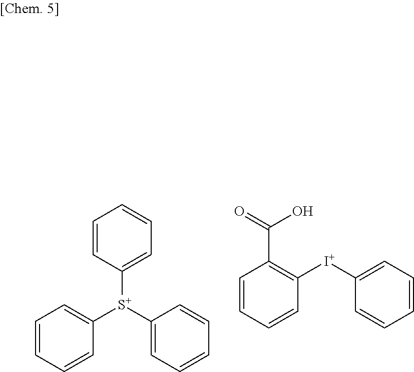 [SMILES: c1ccc([S+](c2ccccc2)c2ccccc2)cc1 ; O=C(O)c1ccccc1[I+]c1ccccc1]

Examples of the group having an ionic bond include the following groups:

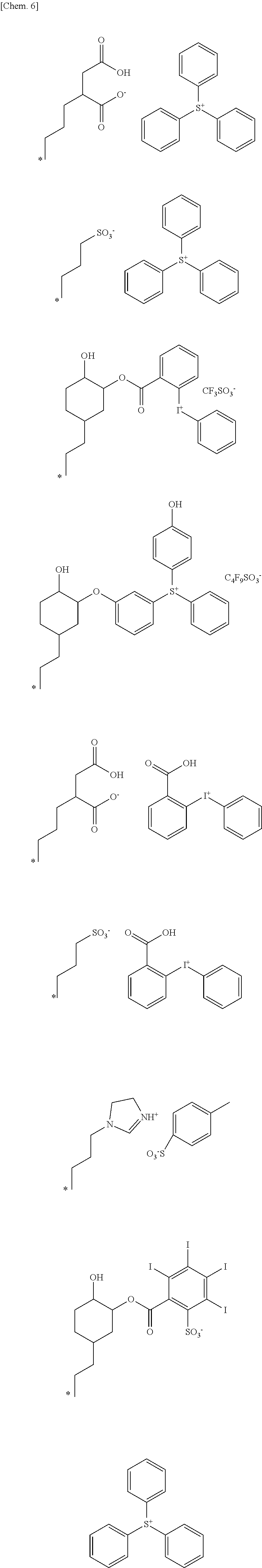

where each asterisk * represents a bonding hand bonded to a silicon atom.

The polysiloxane contains, for example, at least one of an M unit, a D unit, a T unit, or a Q unit.

The M unit is a structural unit represented by R^{a}R^{b}R^{c}SiO_{1/2}, the D unit is a structural unit represented by R^{a}R^{b}SiO_{2/2}, the T unit is a structural unit represented by R^{a}SiO_{1/2}, and the Q unit is a structural unit represented by SiO₄₂. R^{a}, R^{b}, and R^{c} in these structural units represent a monovalent organic group having no hydrolyzability.

The polysiloxane contains, for example, a Q unit.

The polysiloxane preferably contains a T unit. The proportion of the T unit in the polysiloxane is preferably 30 mass % or more, more preferably 50 mass or more, and particularly preferably 60 mass % or more, relative to the total of the M unit, the D unit, the T unit, and the Q unit of the polysiloxane. In this case, the polysiloxane may contain or need not contain the M unit, the D unit, and the Q unit. When the polysiloxane contains the T unit, the surface-modified layer formed by the action of the monovalent organic group tends to interact with an adjacent layer or film. As a result, for example, collapse of resist patterns formed on the surface-modified layer in EUV lithography or electron beam lithography can be more sufficiently prevented. In a case where the polysiloxane may contain the M unit and the D unit, when the mass ratio of the T unit is larger than the total of the M unit and the D unit in the polysiloxane, the film strength, film formability, and the like of the surface-modified layer can be enhanced.

The polysiloxane may be, for example, a hydrolysis condensate of a hydrolyzable silane containing at least one hydrolyzable silane represented by the following Formula (1).

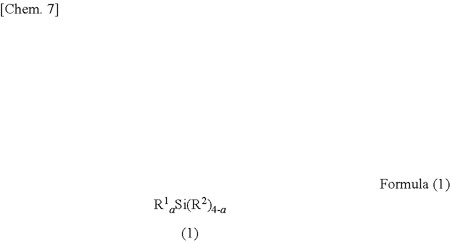

In Formula (1), R¹ is a group bonded to a silicon atom, and represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or an organic group having an optionally ring-opened epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more of these groups.

R² is a group or atom bonded to a silicon atom, and each independently represents an alkoxy group, an aralkyloxy group, an acyloxy group, or a halogen atom.
a represents an integer of 0 to 3.

### ———R¹———

The alkyl group may be linear, branched, or cyclic, and the number of carbon atoms thereof is not particularly limited, but is preferably 40 or less, more preferably 30 or less, still more preferably 20 or less, and yet still more preferably 10 or less.

Specific examples of the linear or branched alkyl group as the alkyl group include a methyl group, ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl group, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, and 1-ethyl-2-methyl-n-propyl group.

In the present specification, “i” means “iso”, “s” means “sec”, and “t” means “tert”.

Specific examples of the cyclic alkyl group include cycloalkyl groups, such as cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, cycloalkyl groups, such as 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group; and crosslinked cyclic cycloalkyl groups, such as bicyclobutyl group, bicyclopentyl group, bicyclohexyl group, bicycloheptyl group, bicyclooctyl group, bicyclononyl group, and bicyclodecyl group.

The aryl group may be any of a phenyl group, a monovalent group derived by removing one hydrogen atom from a condensed-ring aromatic hydrocarbon compound, and a monovalent group derived by removing one hydrogen atom from a linked-ring aromatic hydrocarbon compound. The number of carbon atoms of the aryl group is not particularly limited, but is preferably 40 or less, more preferably 30 or less, and still more preferably 20 or less.

Examples of the aryl group include an aryl group having 6 to 20 carbon atoms, and examples thereof include, but are not limited thereto, a phenyl group, 1-naphthyl group, 2-naphthyl group, 1-anthryl group, 2-anthryl group, 9-anthryl group, 1-phenanthryl group, 2-phenanthryl group, 3-phenanthryl group, 4-phenanthryl group, 9-phenanthryl group, 1-naphthacenyl group, 2-naphthacenyl group, 5-naphthacenyl group, 2-chrysenyl group, 1-pyrenyl group, 2-pyrenyl group, pentacenyl group, benzopyrenyl group, and triphenylenyl group, biphenyl-2-yl group (o-biphenylyl group), biphenyl-3-yl group (m-biphenylyl group), biphenyl-4-yl group (p-biphenylyl group), paraterphenyl-4-yl group, metaterphenyl-4-yl group, orthoterphenyl-4-yl group, 1,1′-binaphthyl-2-yl group, and 2,2′-binaphthyl-1-yl group.

The aralkyl group is an alkyl group substituted with an aryl group, and specific examples of the aryl group and the alkyl group are the same as those described above. The number of carbon atoms of the aralkyl group is not particularly limited, but is preferably 40 or less, more preferably 30 or less, and still more preferably 20 or less.

Specific examples of the aralkyl group include, but are not limited thereto, a phenylmethyl group (benzyl group), 2-phenylethylene group, 3-phenyl-n-propyl group, 4-phenyl-n-butyl group, 5-phenyl-n-pentyl group, 6-phenyl-n-hexyl group, 7-phenyl-n-heptyl group, 8-phenyl-n-octyl group, 9-phenyl-n-nonyl group, and 10 phenyl-n-decyl group.

The alkyl halide group, the aryl halide group, and the aralkyl halide group are an alkyl group substituted with one or more halogen atoms, an aryl group substituted with one or more halogen atoms, and an aralkyl group substituted with one or more halogen atoms, respectively. Specific examples of the alkyl halide group, the aryl halide group, and the aralkyl halide group are the same as those described above.

The number of carbon atoms of the alkyl halide group is not particularly limited, but is preferably 40 or less, more preferably 30 or less, still more preferably 20 or less, and yet still more preferably 10 or less.

Specific examples of the alkyl halide group include, but are not limited to, a monofluoromethyl group, difluoromethyl group, trifluoromethyl group, bromodifluoromethyl group, 2-chloroethyl group, 2-bromoethyl group, 1,1-difluoroethyl group, 2,2,2-trifluoroethyl group, 1,1,2,2-tetrafluoroethyl group, 2-chloro-1,1,2-trifluoroethyl group, pentafluoroethyl group, 3-bromopropyl group, 2,2,3,3-tetrafluoropropyl group, 1,1,2,3,3,3-hexafluoropropyl group, 1,1,1,3,3,3-hexafluoropropane-2-yl group, 3-bromo-2-methylpropyl group, 4-bromobutyl group, and perfluoropentyl group.

The number of carbon atoms of the aryl halide group is not particularly limited, but is preferably 40 or less, more preferably 30 or less, and still more preferably 20 or less.

Specific examples of the aryl halide include a 2-fluorophenyl group, 3-fluorophenyl group, 4-fluorophenyl group, 2,3-difluorophenyl group, 2,4-difluorophenyl group, 2,5-difluorophenyl group, 2,6-difluorophenyl group, 3,4-difluorophenyl group, 3,5-difluorophenyl group, 2,3,4-trifluorophenyl group, 2,3,5-trifluorophenyl group, 2,3,6-trifluorophenyl group, 2,4,5-trifluorophenyl group, 2,4,6-trifluorophenyl group, 3,4,5-trifluorophenyl group, 2,3,4,5-tetrafluorophenyl group, 2,3,4,6-tetrafluorophenyl group, 2,3,5,6-tetrafluorophenyl group, pentafluorophenyl group, 2-fluoro-1-naphthyl group, 3-fluoro-1-naphthyl group, 4-fluoro-1-naphthyl group, 6-fluoro-1-naphthyl group, 7-fluoro-1-naphthyl group, 8-fluoro-1-naphthyl group, 4,5-difluoro-1-naphthyl group, 5,7-difluoro-1-naphthyl group, 5,8-difluoro-1-naphthyl group, 5,6,7,8-tetrafluoro-1-naphthyl group, heptafluoro-1-naphthyl group, 1-fluoro-2-naphthyl group, 5-fluoro-2-naphthyl group, 6-fluoro-2-naphthyl group, 7-fluoro-2-naphthyl group, 5,7-difluoro-2-naphthyl group, and heptafluoro-2-naphthyl group. Examples thereof also include groups in which fluorine atoms (fluoro groups) in the above groups are optionally substituted with chlorine atoms (chloro groups), bromine atoms (bromo groups), or iodine atoms (iodine groups), but not limited thereto.

The number of carbon atoms of the aralkyl halide group is not particularly limited, but is preferably 40 or less, more preferably 30 or less, and still more preferably 20 or less.

Specific examples of the aralkyl halide group include a 2-fluorobenzyl group, 3-fluorobenzyl group, 4-fluorobenzyl group, 2,3-difluorobenzyl group, 2,4-difluorobenzyl group, 2,5-difluorobenzyl group, 2,6-difluorobenzyl group, 3,4-difluorobenzyl group, 3,5-difluorobenzyl group, 2,3,4-trifluorobenzyl group, 2,3,5-trifluorobenzyl group, 2,3,6-trifluorobenzyl group, 2,4,5-trifluorobenzyl group, 2,4,6-trifluorobenzyl group, 2,3,4,5-tetrafluorobenzyl group, 2,3,4,6-tetrafluorobenzyl group, 2,3,5,6-tetrafluorobenzyl group, and 2,3,4,5,6-pentafluorobenzyl group. Examples thereof also include groups in which fluorine atoms (fluoro groups) in the above groups are optionally substituted with chlorine atoms (chloro groups), bromine atoms (bromo groups), or iodine atoms (iodine groups), but not limited thereto.

The alkoxyalkyl group, the alkoxyaryl group, and the alkoxyaralkyl group are an alkyl group substituted with one or more alkoxy groups, an aryl group substituted with one or more alkoxy groups, and an aralkyl group substituted with one or more alkoxy groups, respectively. Specific examples of the alkoxyalkyl group, the alkoxyaryl group, and the alkoxyaralkyl group are the same as those described above.

The alkoxy group as the substituent is, for example, an alkoxy group having at least any one of linear, branched, and cyclic alkyl moieties having 1 to 20 carbon atoms.

Examples of the linear or branched alkoxy group include a methoxy group, ethoxy group, n-propoxy group, i-propoxy group, n-butoxy group, i-butoxy group, s-butoxy group, t-butoxy group, n-pentyloxy group, 1-methyl-n-butoxy group, 2-methyl-n-butoxy group, 3-methyl-n-butoxy group, 1,1-dimethyl-n-propoxy group, 1,2-dimethyl-n-propoxy group, 2,2-dimethyl-n-propoxy group, 1-ethyl-n-propoxy group, n-hexyloxy group, 1-methyl-n-pentyloxy group, 2-methyl-n-pentyloxy group, 3-methyl-n-pentyloxy group, 4-methyl-n-pentyloxy group, 1,1-dimethyl-n-butoxy group, 1,2-dimethyl-n-butoxy group, 1,3-dimethyl-n-butoxy group, 2,2-dimethyl-n-butoxy group, 2,3-dimethyl-n-butoxy group, 3,3-dimethyl-n-butoxy group, 1-ethyl-n-butoxy group, 2-ethyl-n-butoxy group, 1,1,2-trimethyl-n-propoxy group, 1,2,2-trimethyl-n-propoxy group, 1-ethyl-1-methyl-n-propoxy group, and 1-ethyl-2-methyl-n-propoxy group.

Examples of the cyclic alkoxy group include a cyclopropoxy group, cyclobutoxy group, 1-methyl-cyclopropoxy group, 2-methyl-cyclopropoxy group, cyclopentyloxy group, 1-methyl-cyclobutoxy group, 2-methyl-cyclobutoxy group, 3-methyl-cyclobutoxy group, 1,2-dimethyl-cyclopropoxy group, 2,3-dimethyl-cyclopropoxy group, 1-ethyl-cyclopropoxy group, 2-ethyl-cyclopropoxy group, cyclohexyloxy group, 1-methyl-cyclopentyloxy group, 2-methyl-cyclopentyloxy group, 3-methyl-cyclopentyloxy group, 1-ethyl-cyclobutoxy group, 2-ethyl-cyclobutoxy group, 3-ethyl-cyclobutoxy group, 1,2-dimethyl-cyclobutoxy group, 1,3-dimethyl-cyclobutoxy group, 2,2-dimethyl-cyclobutoxy group, 2,3-dimethyl-cyclobutoxy group, 2,4-dimethyl-cyclobutoxy group, 3,3-dimethyl-cyclobutoxy group, 1-n-propyl-cyclopropoxy group, 2-n-propyl-cyclopropoxy group, 1-i-propyl-cyclopropoxy group, 2-i-propyl-cyclopropoxy group, 1,2,2-trimethyl-cyclopropoxy group, 1,2,3-trimethyl-cyclopropoxy group, 2,2,3-trimethyl-cyclopropoxy group, 1-ethyl-2-methyl-cyclopropoxy group, 2-ethyl-1-methyl-cyclopropoxy group, 2-ethyl-2-methyl-cyclopropoxy group, and 2-ethyl-3-methyl-cyclopropoxy group.

Specific examples of the alkoxyalkyl group include, but are not limited to, lower (about 5 or less carbon atoms) alkyloxy lower (about 5 or less carbon atoms) alkyl groups, such as methoxymethyl group, ethoxymethyl group, 1-ethoxyethyl group, 2-ethoxyethyl group, and ethoxymethyl group.

Specific examples of the alkoxyaryl group include, but are not limited to, a 2-methoxyphenyl group, 3-methoxyphenyl group, 4-methoxyphenyl group, 2-(1-ethoxy)phenyl group, 3-(1-ethoxy)phenyl group, 4-(1-ethoxy)phenyl group, 2-(2-ethoxy)phenyl group, 3-(2-ethoxy)phenyl group, 4-(2-ethoxy)phenyl group, 2-methoxynaphthalene-1-yl group, 3-methoxynaphthalene-1-yl group, 4-methoxynaphthalene-1-yl group, 5-methoxynaphthalene-1-yl group, 6-methoxynaphthalene-1-yl group, and 7-methoxynaphthalene-1-yl group.

Specific examples of the alkoxyaralkyl group include, but are not limited to, a 3-(methoxyphenyl)benzyl group and a 4-(methoxyphenyl)benzyl group.

The alkenyl group may be linear or branched, and the number of carbon atoms of the linear or branched alkenyl group is not particularly limited, but is preferably 40 or less, more preferably 30 or less, still more preferably 20 or less, and yet still more preferably 10 or less.

Specific examples of the alkenyl group include an ethenyl group (vinyl group), 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3 pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group. Examples thereof also include crosslinked cyclic alkenyl groups such as a bicycloheptenyl group (norbornyl group).

Examples of the substituent in the aforementioned alkyl group, aryl group, aralkyl group, alkyl halide group, aryl halide group, aralkyl halide group, alkoxyalkyl group, alkoxyaryl group, alkoxyaralkyl group, and alkenyl group described above include an alkyl group, an aryl group, an aralkyl group, an alkyl halide group, an aryl halide group, an aralkyl halide group, an alkoxyalkyl group, an aryloxy group, an alkoxyaryl group, an alkoxyaralkyl group, an alkenyl group, an alkoxy group, and an aralkyloxy group. Specific examples thereof and the preferred number of carbon atoms thereof are the same as those described above or below.

The aryloxy group as described in the substituent is a group in which an aryl group is bonded via an oxygen atom (—O—), and specific examples of the aryl group are the same as those described above. The number of carbon atoms in the aryloxy group is not particularly limited, but is preferably 40 or less, more preferably 30 or less, and still more preferably 20 or less. Specific examples thereof include, but are not limited to, phenoxy group and naphthalene-2-yloxy group.

When two or more substituents are present, the substituents may be bonded together to form a ring.

Examples of the organic group having an optionally ring-opened epoxy group include a glycidoxymethyl group, a glycidoxyethyl group, a glycidoxypropyl group, a glycidoxybutyl group, an epoxy cyclohexyl group, and groups in which epoxy groups of the above groups are ring-opened.

Examples of the organic group having an acryloyl group include an acryloyloxymethyl group, an acryloyloxyethyl group, and an acryloyloxypropyl group.

Examples of the organic group having a methacryloyl group include a methacryloyloxymethyl group, a methacryloyloxyethyl group, and a methacryloyloxypropyl group.

Examples of the organic group having a mercapto group include a mercaptoethyl group, a mercaptobutyl group, a mercaptohexyl group, a mercaptooctyl group, and a mercaptophenyl group.

Examples of the organic group having an amino group include, but are not limited to, an amino group, an aminomethyl group, an aminoethyl group, an aminophenyl, a dimethylaminoethyl group, and a dimethylaminopropyl group. The organic group having an amino group will be described later in more detail.

Examples of the organic group having an alkoxy group include, but are not limited to, a methoxymethyl group and a methoxyethyl group. However, the organic group excludes a group wherein an alkoxy group is directly bonded to a silicon atom.

Examples of the organic group having a sulfonyl group include, but are not limited to, a sulfonylalkyl group and a sulfonylaryl group.

Examples of the organic group having a cyano group include a cyanoethyl group, a cyanopropyl group, a cyanophenyl, and a thiocyanate group.

The organic group having an amino group is, for example, an organic group having at least one of a primary amino group, a secondary amino group, or a tertiary amino group. A hydrolysis condensate in which a hydrolyzable silane having a tertiary amino group is hydrolyzed with a strong acid to form a counter cation having a tertiary ammonium group can be preferably used. The organic group may contain a heteroatom such as an oxygen atom or a sulfur atom, in addition to the nitrogen atom forming the amino group.

A preferable example of the organic group having an amino group is a group represented by the following Formula (A1).

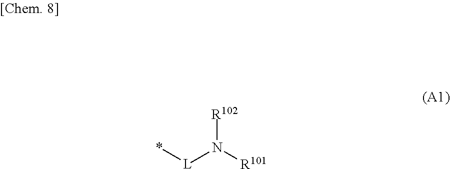

In Formula (A1), R¹⁰¹ and R¹⁰² each independently represent a hydrogen atom or a hydrocarbon group, and L represents an independently and optionally substituted alkylene group, and an asterisk * represents a bonding hand.

Examples of the hydrocarbon group include, but are not limited to, an alkyl group, an alkenyl group, and an aryl group. Specific examples of the alkyl group, the alkenyl group, and the aryl group are the same as those described above regarding R¹.

The alkylene group may be linear or branched, and the number of carbon atoms of the linear or branched alkylene group is ordinarily 1 to 10, preferably 1 to 5. Examples of the linear or branched alkylene group include linear alkylene groups such as a methylene group, an ethylene group, a trimethylene group, a tetramethylene group, a pentamethylene group, a hexamethylene group, a heptamethylene group, an octamethylene group, a nonamethylene group, and a decamethylene group. Examples of the organic group having an amino group include, but are not limited to, an amino group, an aminomethyl group, an aminoethyl group, an aminophenyl, a dimethylaminoethyl group, and a dimethylaminopropyl group.

### ———R²———

Examples of the alkoxy group in R² include the alkoxy groups exemplified in the description of R¹.

Examples of the halogen atom in R² include the halogen atoms exemplified in the description of R¹.

The aralkyloxy group is a monovalent group derived by removing a hydrogen atom from a hydroxy group of aralkyl alcohol, and specific examples of the aralkyl group in the aralkyloxy group are the same as those described above. The number of carbon atoms of the aralkyloxy group is not particularly limited, but may be, for example, 40 or less, preferably 30 or less, and more preferably 20 or less.

Specific examples of the aralkyloxy group include, but are not limited to, a phenylmethyloxy group (benzyloxy group), 2-phenylethyleneoxy group, 3-phenyl-n-propyloxy group, 4-phenyl-n-butyloxy group, 5-phenyl-n-pentyloxy group, 6-phenyl n-hexyloxy group, 7-phenyl-n-heptyloxy group, 8-phenyl-n-octyloxy group, 9-phenyl-n-nonyloxy group, and 10-phenyl-n-decyloxy group.

The acyloxy group is a monovalent group derived by removing a hydrogen atom from a carboxyl group (—COOH) of a carboxylic acid compound, and examples of the acyloxy group typically include, but are not limited to, an alkylcarbonyloxy group, an arylcarbonyloxy group, or an aralkylcarbonyloxy group, derived by removing a hydrogen atom from a carboxyl group of an alkyl carboxylic acid, an aryl carboxylic acid, or an aralkyl carboxylic acid. Specific examples of the alkyl group, aryl group, and aralkyl group in the alkyl carboxylic acid, aryl carboxylic acid, and aralkyl carboxylic acid are the same as those described above.

Specific examples of the acyloxy group include an acyloxy group having 2 to 20 carbon atoms, and examples thereof include a methylcarbonyloxy group, ethylcarbonyloxy group, n-propylcarbonyloxy group, i-propylcarbonyloxy group, n-butylcarbonyloxy group, i-butylcarbonyloxy group, s-butylcarbonyloxy group, t-butylcarbonyloxy group, n-pentylcarbonyloxy group, 1-methyl-n-butylcarbonyloxy group, 2-methyl-n-butylcarbonyloxy group, 3-methyl-n-butylcarbonyloxy group, 1,1-dimethyl-n-propylcarbonyloxy group, 1,2-dimethyl-n-propylcarbonyloxy group, 2,2-dimethyl-n-propylcarbonyloxy group, 1-ethyl-n-propylcarbonyloxy group, n-hexylcarbonyloxy group, 1-methyl-n-pentylcarbonyloxy group, 2-methyl-n-pentylcarbonyloxy group, 3-methyl-n-pentylcarbonyloxy group, 4-methyl-n-pentylcarbonyloxy group, 1,1-dimethyl-n-butylcarbonyloxy group, 1,2-dimethyl-n-butylcarbonyloxy group, 1,3-dimethyl-n-butylcarbonyloxy group, 2,2-dimethyl-n-butylcarbonyloxy group, 2,3-dimethyl-n-butylcarbonyloxy group, 3,3-dimethyl-n-butylcarbonyloxy group, 1-ethyl-n-butylcarbonyloxy group, 2-ethyl-n-butylcarbonyloxy group, 1,1,2-trimethyl-n-propylcarbonyloxy group, 1,2,2-trimethyl-n-propylcarbonyloxy group, 1-ethyl-1-methyl-n-propylcarbonyloxy group, 1-ethyl-2-methyl-n-propylcarbonyloxy group, phenylcarbonyloxy group, and tosylcarbonyloxy group.

### ———Specific Example of Hydrolyzable Silane Represented by Formula (1)———

Specific examples of the hydrolyzable silane represented by Formula (1) include, but are not limited to, tetramethoxysilane, tetrachlorosilane, tetraacetoxysilane, tetraethoxysilane, tetra-n-propoxysilane, tetra-i-propoxysilane, tetra-n-butoxysilane, methyltrimethoxysilane, methyltrichlorosilane, methyltriacetoxysilane, methyltriethoxysilane, methyltripropoxysilane, methyltributoxysilane, methyltriamyloxysilane, methyltriphenoxysilane, methyltribenzyloxysilane, methyltriphenethyloxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, and α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, 6-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, ethyltrimethoxysilane, ethyltriethoxysilane, vinyltrimethoxysilane, vinyltriethoxysilane, vinyltrichlorosilane, vinyltriacetoxysilane, methylvinyldimethoxysilane, methylvinyldiethoxysilane, methylvinyldichlorosilane, methylvinyldiacetoxysilane, dimethylvinylmethoxysilane, dimethylvinylethoxysilane, dimethylvinylchlorosilane, dimethylvinylacetoxysilane, divinyldimethoxysilane, divinyldiethoxysilane, divinyldichlorosilane, divinyldiacetoxysilane, γ-glycidoxypropylvinyldimethoxysilane, γ-glycidoxypropylvinyldiethoxysilane, allyltrimethoxysilane, allyltriethoxysilane, allyltrichlorosilane, allyltriacetoxysilane, allylmethyldimethoxysilane, allylmethyldiethoxysilane, allylmethyldichlorosilane, allylmethyldiacetoxysilane, allyldimethylmethoxysilane, allyldimethylethoxysilane, allyldimethylchlorosilane, allyldimethylacetoxysilane, diallyldimethoxysilane, diallyldiethoxysilane, diallyldichlorosilane, diallyldiacetoxysilane, 3-allylaminopropyltrimethoxysilane, 3-allylaminopropyltriethoxysilane, p-styryltrimethoxysilane, phenyltrimethoxysilane, phenyltriethoxysilane, phenyltrichlorosilane, phenyltriacetoxysilane, phenylmethyldimethoxysilane, phenylmethyldiethoxysilane, phenylmethyldichlorosilane, phenylmethyldiacetoxysilane, phenyldimethylmethoxysilane, phenyldimethylethoxysilane, phenyldimethylchlorosilane, phenyldimethylacetoxysilane, diphenylmethylmethoxysilane, diphenylmethylethoxysilane, diphenylmethylchlorosilane, diphenylmethylacetoxysilane, diphenyldimethoxysilane, diphenyldiethoxysilane, diphenyldichlorosilane, diphenyldiacetoxysilane, triphenylmethoxysilane, triphenylethoxysilane, triphenylacetoxysilane, triphenylchlorosilane, 3-phenylaminopropyltrimethoxysilane, 3-phenylaminopropyltriethoxysilane, dimethoxymethyl-3-(3-phenoxypropylthiopropyl)silane, triethoxy((2-methoxy-4-(methoxymethyl)phenoxy)methyl)silane, benzyltrimethoxysilane, benzyltriethoxysilane, benzylmethyldimethoxysilane, benzylmethyldiethoxysilane, benzyldimethylmethoxysilane, benzyldimethylethoxysilane, benzyldimethylchlorosilane, phenethyltrimethoxysilane, phenethyltriethoxysilane, phenethyltrichlorosilane, phenethyltriacetoxysilane, phenethylmethyldimethoxysilane, phenethylmethyldiethoxysilane, phenethylmethyldichlorosilane, phenethylmethyldiacetoxysilane, methoxyphenyltrimethoxysilane, methoxyphenyltriethoxysilane, methoxyphenyltriacetoxysilane, methoxyphenyltrichlorosilane, methoxybenzyltrimethoxysilane, methoxybenzyltriethoxysilane, methoxybenzyltriacetoxysilane, methoxybenzyltrichlorosilane, methoxyphenethyltrimethoxysilane, methoxyphenethyltriethoxysilane, methoxyphenethyltriacetoxysilane, methoxyphenethyltrichlorosilane, ethoxyphenyltrimethoxysilane, ethoxyphenyltriethoxysilane, ethoxyphenyltriacetoxysilane, ethoxyphenyltrichlorosilane, ethoxybenzyltrimethoxysilane, ethoxybenzyltriethoxysilane, ethoxybenzyltriacetoxysilane, ethoxybenzyltrichlorosilane, i-propoxyphenyltrimethoxysilane, i-propoxyphenyltriethoxysilane, i-propoxyphenyltriacetoxysilane, i-propoxyphenyltrichlorosilane, i-propoxybenzyltrimethoxysilane, i-propoxybenzyltriethoxysilane, i-propoxybenzyltriacetoxysilane, i-propoxybenzyltrichlorosilane, t-butoxyphenyltrimethoxysilane, t-butoxyphenyltriethoxysilane, t-butoxyphenyltriacetoxysilane, t-butoxyphenyltrichlorosilane, t-butoxybenzyltrimethoxysilane, t-butoxybenzyltriethoxysilane, t-butoxybenzyltriacetoxysilane, t-butoxybenzyltrichlorosilane, methoxynaphthyltrimethoxysilane, methoxynaphthyltriethoxysilane, methoxynaphthyltriacetoxysilane, methoxynaphthyltrichlorosilane, ethoxynaphthyltrimethoxysilane, ethoxynaphthyltriethoxysilane, ethoxynaphthyltriacetoxysilane, ethoxynaphthyltrichlorosilane, γ-chloropropyltrimethoxysilane, γ-chloropropyltriethoxysilane, γ-chloropropyltriacetoxysilane, 3,3,3-trifluoropropyltrimethoxysilane, γ-methacryloxypropyltrimethoxysilane, γ-mercaptopropyltrimethoxysilane, γ-mercaptopropyltriethoxysilane, β-cyanoethyltriethoxysilane, thiocyanatepropyltriethoxysilane, chloromethyltrimethoxysilane, chloromethyltriethoxysilane, triethoxysilylpropyldiallylisocyanurate, bicyclo[2,2,1]heptenyltriethoxysilane, benzenesulfonylpropyltriethoxysilane, benzenesulfonamidepropyltriethoxysilane, dimethylaminopropyltrimethoxysilane, dimethyldimethoxysilane, phenylmethyldimethoxysilane, dimethyldiethoxysilane, phenylmethyldiethoxysilane, γ-chloropropylmethyldimethoxysilane, γ-chloropropylmethyldiethoxysilane, dimethyldiacetoxysilane, γ-methacryloxypropylmethyldimethoxysilane, γ-methacryloxypropylmethyldiethoxysilane, γ-mercaptopropylmethyldimethoxysilane, γ-mercaptomethyldiehoxysilane, methylvinyldimethoxysilane, methylvinyldiethoxysilane, silanes represented by Formulae (A-1) to (A-41) below, and silanes represented by Formulae (1-1) to (1-290) below.

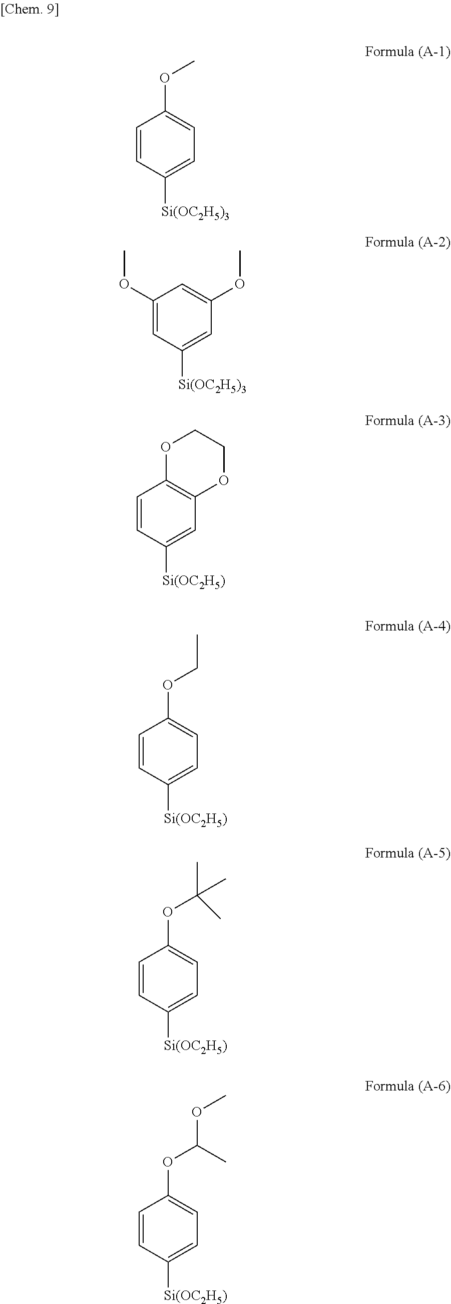

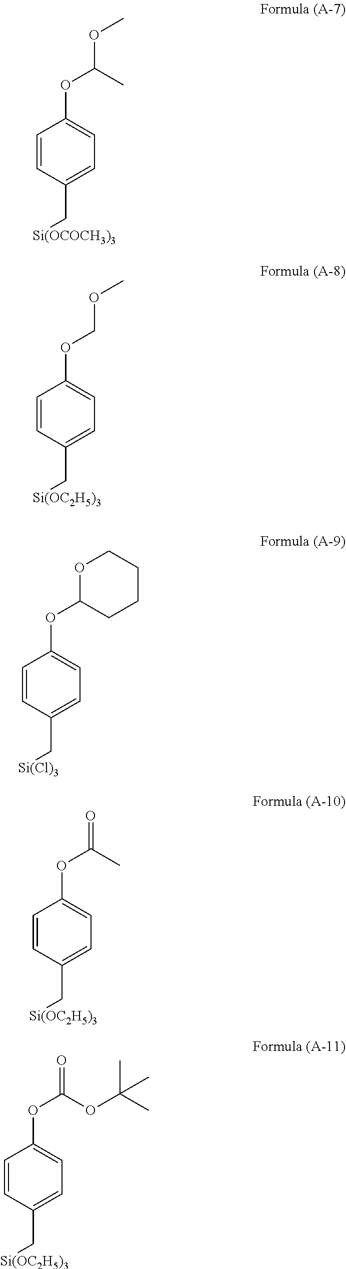

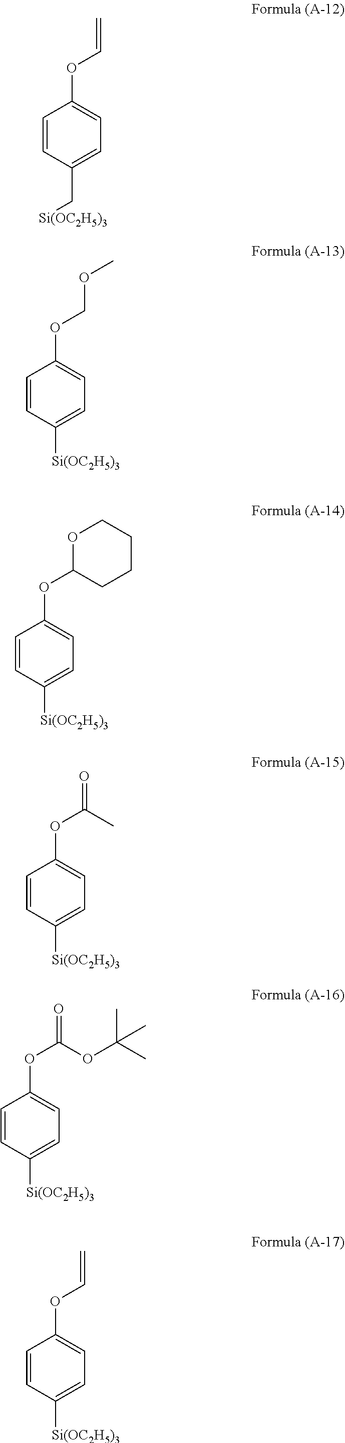

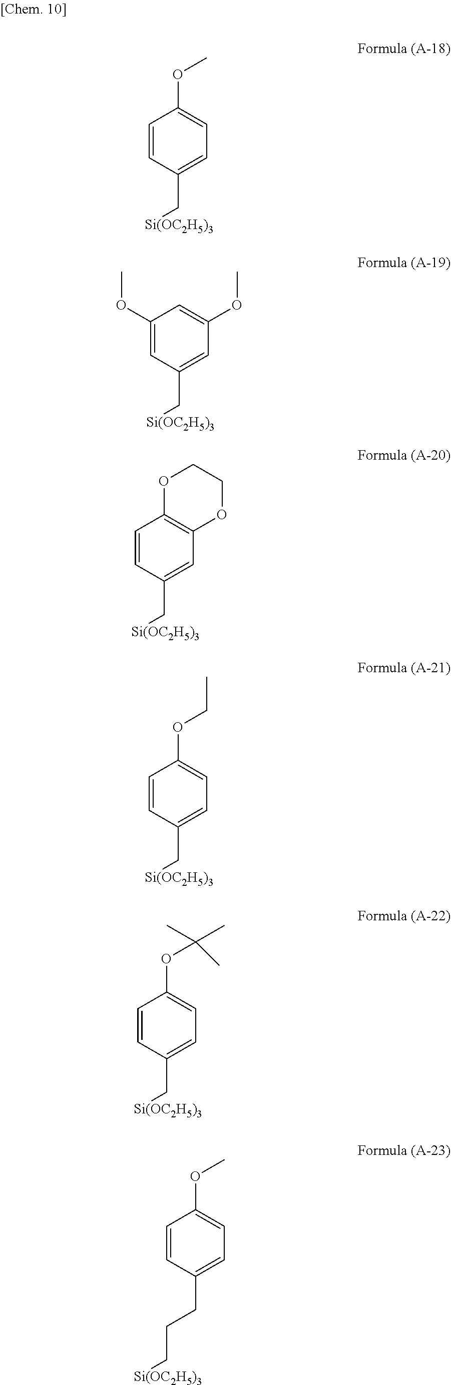

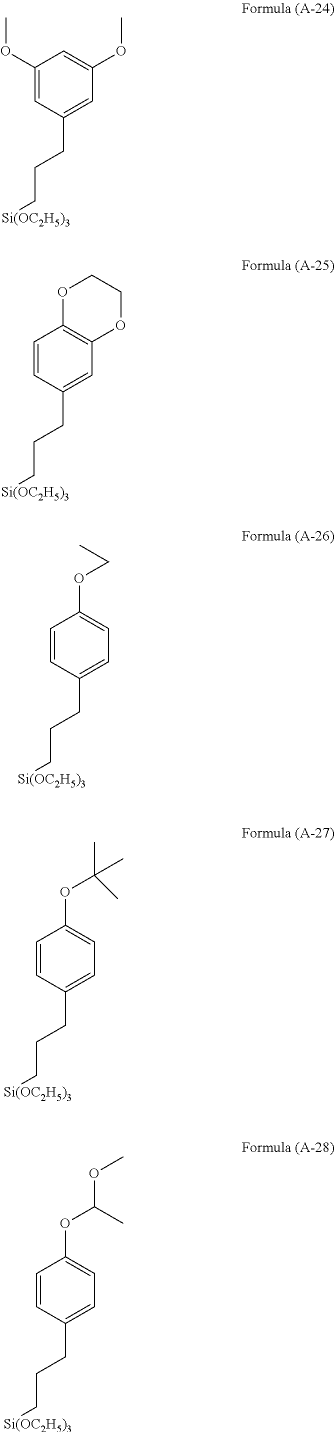

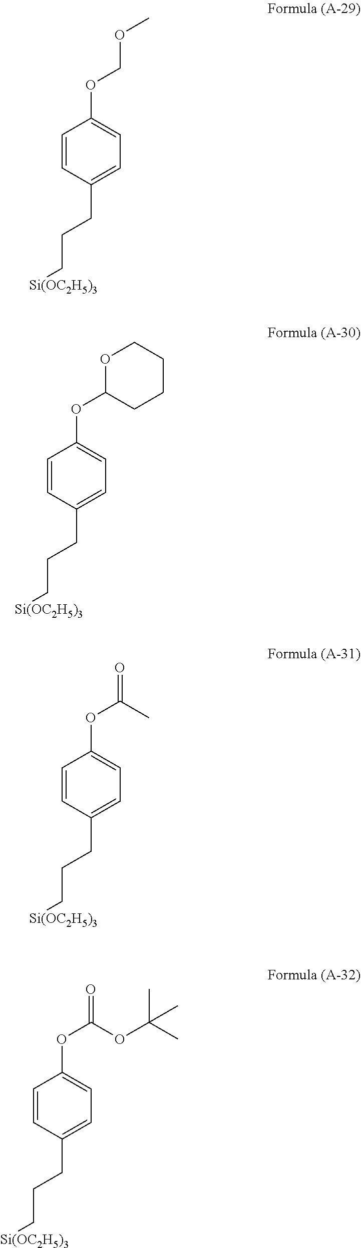

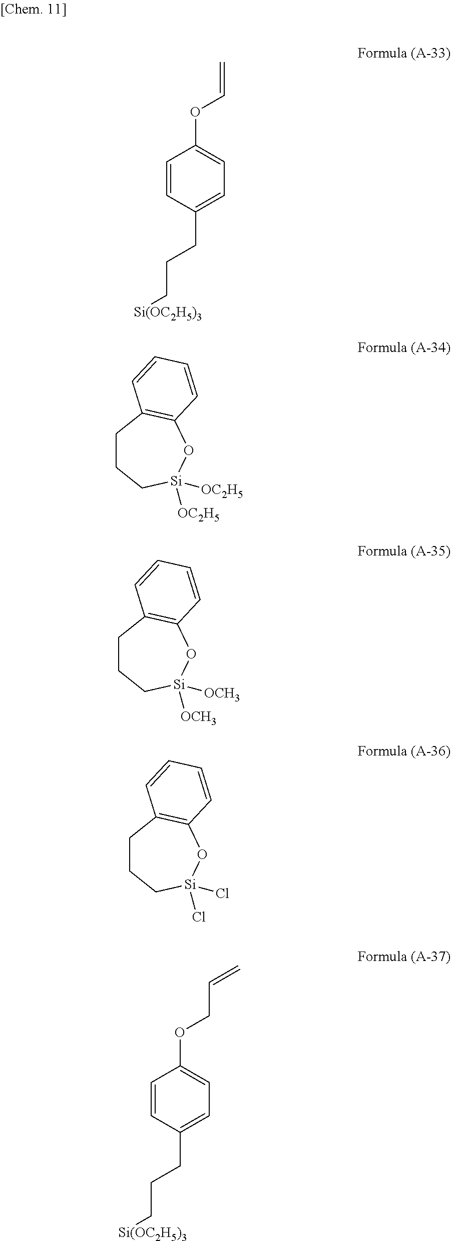

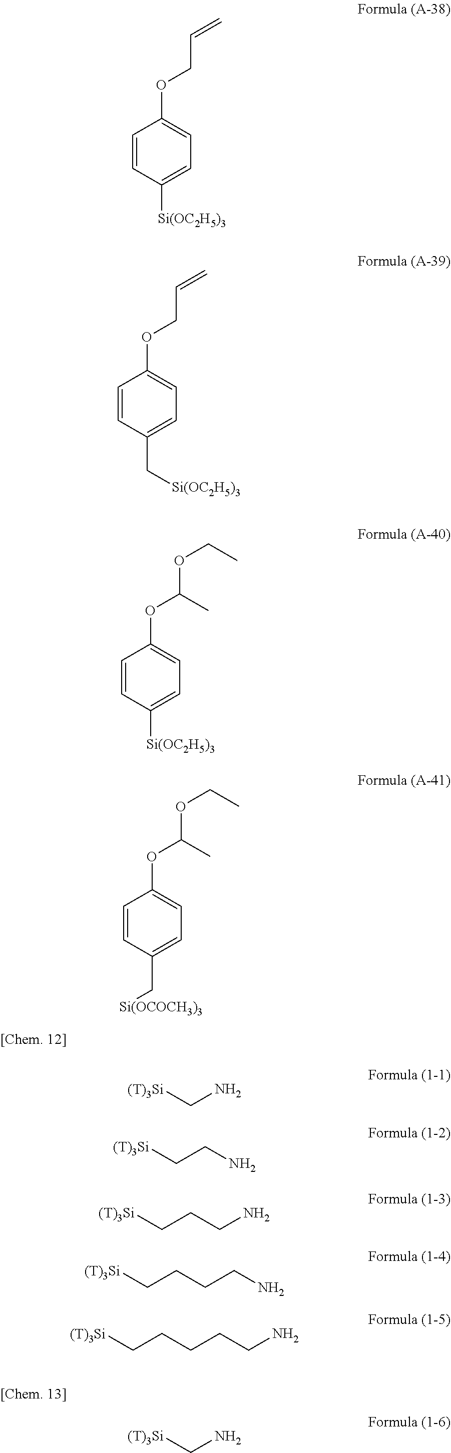

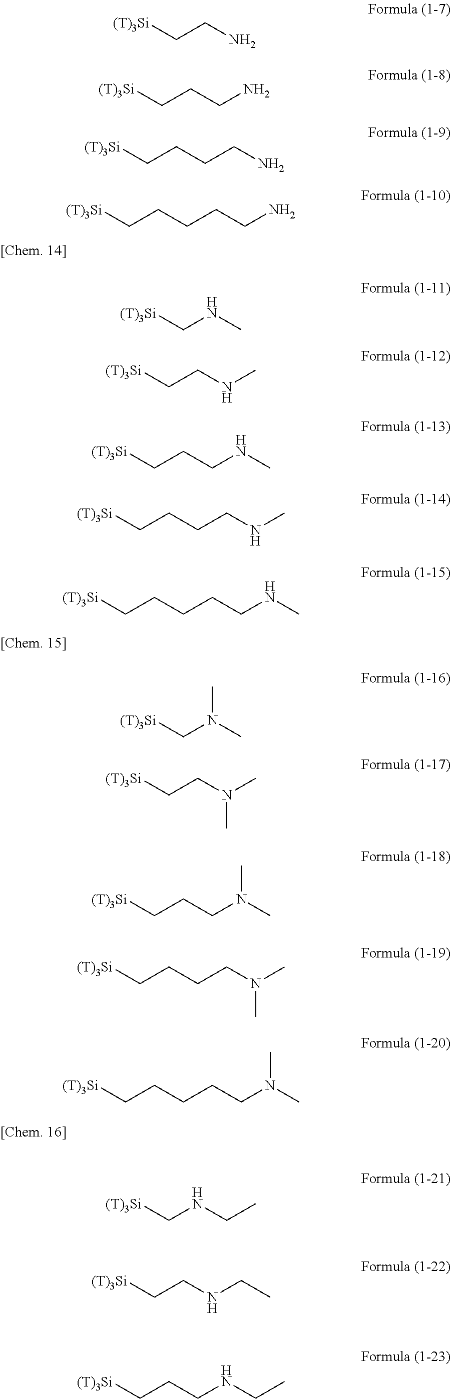

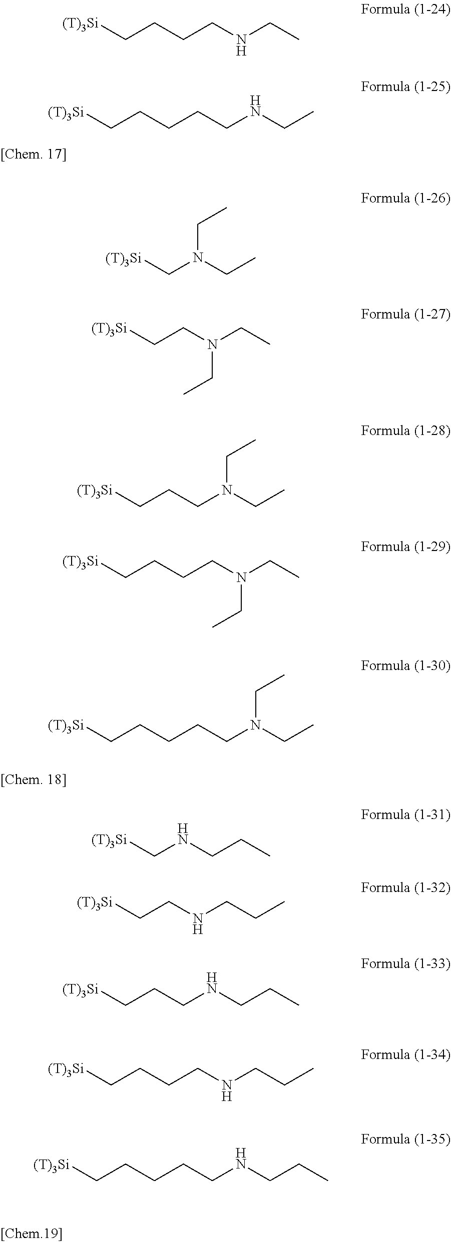

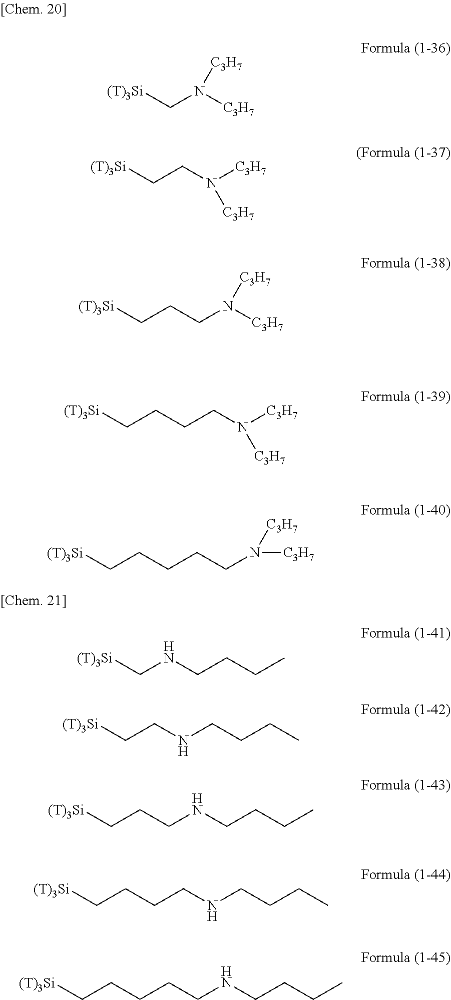

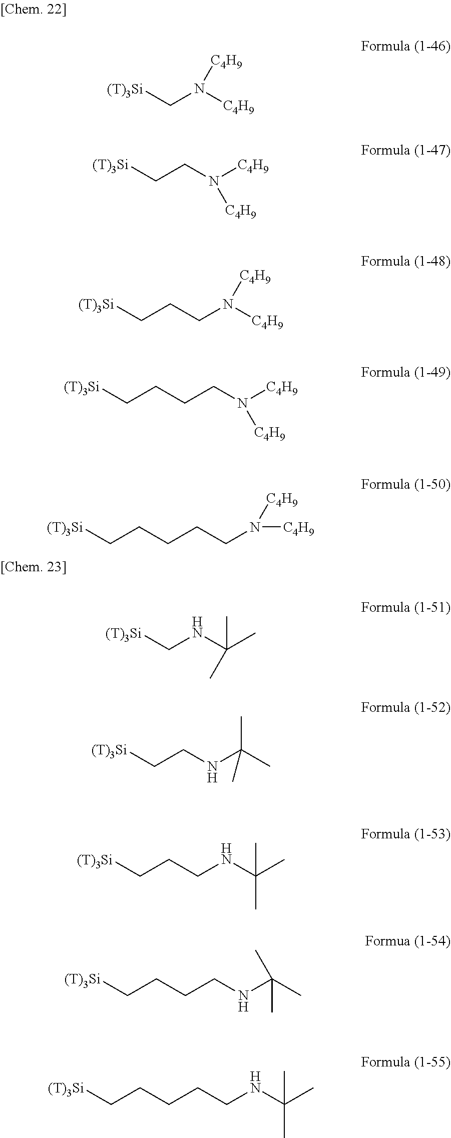

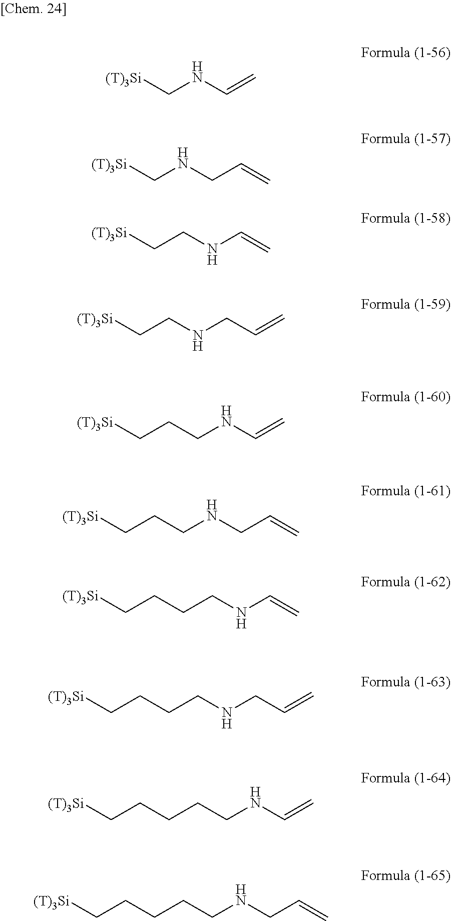

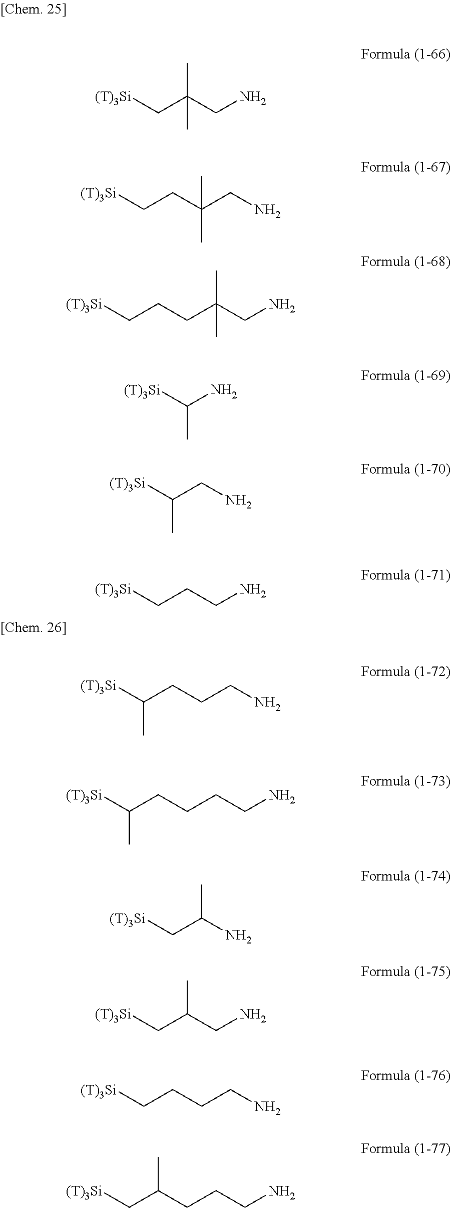

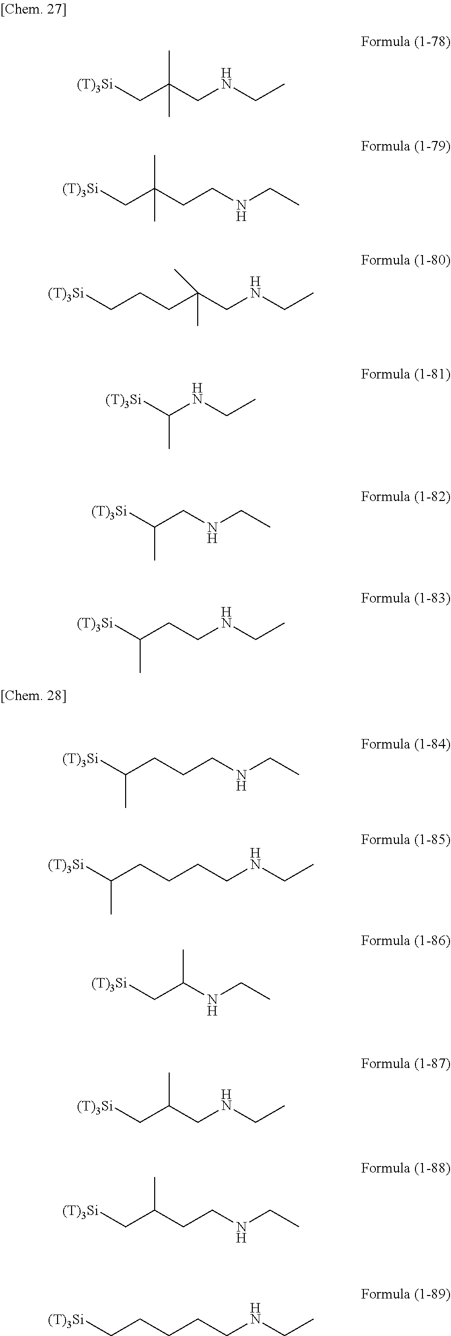

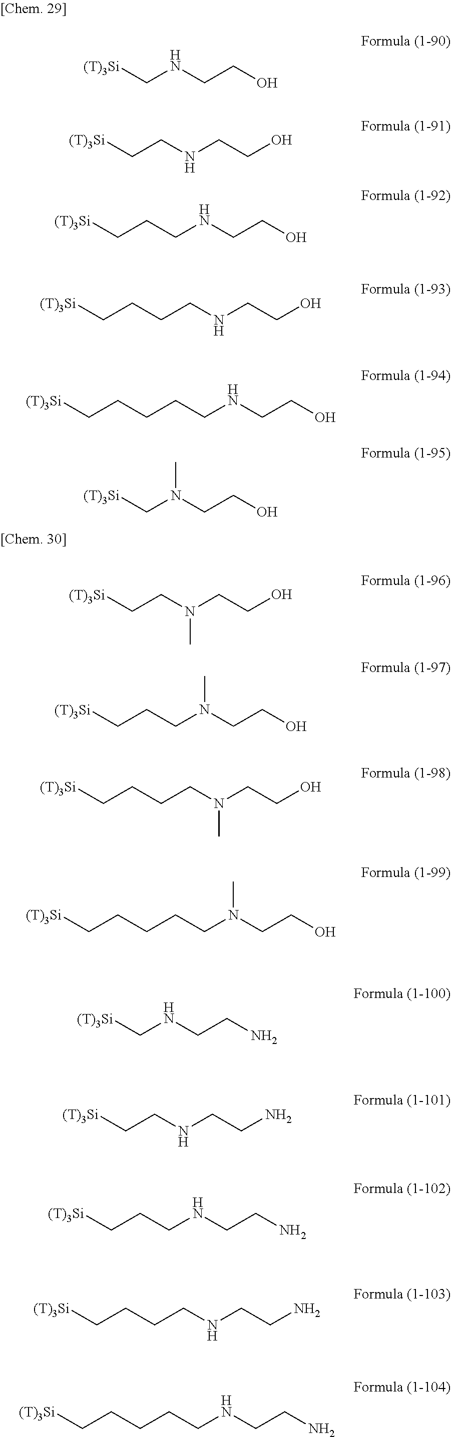

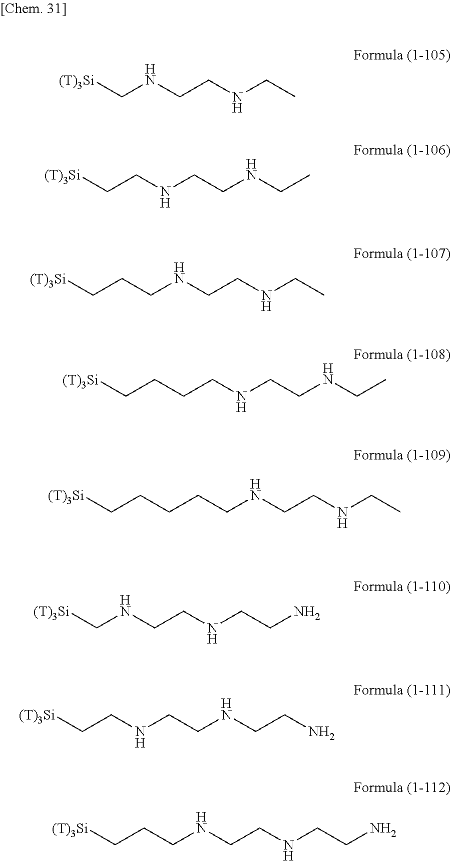

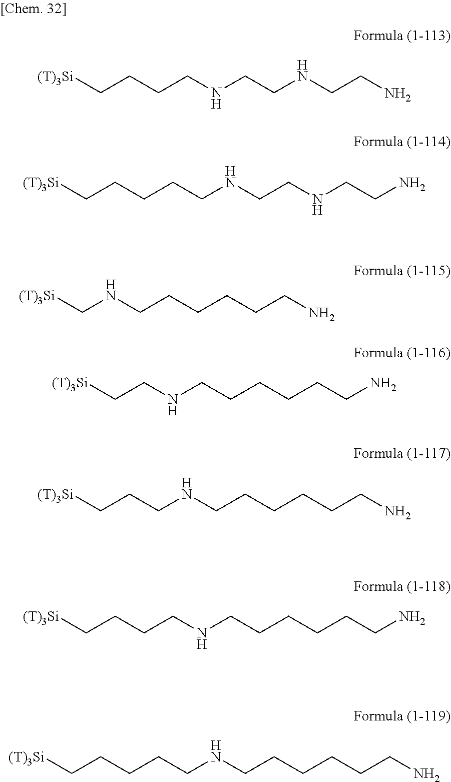

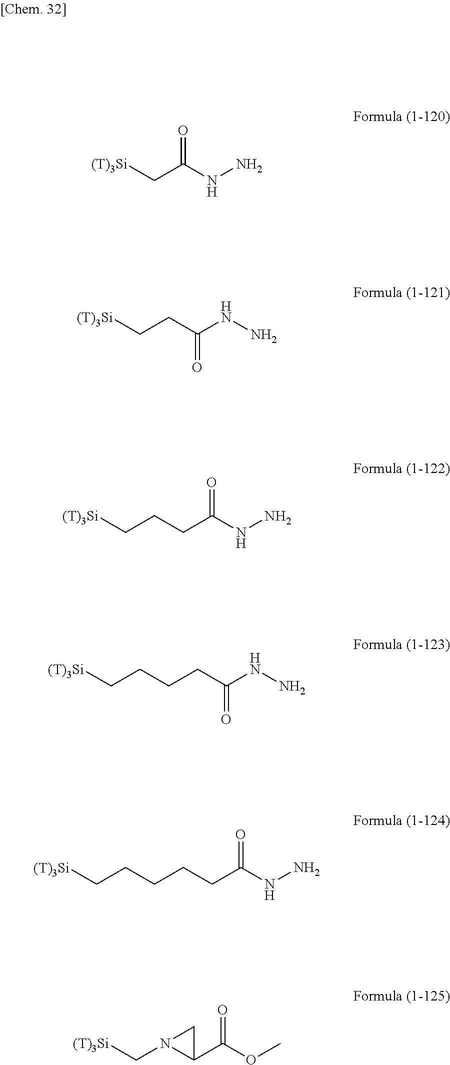

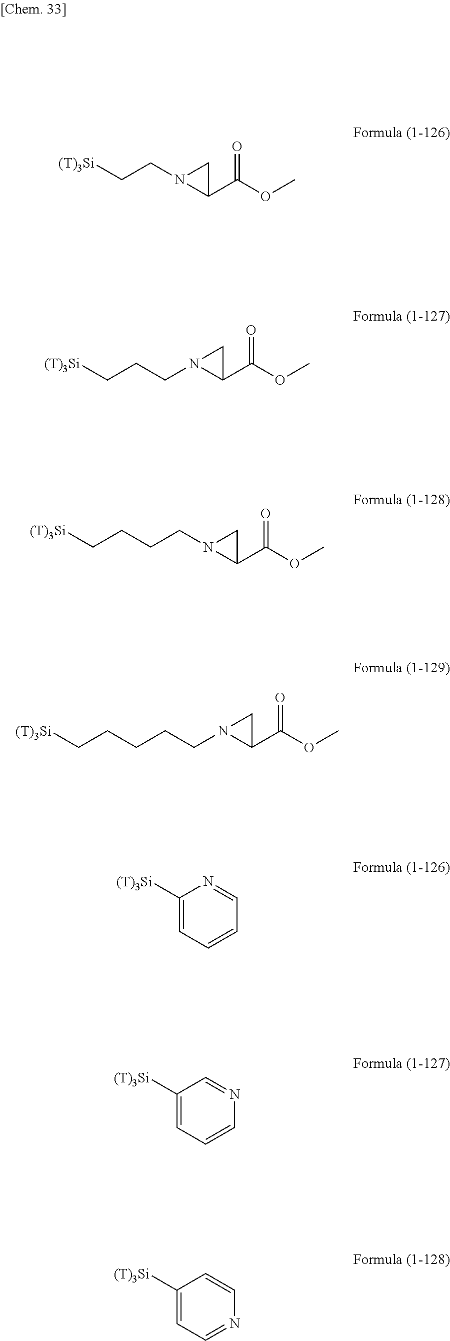

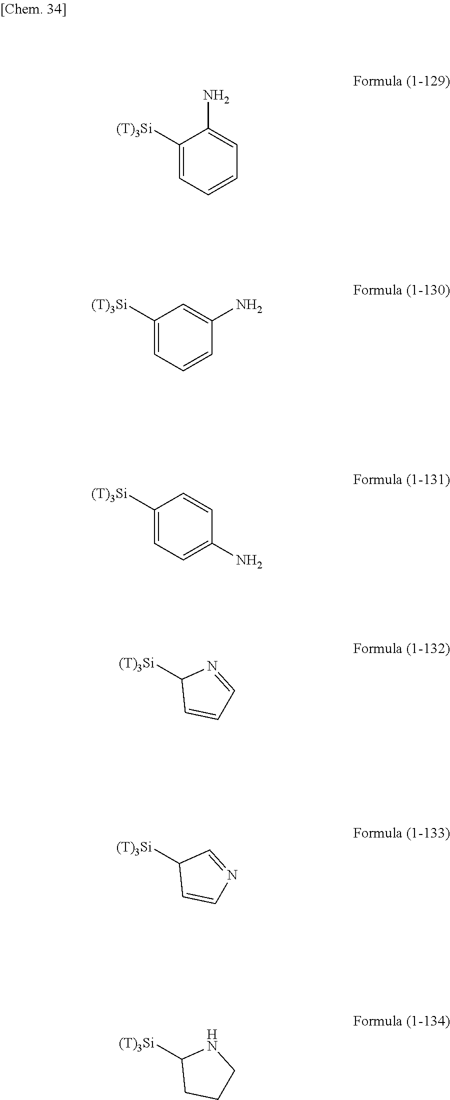

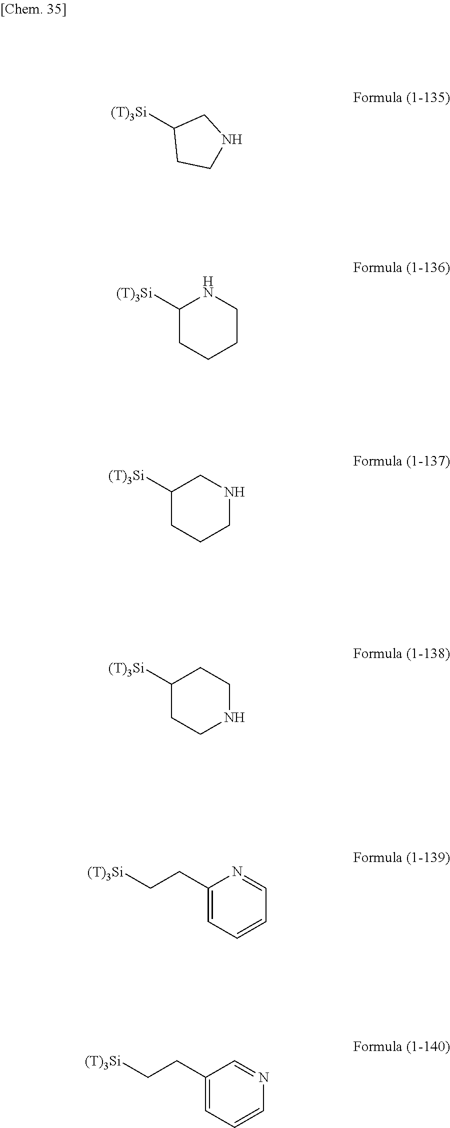

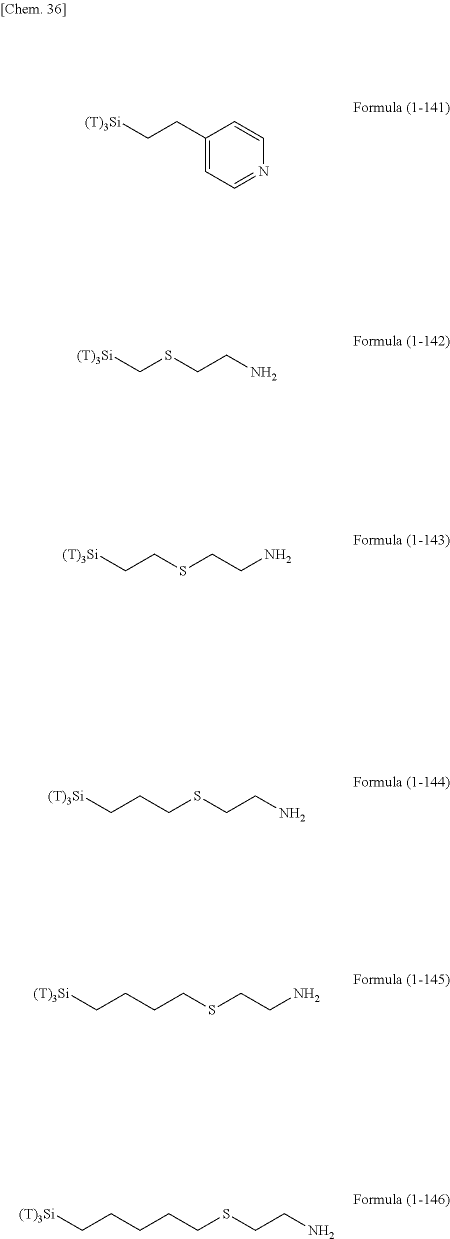

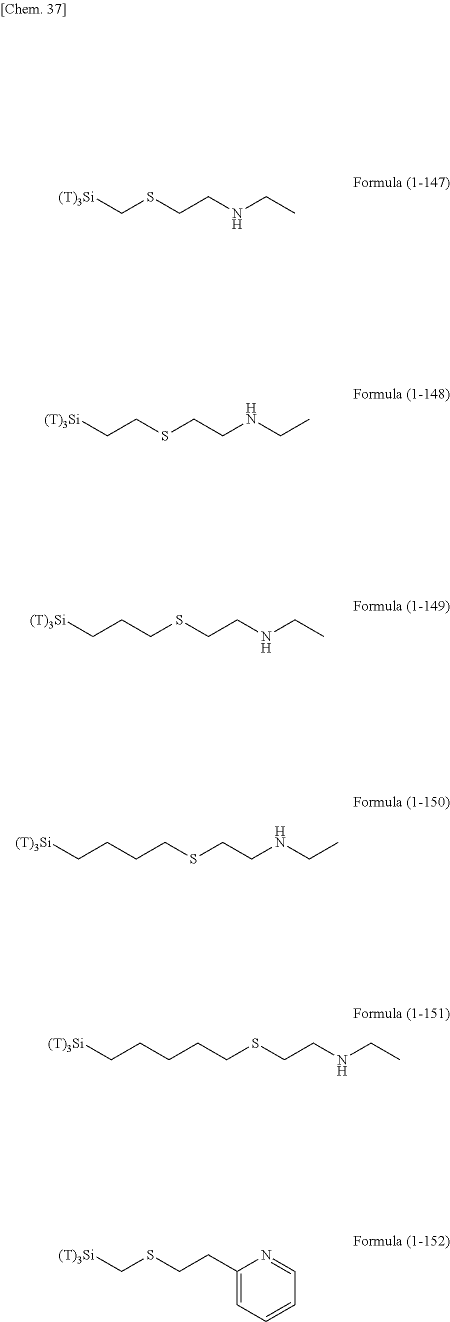

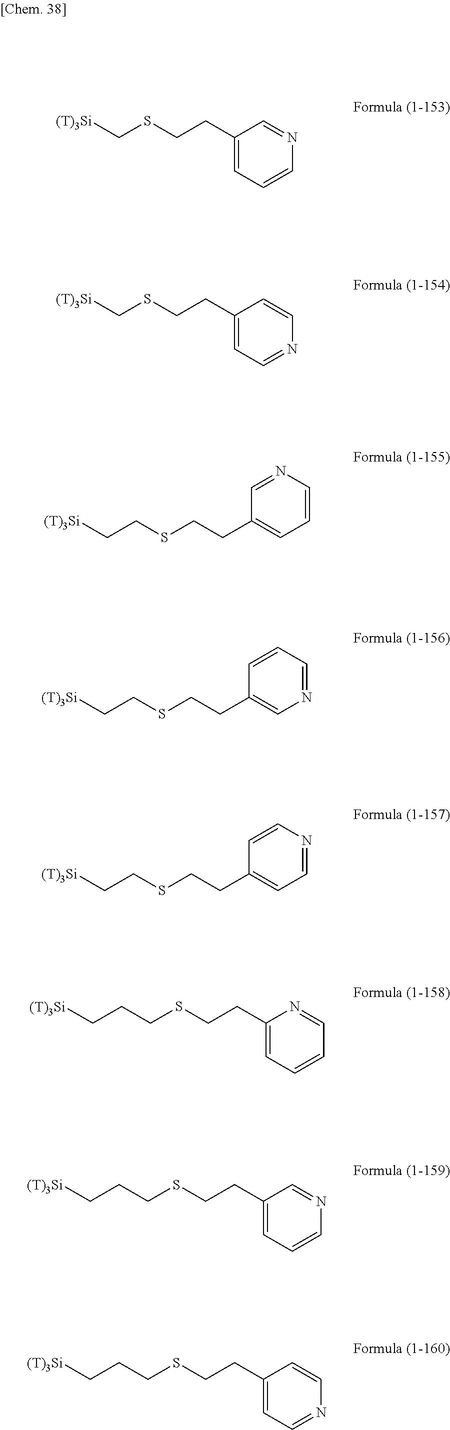

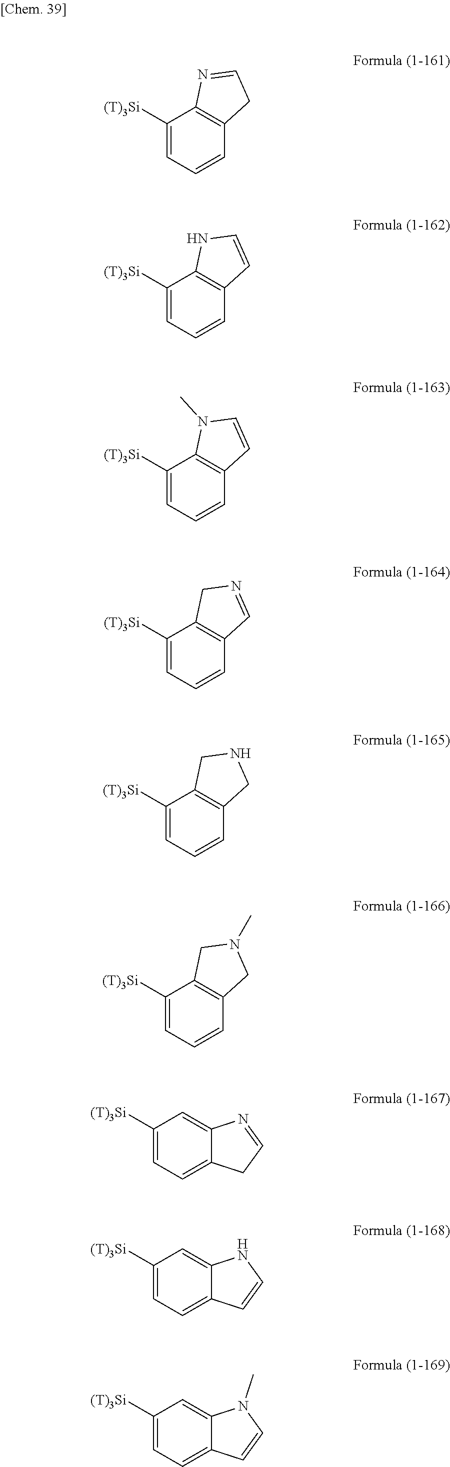

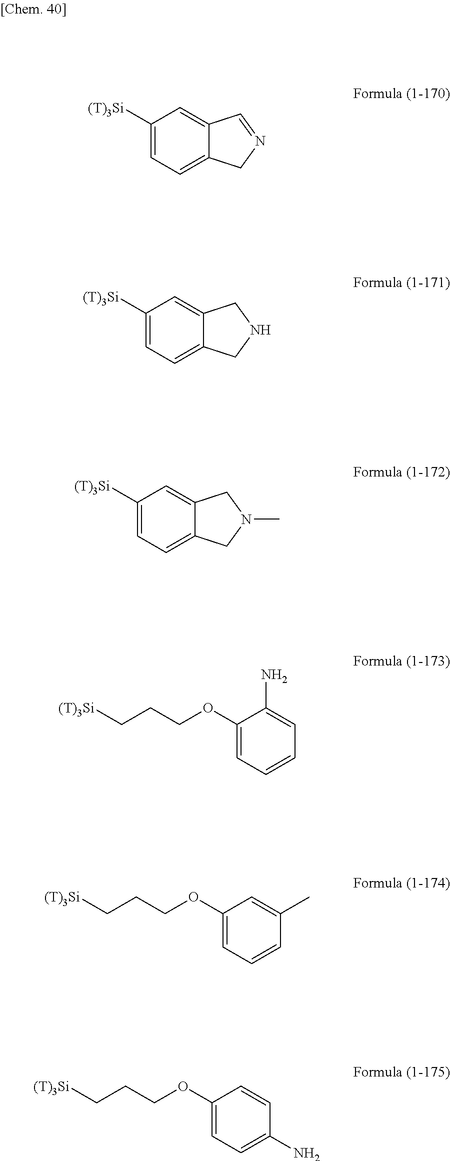

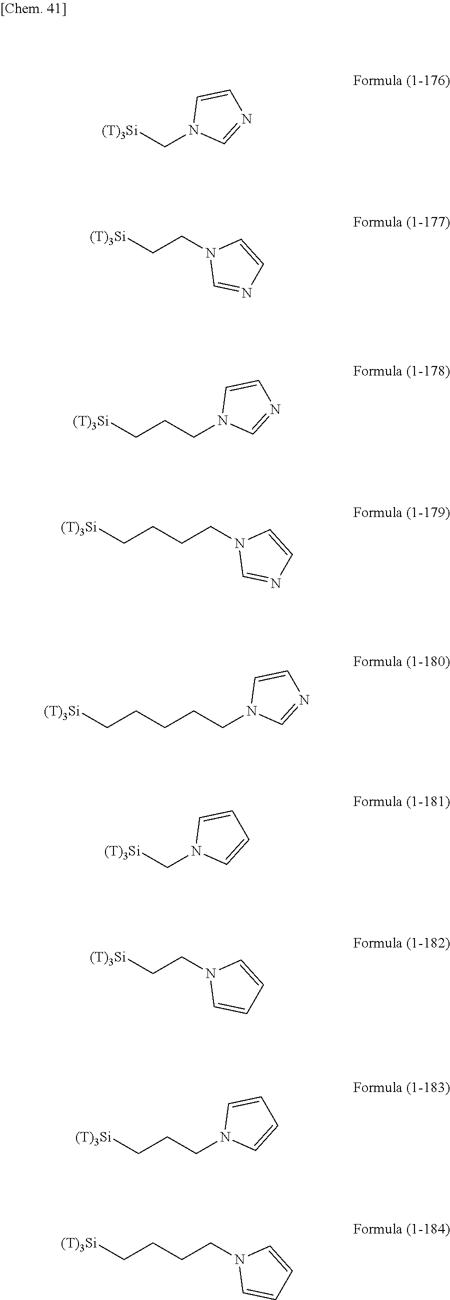

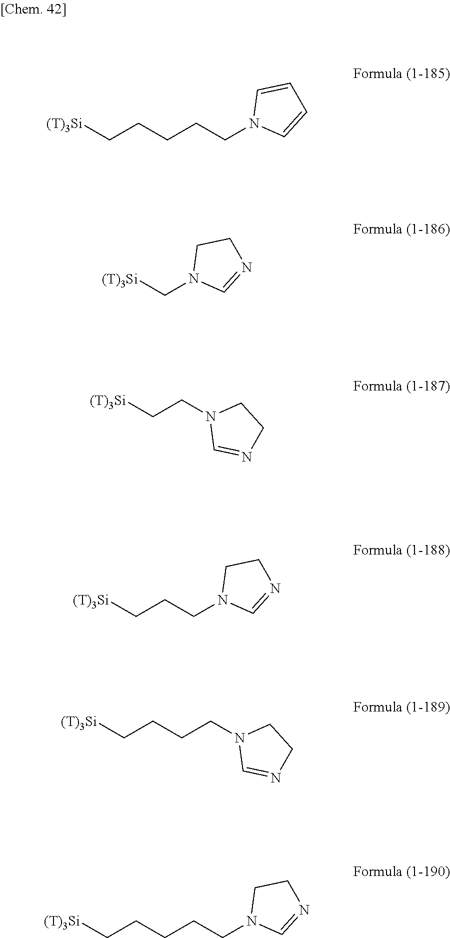

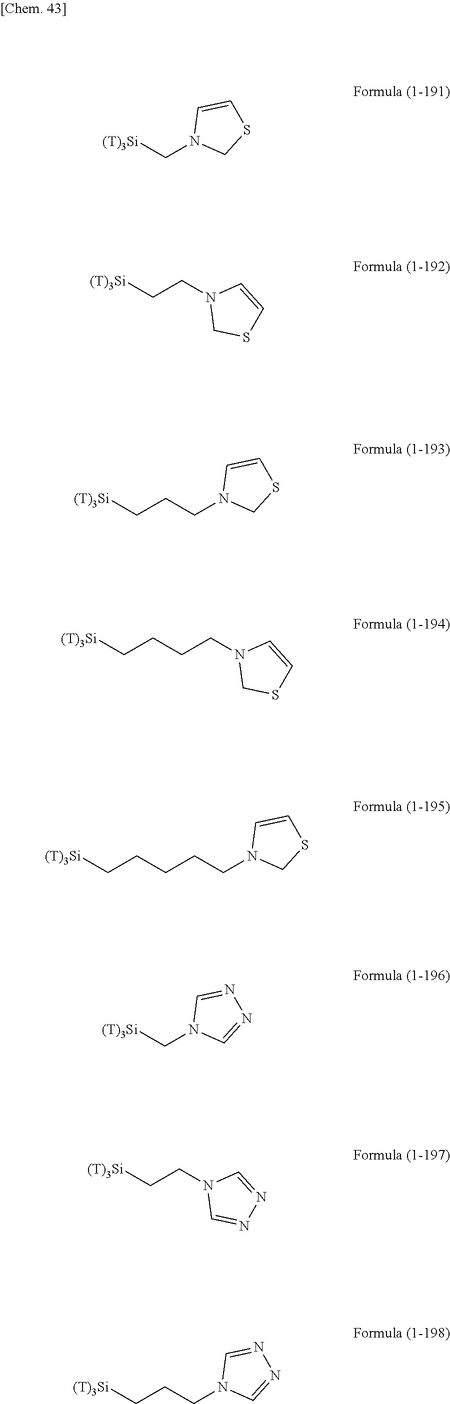

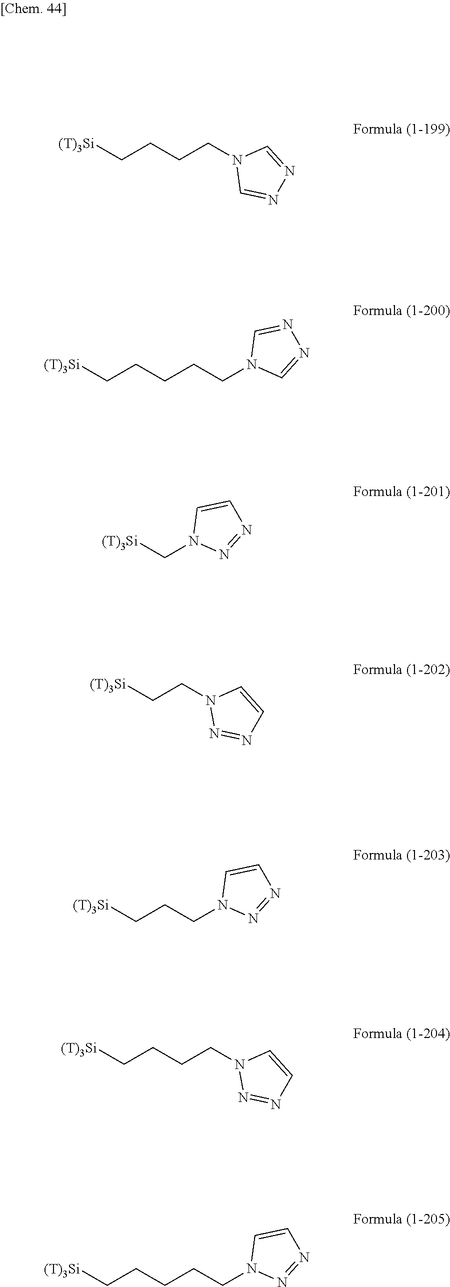

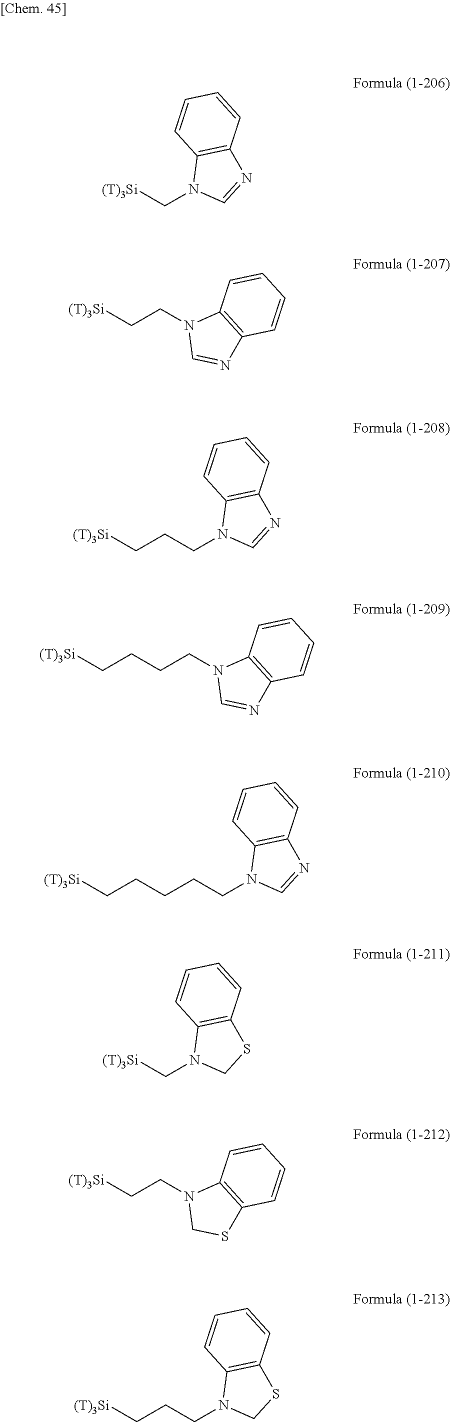

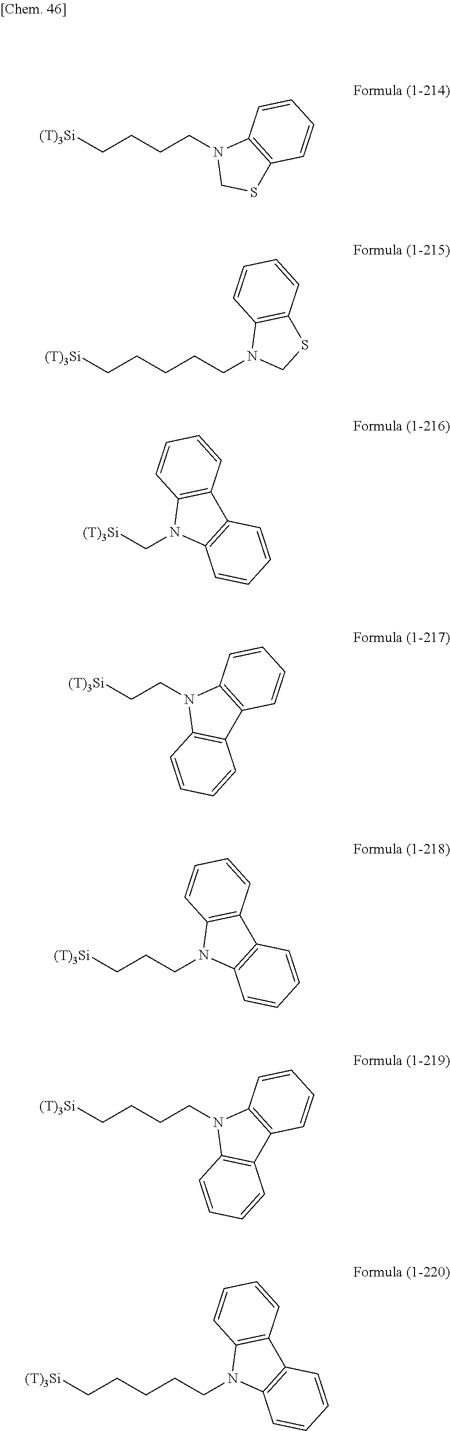

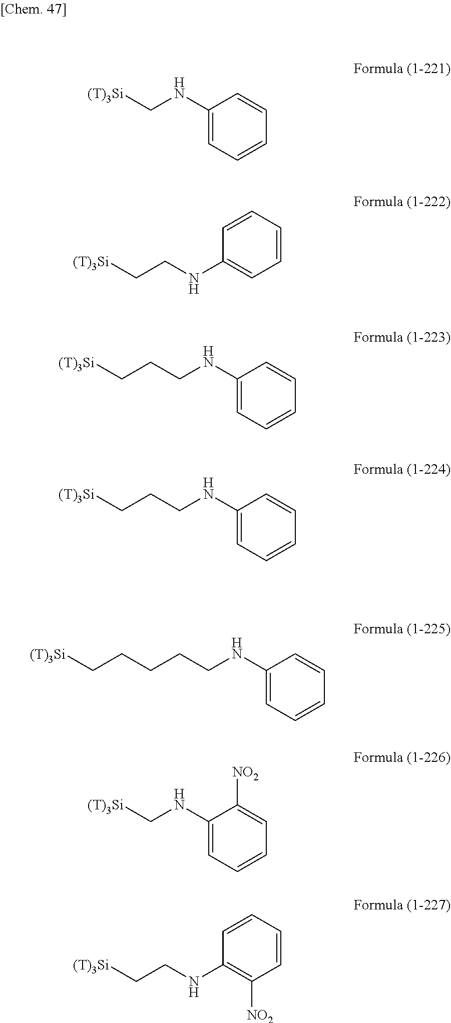

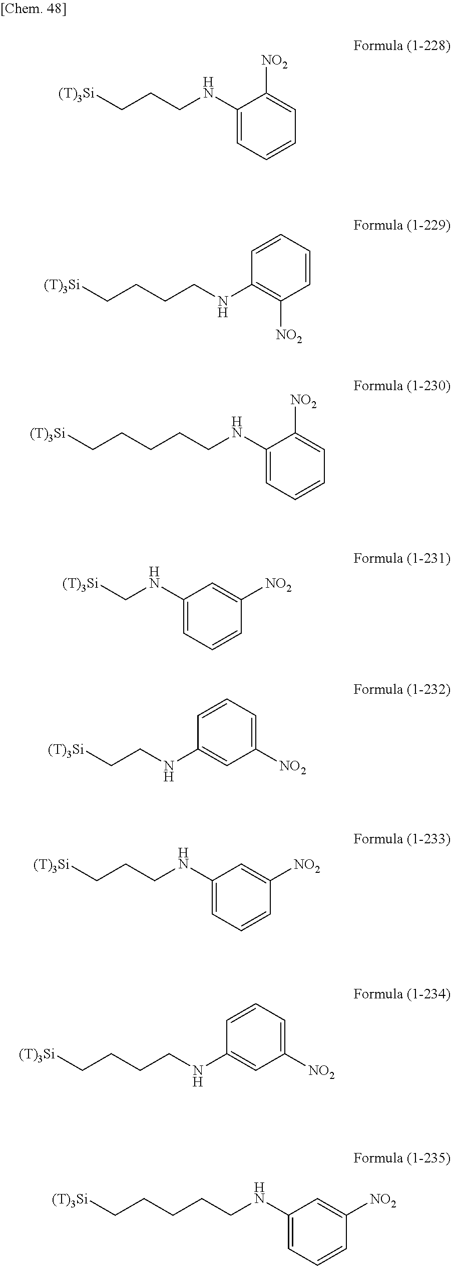

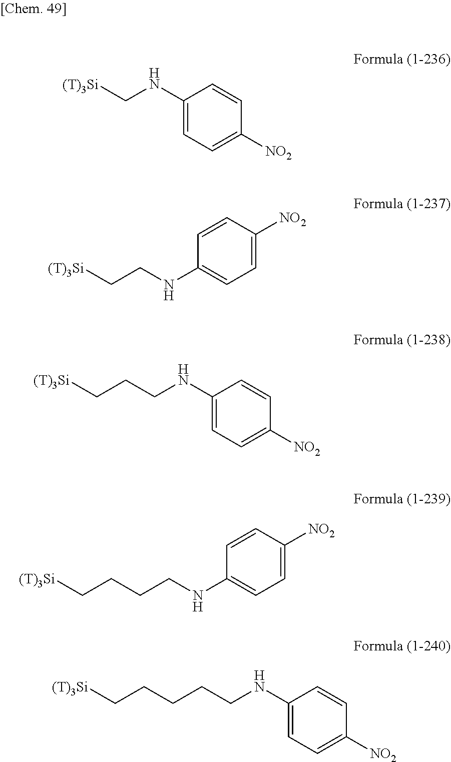

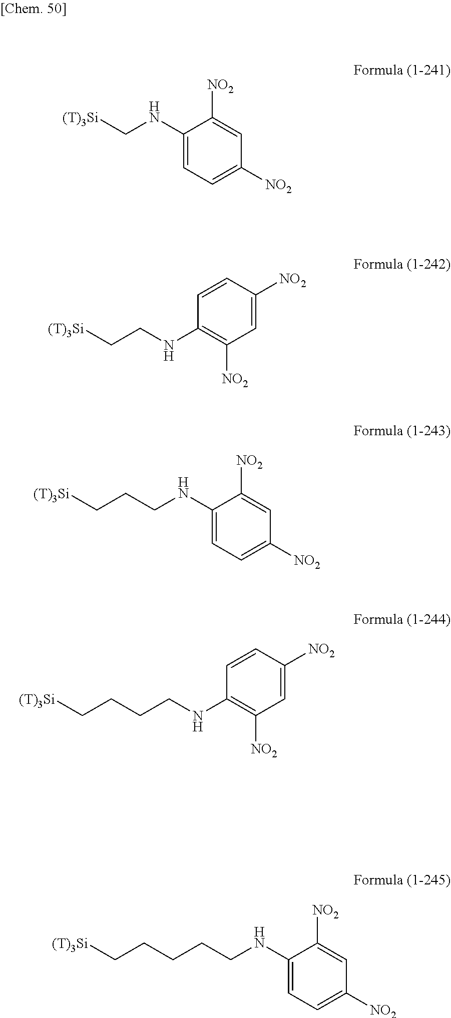

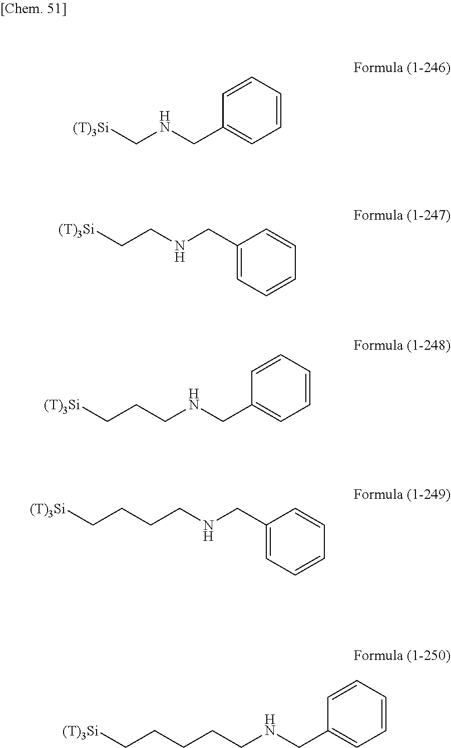

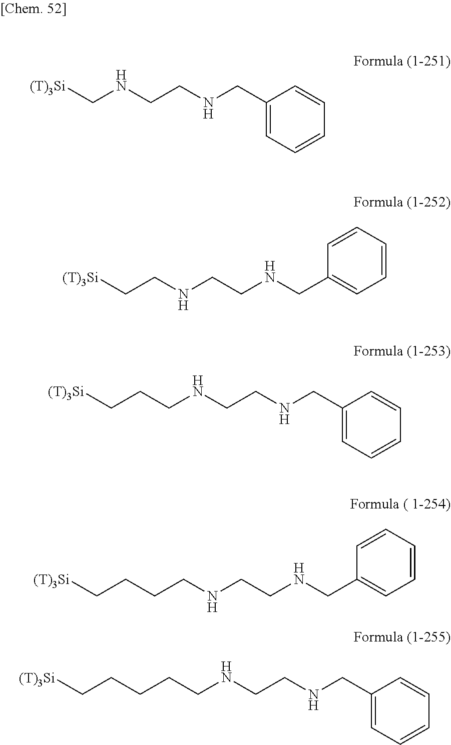

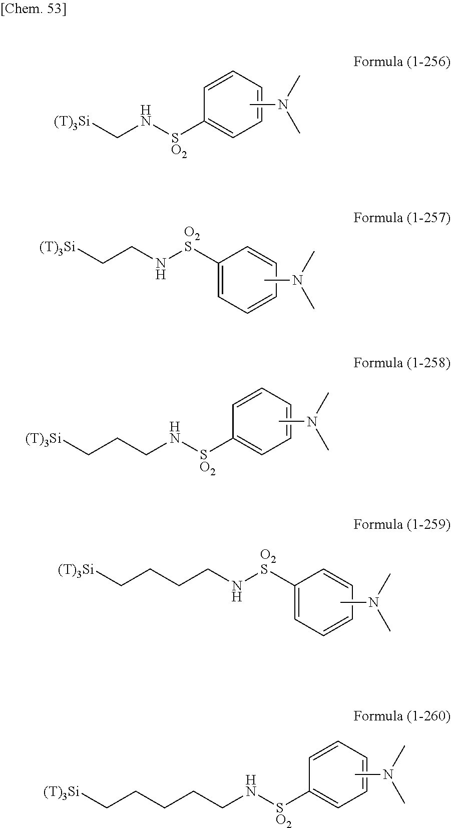

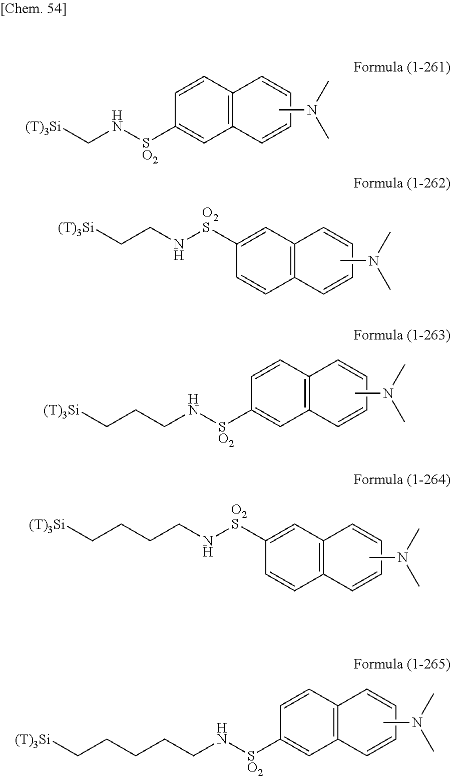

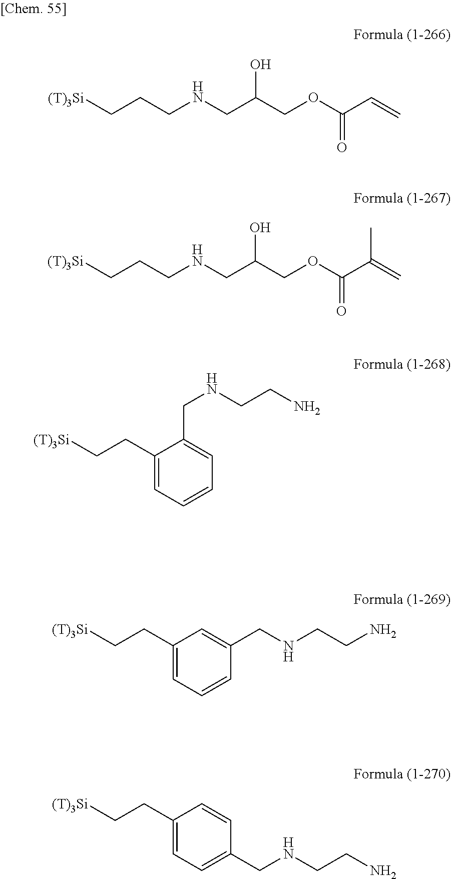

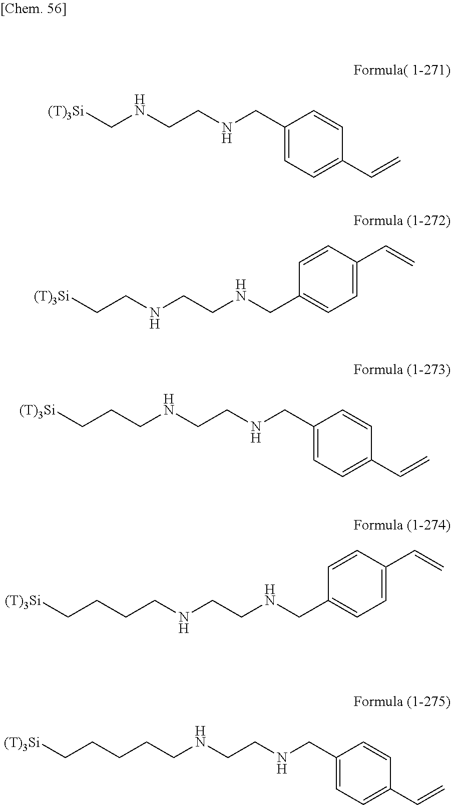

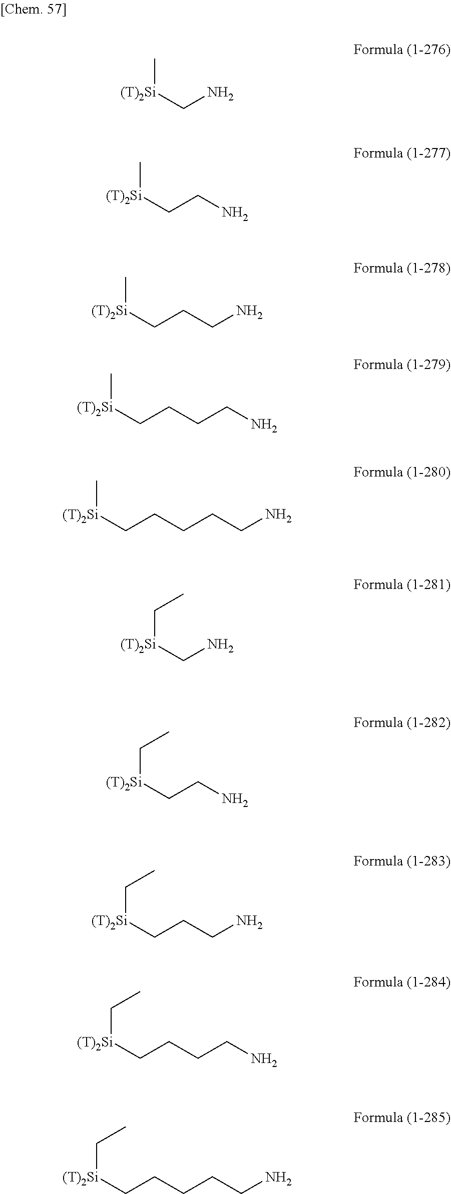

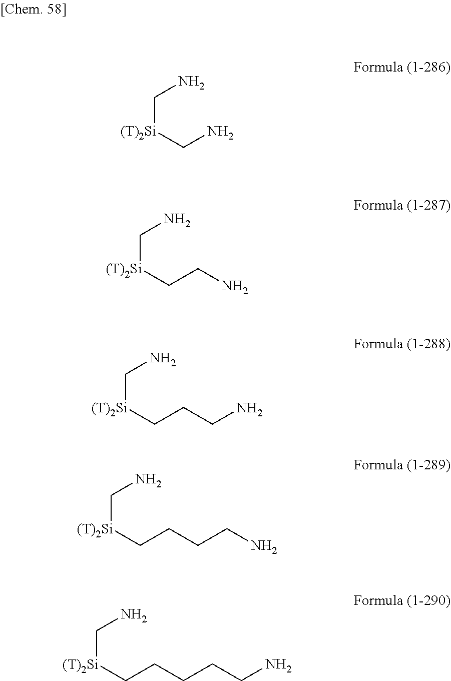

In Formulae (1-1) to (1-290), Ts each independently represent an alkoxy group, an acyloxy group, or a halogen group, and represents preferably a methoxy group or an ethoxy group, for example.

The polysiloxane may be, for example, a hydrolysis condensate of a hydrolyzable silane containing the hydrolyzable silane represented by the following Formula (2) together with the hydrolyzable silane represented by Formula (1) or in place of the hydrolyzable silane represented by Formula (1).

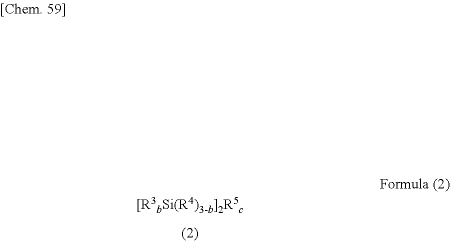

In Formula (2), R³ is a group bonded to a silicon atom, and represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or an organic group having an optionally ring-opened epoxy group, an organic group having an acryloyl group, an organic group having a methacryloyl group, an organic group having a mercapto group, an organic group having an amino group, an organic group having an alkoxy group, an organic group having a sulfonyl group, or an organic group having a cyano group, or a combination of two or more of these groups.

R⁴ is a group or atom bonded to a silicon atom, and each independently represents an alkoxy group, an aralkyloxy group, an acyloxy group, or a halogen atom.

R⁵ is a group bonded to a silicon atom, and each independently represents an alkylene group or an arylene group.

b represents 0 or 1, and c represents 0 or 1.

Specific examples of the groups of R³ and preferred number of carbon atoms thereof are the same as the groups and the number of carbon atoms thereof described above regarding R¹.

Specific examples of the groups and atoms of R⁴ and preferred number of carbon atoms thereof are the same as the groups and the number of carbon atoms thereof described above regarding R².

Specific examples of the alkylene group in R⁵ include, but are not limited to, alkylene groups, for example, linear alkylene groups such as a methylene group, an ethylene group, a trimethylene group, a tetramethylene group, a pentamethylene group, a hexamethylene group, a heptamethylene group, an octamethylene group, a nonamethylene group, a decamethylene group; branched alkylene groups, such as a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group, a 1-ethyltrimethylene group; and alkanetriyl groups, such as a methanetriyl group, an ethane-1,1,2-triyl group, an ethane-1,2,2-triyl group, an ethane-2,2,2-triyl group, a propane-1,1,1-triyl group; a propane-1,1,2-triyl group, a propane-1,2,3-triyl group, a propane-1,2,2-triyl group, a propane-1,1,3-triyl group, a butane-1,1,1-triyl group, a butane-1,1,2-triyl group, a butane-1,1,3-triyl group, a butane-1,2,3-triyl group, a butane-1,2,4-triyl group, a butane-1,2,2-triyl group, a butane-2,2,3-triyl group, a 2-methylpropane-1,1,1-triyl group, a 2-methylpropane-1,1,2-triyl group, and a 2-methylpropane-1,1,3-triyl group.

Specific examples of the arylene group in R⁵ include, but are not limited to, a 1,2-phenylene group, a 1,3-phenylene group, a 1,4-phenylene group; groups derived from a condensed-ring aromatic hydrocarbon compound through removal of two hydrogen atoms on the aromatic ring, such as a 1,5-naphthalenediyl group, a 1,8-naphthalenediyl group, a 2,6-naphthalenediyl group, a 2,7-naphthalenediyl group, a 1,2-anthracenediyl group, a 1,3-anthracenediyl group, a 1,4-anthracenediyl group, a 1,5-anthracenediyl group, a 1,6-anthracenediyl group, a 1,7-anthracenediyl group, a 1,8-anthracenediyl group, a 2,3-anthracenediyl group, a 2,6-anthracenediyl group, a 2,7-anthracenediyl group, a 2,9-anthracenediyl group, a 2,10-anthracenediyl group, and a 9,10-anthracenediyl group; and groups derived from a linked-ring aromatic hydrocarbon compound through removal of two hydrogen atoms on the aromatic ring, such as a 4,4′-biphenyldiyl group and a 4,4″-p-terphenyldiyl group.

b is preferably 0.

c is preferably 1.

Specific examples of the hydrolyzable silane represented by Formula (2) include, but are not limited to, methylenebistrimethoxysilane, methylenebistrichlorosilane, methylenebistriacetoxysilane, ethylenebistriethoxysilane, ethylenebistrichlorosilane, ethylenebistriacetoxysilane, propylenebistriethoxysilane, butylenebistrimethoxysilane, phenylenebistrimethoxysilane, phenylenebistriethoxysilane, phenylenebismethyldiethoxysilane, phenylenebismethyldimethoxysilane, naphthylenebistrimethoxysilane, bistrimethoxysilane, bistrimethoxydisilane, bistriethoxydisilane, bisethyldiethoxydisilane, and bismethyldimethoxydisilane.

The polysiloxane may be, for example, a hydrolysis condensate of a hydrolyzable silane containing the hydrolyzable silane represented by Formula (1) and/or the hydrolyzable silane represented by Formula (2) or in place of an additional hydrolyzable silane described below.

Examples of other hydrolyzable silanes include, but are not limited to, silane compounds having an onium group in the molecule, silane compounds having a sulfone group, silane compounds having a sulfonamide group, and silane compounds having a cyclic urea skeleton in the molecule.

### ———Silane Compounds (Hydrolyzable Organosilanes) Having Onium Group in Molecule———

A silane compound having an onium group in the molecule is expected to effectively and efficiently promote the crosslinking reaction of a hydrolyzable silane.

One preferred example of the silane compound having an onium group in the molecule is shown in Formula (3).

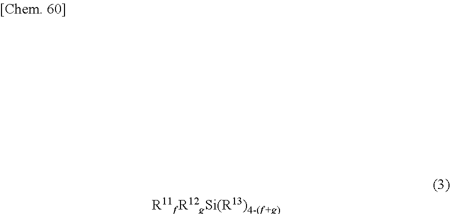

R¹¹ is a group bonded to a silicon atom, and represents an onium group or an organic group having the onium group.

R¹² is a group bonded to a silicon atom, and each independently represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or an organic group having an optionally ring-opened epoxy group, an organic group having an acryloyl group, an organic group having a methacryloyl group, an organic group having a mercapto group, an organic group having an amino group, or an organic group having a cyano group, or a combination of two or more of these groups.

R¹³ is a group or atom bonded to a silicon atom, and each independently represents an alkoxy group, an aralkyloxy group, an acyloxy group, or a halogen atom.

f represents 1 or 2, g represents 0 or 1, and 1≤f+g≤2 is satisfied.

Specific examples of the alkyl group, the aryl group, the aralkyl group, the alkyl halide group, the aryl halide group, the aralkyl halide group, the alkoxyalkyl group, the alkoxyaryl group, the alkoxyaralkyl group, the alkenyl group, and the organic group having an optionally ring-opened epoxy group, the organic group having an acryloyl group, the organic group having a methacryloyl group, the organic group having a mercapto group, the organic group having an amino group and the organic group having a cyano group, the alkoxy group, the aralkyloxy group, the acyloxy group, and the halogen atom, specific examples of substituents of the alkyl group, the aryl group, the aralkyl group, the alkyl halide, the aryl halide group, the aralkyl halide group, the alkoxyaryl group, the alkoxyaralkyl group, and the alkenyl group, and the preferred number of carbon atoms thereof include, for R¹², those described above with regard to R¹, and for R¹³, those described above with regard to R².

More specifically, the onium group is, for example, a cyclic ammonium group or a chain ammonium group, and is preferably a tertiary ammonium group or a quaternary ammonium group.

That is, preferred specific examples of the onium group or the organic group having the onium group include a cyclic ammonium group, a chain ammonium group, or an organic group containing at least one of the cyclic ammonium group or the chain ammonium group. Preferred is a tertiary ammonium group or a quaternary ammonium group or an organic group containing at least one of the tertiary ammonium group or the quaternary ammonium group.

When the onium group is a cyclic ammonium group, a nitrogen atom forming the ammonium group also serves as an atom constituting the ring. In this case, the nitrogen atom forming the ring and the silicon atom are bonded directly or via a divalent linking group, or the carbon atom forming the ring and the silicon atom are bonded directly or via a divalent linking group.

In one preferred aspect, R¹¹, i.e. the group bonding to the silicon atom, is a heteroaromatic cyclic ammonium group represented by the following Formula (S1).

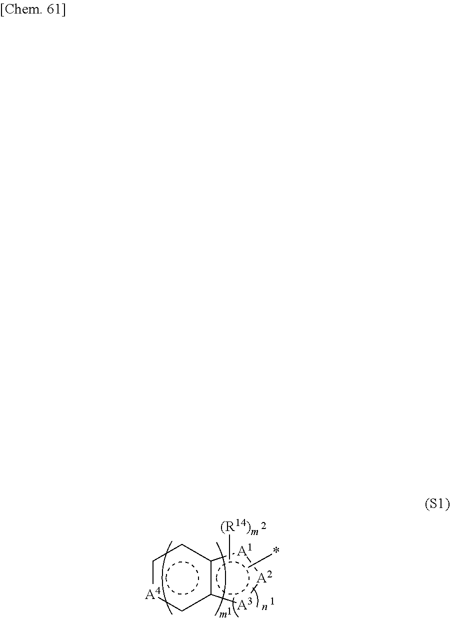

In Formula (S1), A¹, A², A³, and A⁴ each independently represent a group represented by any one of the following Formulae (J1) to (J3), and at least one of A¹ to A⁴ is a group represented by the following Formula (J2). The bond between each of A¹ to A⁴ and the atom adjacent thereto and constituting the ring is determined to be a single bond or a double bond according to which of A¹ to A⁴ the silicon atom in Formula (3) is bonded, such that the constituted ring exhibits aromaticity. An asterisk * represents a bonding hand.

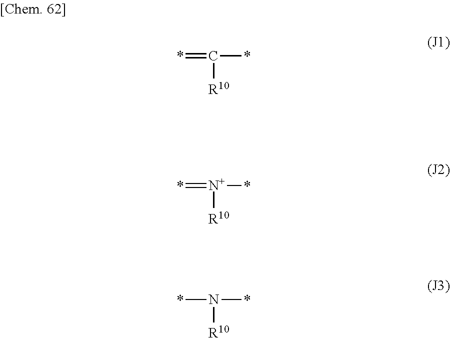

In Formulae (J1) to (J3), each R¹⁰ independently represents a single bond, a hydrogen atom, an alkyl group, an aryl group, an aralkyl group, an alkyl halide group, an aryl halide group, an aralkyl halide group or an alkenyl group. Specific examples of the alkyl group, the aryl group, the aralkyl group, the alkyl halide group, the aryl halide group, the aralkyl halide group, and the alkenyl group, and the preferred number of carbon atoms thereof are the same as those described above. An asterisk * represents a bonding hand.

In Formula (S1), each R¹⁴ independently represents an alkyl group, an aryl group, an aralkyl group, an alkyl halide group, an aryl halide group, an aralkyl halide group, an alkenyl group or a hydroxy group. When two or more R¹⁴s are present, the two R¹⁴s may be bonded to each other to form a ring. A ring formed by two R¹⁴s may have a crosslinked ring structure, and in such a case, the cyclic ammonium group has an adamantane ring, a norbornene ring, a spiro ring or the like.

Specific examples of such an alkyl group, an aryl group, an aralkyl group, an alkyl halide group, an aryl halide group, an aralkyl halide group, and an alkenyl group, and the preferred number of carbon atoms thereof are the same as those described above.

In Formula (S1), n¹ is an integer of 1 to 8, m¹ is 0 or 1, and m² is 0 or a positive integer ranging from 1 to the possible maximum number being substituted on a monocyclic or polycyclic ring.

When m¹ is 0, a (4+n¹)-membered ring including A¹ to A⁴ is formed. That is, when n¹ is 1, a 5-membered ring is formed; when n¹ is 2, a δ-membered ring is formed; when n¹ is 3, a 7-membered ring is formed; when n¹ is 4, an 8-membered ring is formed; when n¹ is 5, a 9-membered ring is formed; when n¹ is 6, a 10-membered ring is formed; when n¹ is 7, a 11-membered ring is formed; and when n¹ is 8, a 12-membered ring is formed.

When m¹ is 1, a condensed ring is formed by condensation between a (4+n¹)-membered ring including A¹ to A³ and a 6-membered ring including A⁴.

Since each of A¹ to A⁴ is any of the groups of Formulae (J1) to (J3), the ring-forming atom has or does not have a hydrogen atom. In each of A¹ to A⁴, when the ring-forming atom has a hydrogen atom, the hydrogen atom may be substituted with R¹⁴. Alternatively, a ring-forming atom other than the ring-forming atom in each of A¹ to A⁴ may be substituted with R¹⁴. Because of such circumstances, as described above, m² is selected from 0 or an integer ranging from 1 to the possible maximum number being substituted on a monocyclic or polycyclic ring.

The bonding hand of the heteroaromatic cyclic ammonium group represented by Formula (S1) is present on any carbon atom or nitrogen atom present in such a monocyclic ring or condensed ring, and is directly bonded to a silicon atom. Alternatively, the bonding hand is bonded to a linking group to form an organic group containing the cyclic ammonium group, and the organic group is bonded to a silicon atom.

Examples of the linking group include, but are not limited thereto, an alkylene group, an arylene group, and an alkenylene group.

Specific examples of the alkylene group and the arylene group and preferred number of carbon atoms are the same as those described above.

The alkenylene group is a divalent group derived by further removing one hydrogen atom from the alkenyl group, and specific examples of the alkenyl group are the same as those described above. The number of carbon atoms in the alkenylene group is not particularly limited, but is preferably 40 or less, more preferably 30 or less, and still more preferably 20 or less.

Specific examples thereof include, but are not limited thereto, vinylene, 1-methylvinylene, propenylene, 1-butenylene, 2-butenylene, 1-pentenylene, and 2-pentenylene group.

Specific examples of the silane compound (hydrolyzable organosilane) represented by Formula (3) having the heteroaromatic cyclic ammonium group represented by Formula (S1) include, but are not limited to, silanes represented by the following Formulae (I-1) to (I-50).

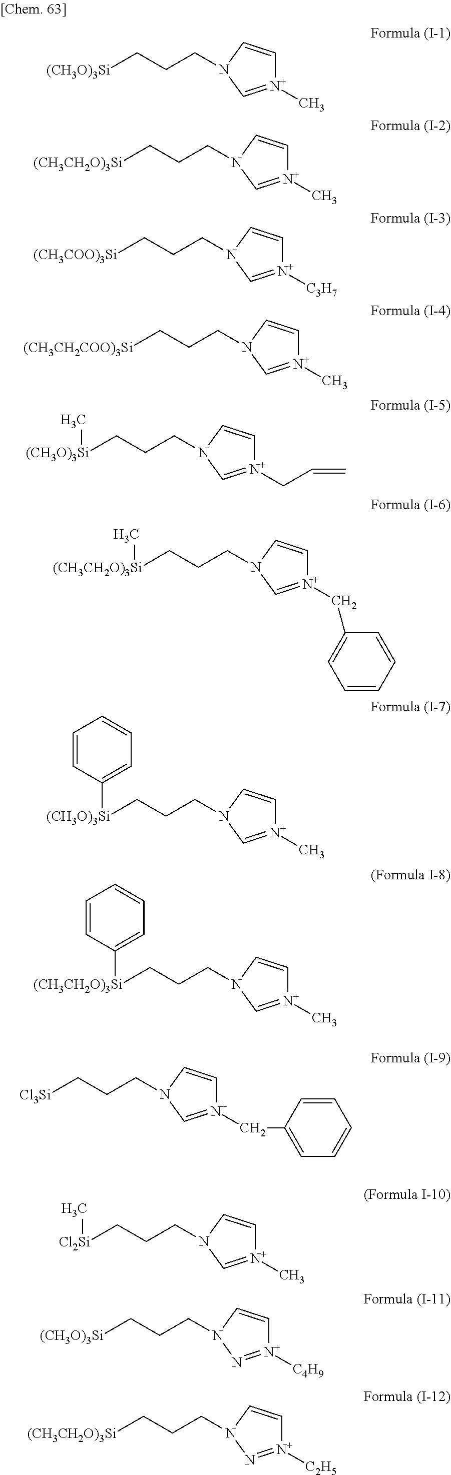

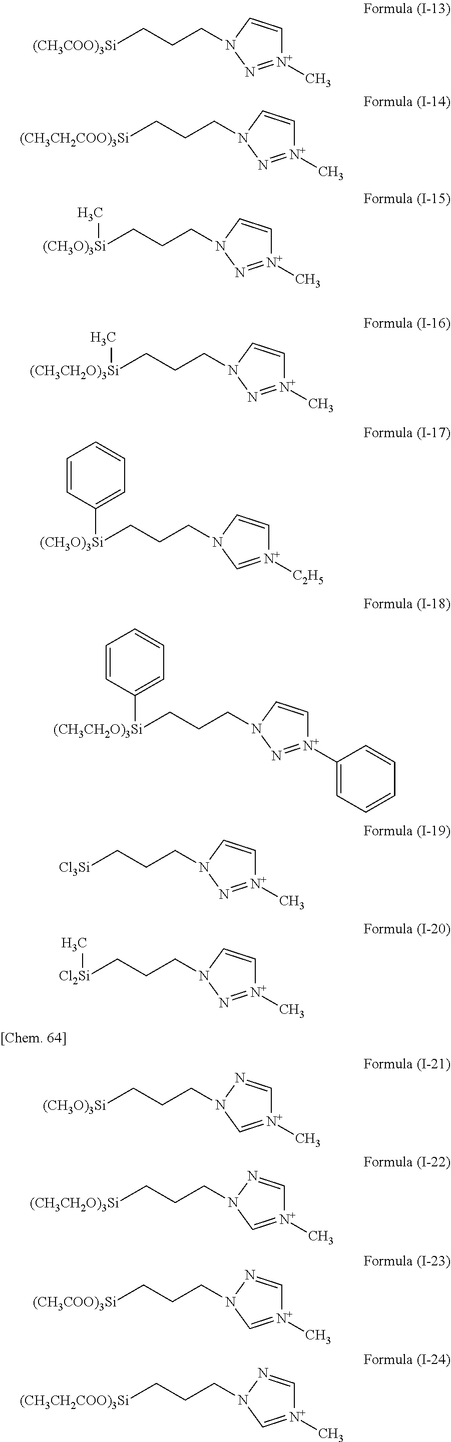

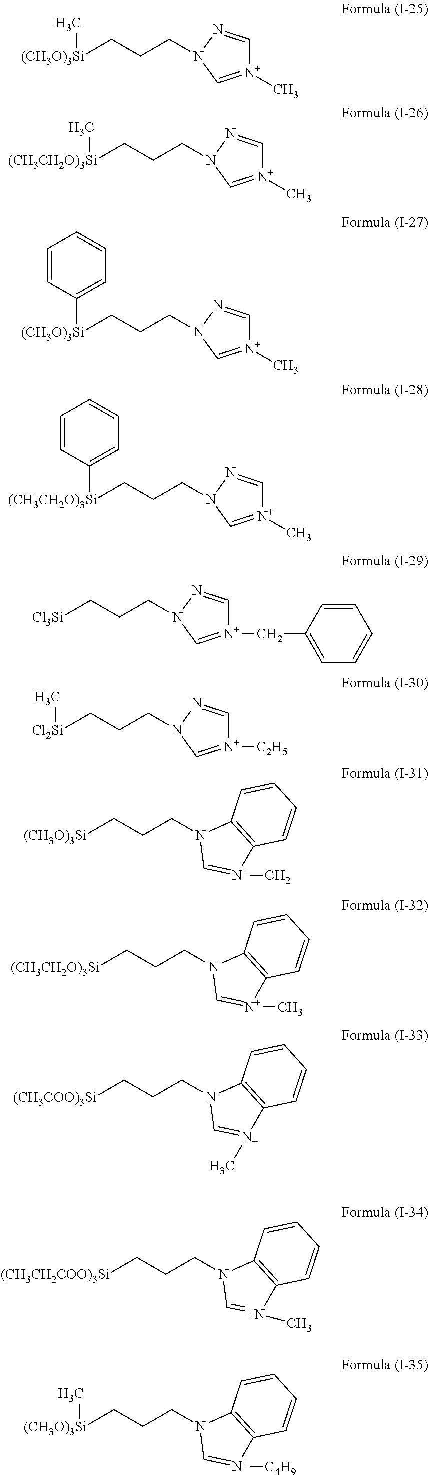

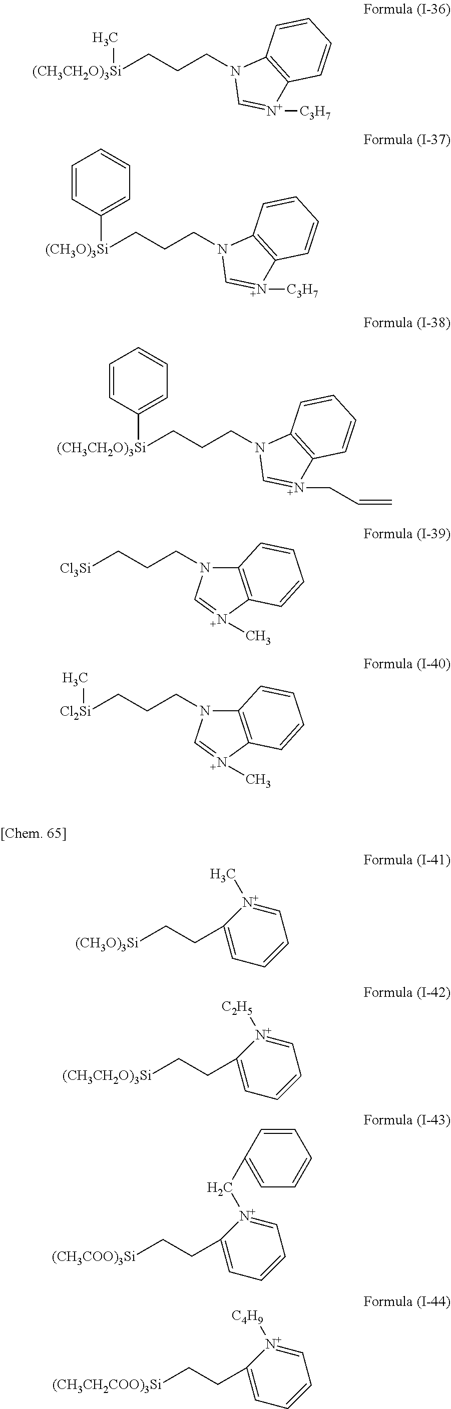

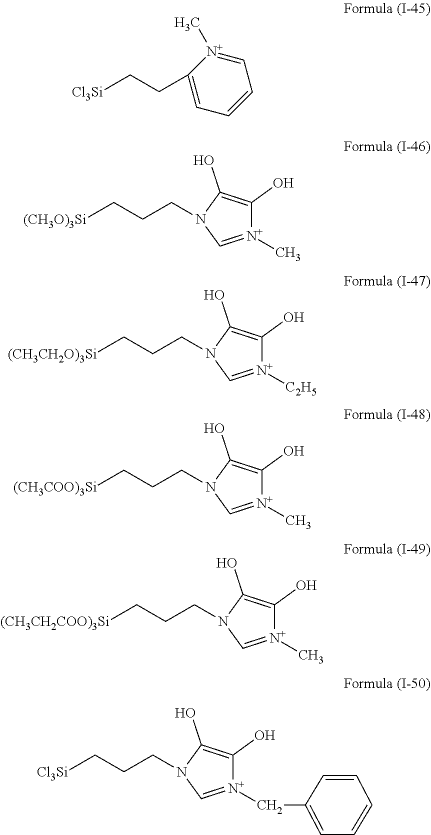

In another example, R¹¹, i.e. the group bonding to the silicon atom in Formula (3), may be a heteroaliphatic cyclic ammonium group represented by the following Formula (S2).

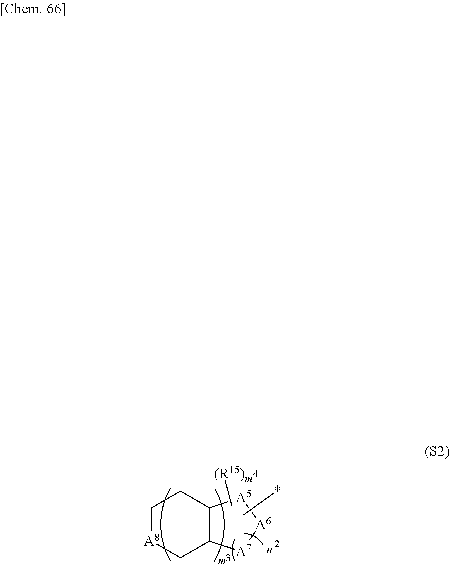

In Formula (S2), A⁵, A⁶, A⁷, and A⁸ each independently represent a group represented by any one of the following Formulae (J4) to (J6), and at least one of A⁵ to A⁸ represents a group represented by the following Formula (J5). Depending on to which atom of A⁵ to A⁸ a silicon atom in Formula (3) is bonded, it is determined whether a bond between any one of A⁵ to A⁸ and a ring-forming atom adjacent to the any one is a single bond or a double bond so that the ring to be formed exhibits non-aromaticity. An asterisk * represents a bonding hand.

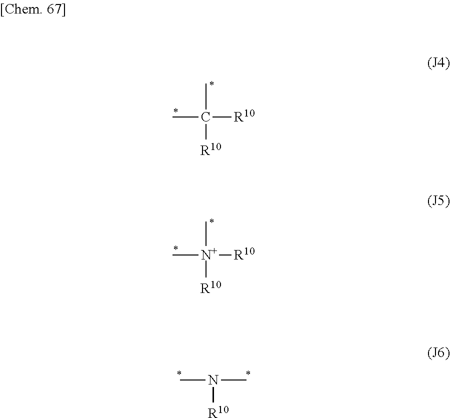

In Formulae (J4) to (J6), each R¹⁰ independently represents a single bond, a hydrogen atom, an alkyl group, an aryl group, an aralkyl group, an alkyl halide group, an aryl halide group, an aralkyl halide group or an alkenyl group. Specific examples of the alkyl group, the aryl group, the aralkyl group, the alkyl halide group, the aryl halide group, the aralkyl halide group, and the alkenyl group, and the preferred number of carbon atoms thereof are the same as those described above. Each asterisk * represents a bonding hand.

In Formula (S2), each R¹⁵ independently represents an alkyl group, an aryl group, an aralkyl group, an alkyl halide group, an aryl halide group, an aralkyl halide group, an alkenyl group or a hydroxy group. When two or more R¹⁵s are present, the two R¹⁵s may be bonded to each other to form a ring. A ring formed by two R¹⁵s may have a crosslinked ring structure, and in such a case, the cyclic ammonium group has an adamantane ring, a norbornene ring, a spiro ring or the like.

Specific examples of the alkyl group, the aryl group, the aralkyl group, the alkyl halide group, the aryl halide group, the aralkyl halide group, and the alkenyl group, and the preferred number of carbon atoms thereof are the same as those described above.

In Formula (S2), n² is an integer of 1 to 8, m³ is 0 or 1, and m⁴ is 0 or a positive integer ranging from 1 to the possible maximum number being substituted on a monocyclic or polycyclic ring.

When m³ is 0, a (4+n²)-membered ring including A⁵ to A⁸ is formed. That is, when n² is 1, a 5-membered ring is formed; when n² is 2, a δ-membered ring is formed; when n² is 3, a 7-membered ring is formed; when n² is 4, an 8-membered ring is formed; when n² is 5, a 9-membered ring is formed; when n² is 6, a 10-membered ring is formed; when n² is 7, a 11-membered ring is formed; and when n² is 8, a 12-membered ring is formed.

When m³ is 1, a condensed ring is formed by condensation between a (4+n²)-membered ring including A⁵ to A⁷ and a 6-membered ring including A⁸.

Since each of A⁵ to A⁸ is any of the groups of Formulae (J4) to (J6), the ring-forming atom has or does not have a hydrogen atom. In each of A⁵ to A⁸, when the ring-forming atom has a hydrogen atom, the hydrogen atom may be substituted with R¹⁵. Alternatively, a ring-forming atom other than the ring-forming atom in each of A⁵ to A⁸ may be substituted with R¹⁵.

Because of such circumstances, as described above, m⁴ is selected from 0 or an integer ranging from 1 to the possible maximum number being substituted on a monocyclic or polycyclic ring.

The bonding hand of the heteroaliphatic cyclic ammonium group represented by Formula (S2) is present on any carbon atom or nitrogen atom present in such a monocyclic ring or condensed ring, and is directly bonded to a silicon atom. Alternatively, the bonding hand is bonded to a linking group to form an organic group containing the cyclic ammonium group, and the organic group is bonded to a silicon atom.

The linking group is, for example, an alkylene group, an arylene group, or an alkenylene group. Specific examples of the alkylene group, the arylene group, and the alkenylene group and the preferred number of carbon atoms are the same as those described above.

Specific examples of the silane compound (hydrolyzable organosilane) represented by Formula (3) having the heteroaliphatic cyclic ammonium group represented by Formula (S2) include, but are not limited to, silanes represented by the following Formulae (II-1) to (II-30).

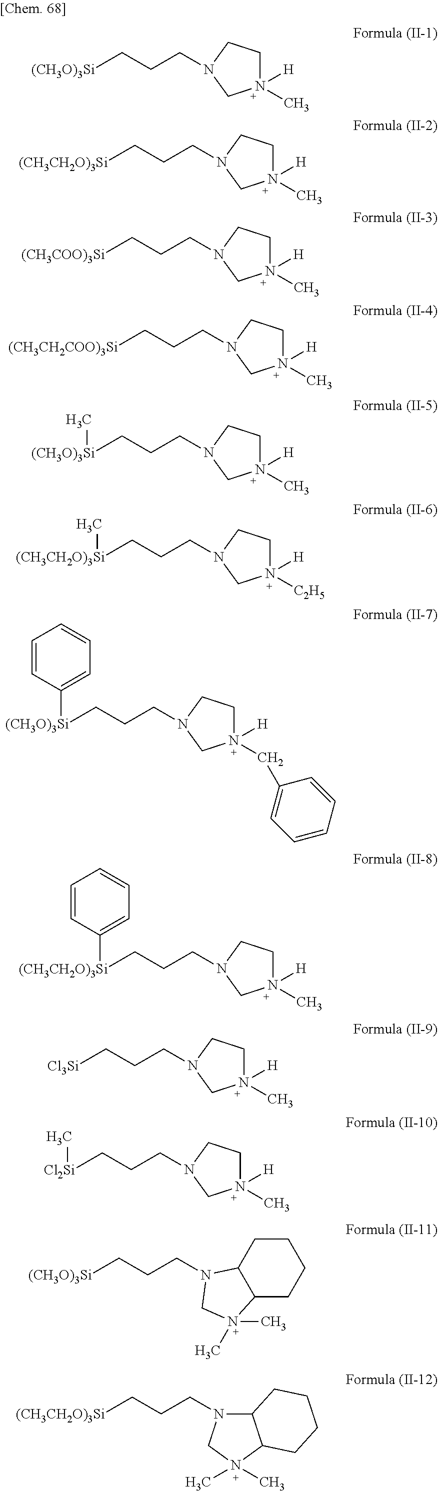

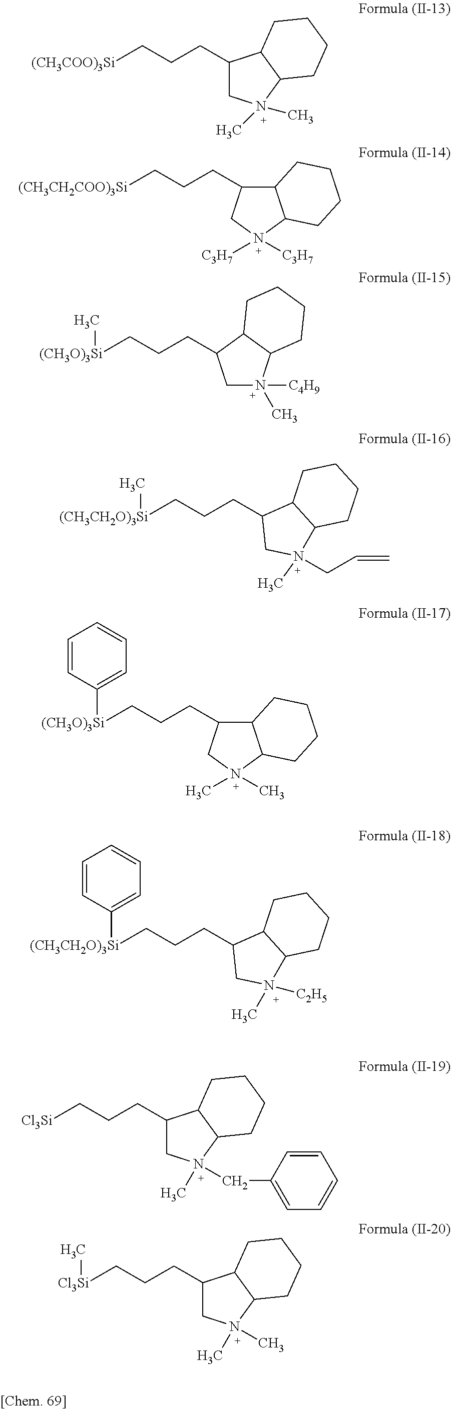

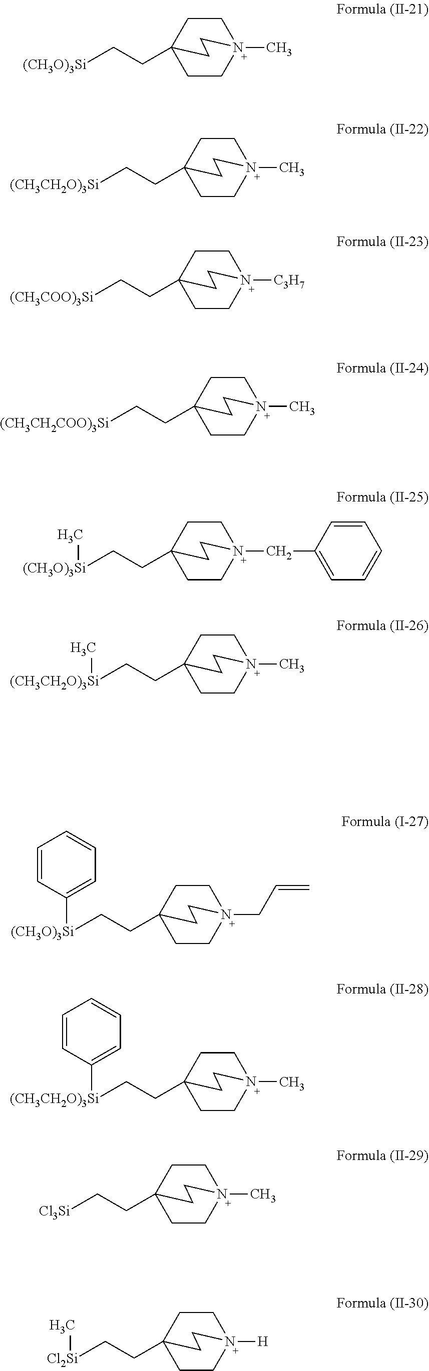

In another example, R¹¹, i.e. the group bonding to the silicon atom in Formula (3), may be a chain ammonium group represented by the following Formula (S3).

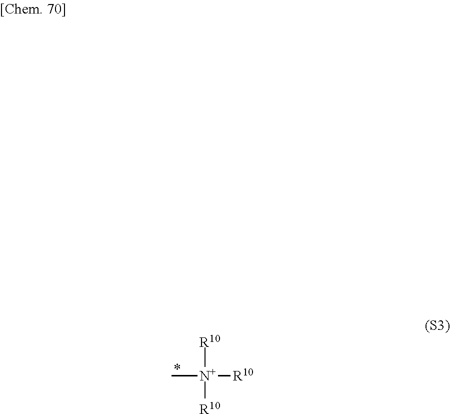

In Formula (S3), each R¹⁰ independently represents a hydrogen atom, an alkyl group, an aryl group, an aralkyl group, an alkyl halide group, an aryl halide group, an aralkyl halide group or an alkenyl group. Specific examples of the alkyl group, the aryl group, the aralkyl group, the alkyl halide group, the aryl halide group, the aralkyl halide group, and the alkenyl group, and the preferred number of carbon atoms thereof are the same as those described above. Each asterisk * represents a bonding hand.

The chain ammonium group represented by Formula (S3) is directly bonded to a silicon atom. Alternatively, the chain ammonium group is bonded to a linking group to form an organic group containing the chain ammonium group, and the organic group is bonded to a silicon atom.

The linking group is, for example, an alkylene group, an arylene group, or an alkenylene group. Specific examples of the alkylene group, the arylene group, and the alkenylene group are the same as those described above.

Specific examples of the silane compound (hydrolyzable organosilane) represented by Formula (3) having the chain ammonium group represented by Formula (S3) include, but are not limited to, silanes represented by the following Formulae (III-1) to (III-28).

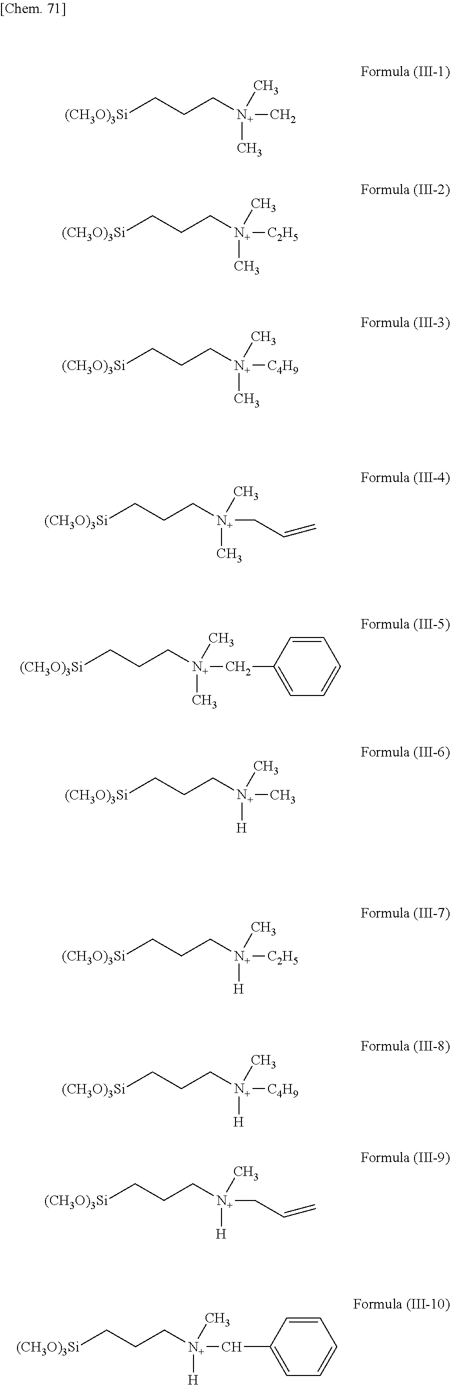

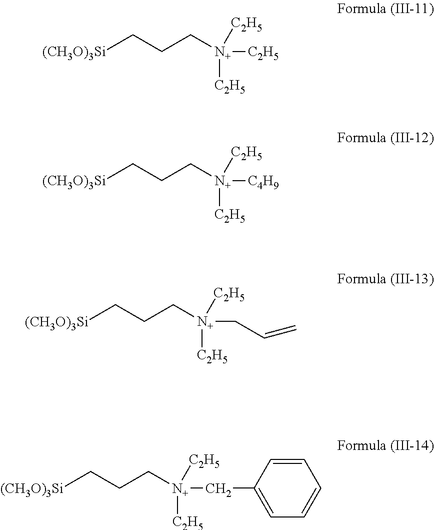

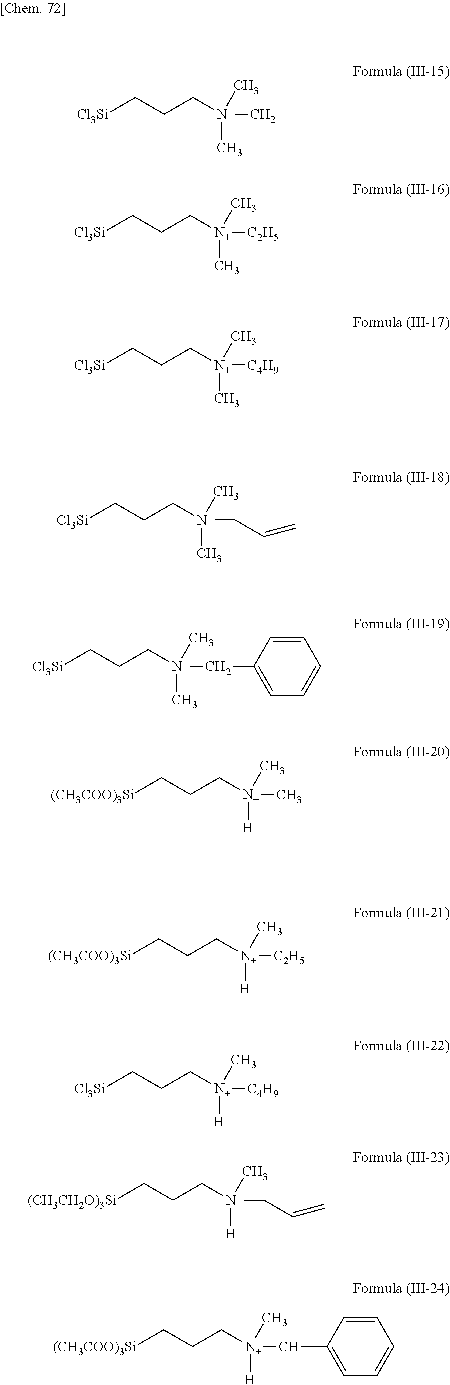

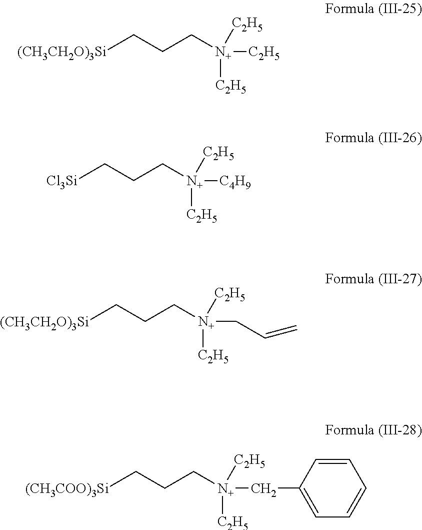

### ———Silane Compounds (Hydrolyzable Organosilanes) Having Sulfone Group or Sulfonamide Group———

Examples of the silane compounds having a sulfone group and the silane compounds having a sulfonamide group include, but are not limited to, compounds represented by the following Formulae (B-1) to (B-36).

In the following Formulae, Me represents a methyl group, and Et represents an ethyl group.

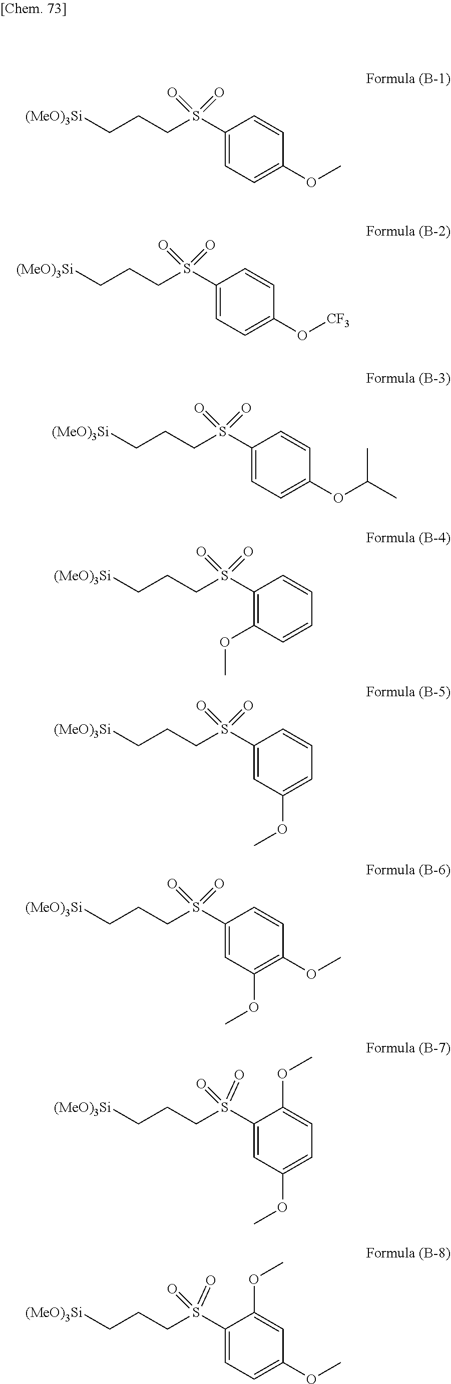

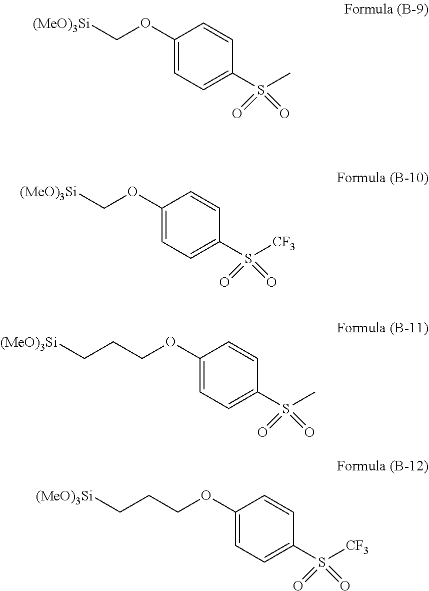

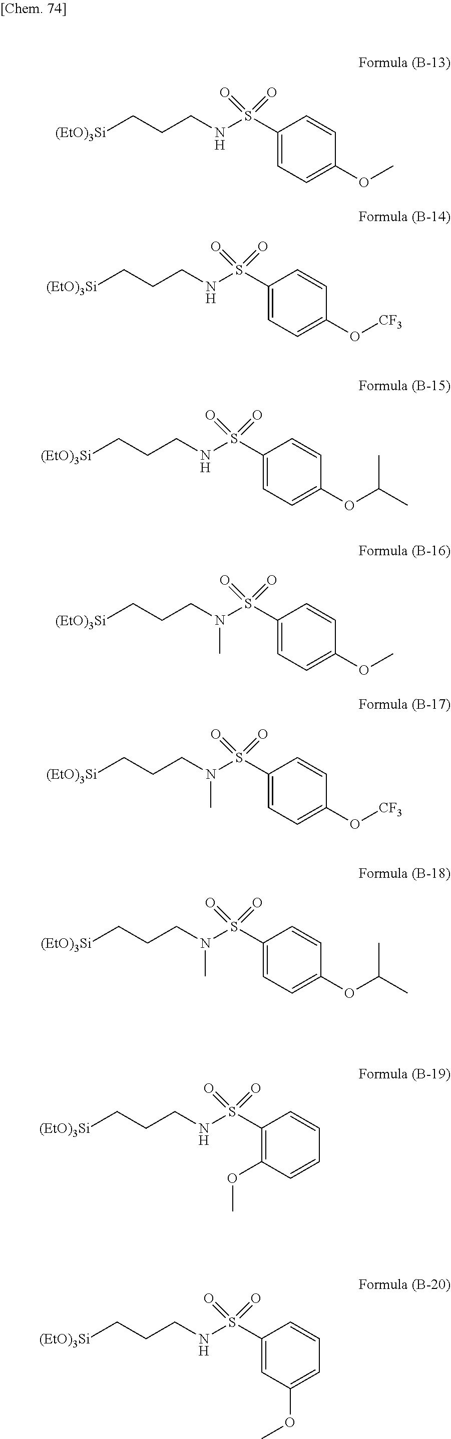

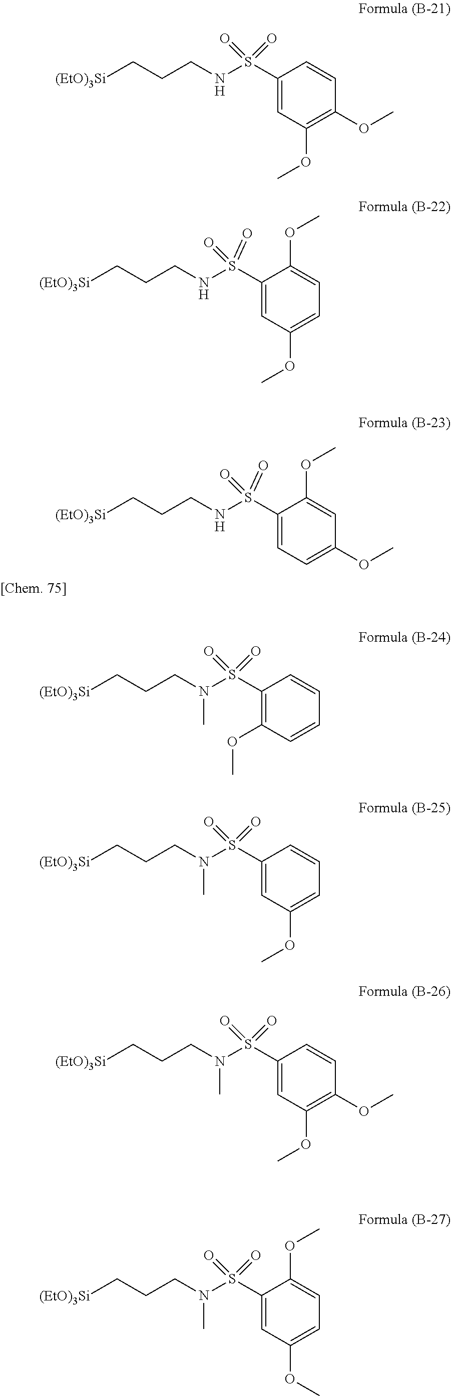

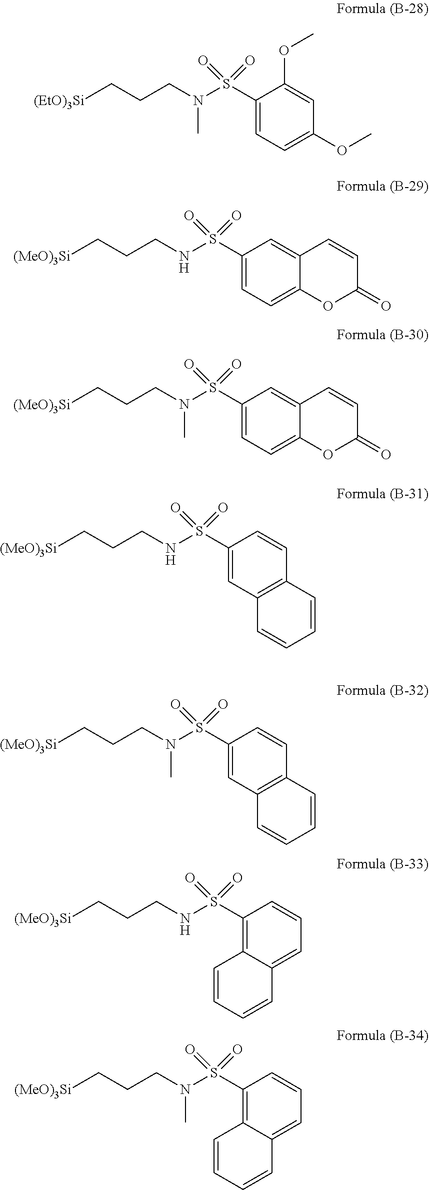

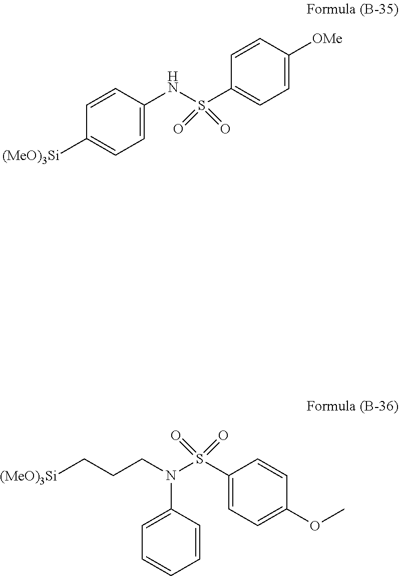

### ———Silane Compounds (Hydrolyzable Organosilanes) Having Cyclic Urea Skeleton in Molecule———

Examples of the hydrolyzable organosilanes having a cyclic urea skeleton in the molecule include hydrolyzable organosilanes represented by the following Formula (4-1).

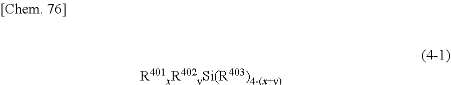

In Formula (4-1), R⁴⁰1 is a group bonded to a silicon atom, and each independently represents a group represented by the following Formula (4-2).

R⁴⁰² is a group bonded to a silicon atom, and represents an optionally substituted alkyl group, an optionally substituted aryl group, an optionally substituted aralkyl group, an optionally substituted alkyl halide group, an optionally substituted aryl halide group, an optionally substituted aralkyl halide group, an optionally substituted alkoxyalkyl group, an optionally substituted alkoxyaryl group, an optionally substituted alkoxyaralkyl group, or an optionally substituted alkenyl group, or represents an organic group having an optionally ring-opened epoxy group, an organic group having an acryloyl group, an organic group having a methacryloyl group, an organic group having a mercapto group, or an organic group having a cyano group, or a combination of two or more of these groups.

R⁴⁰³ is a group or atom bonded to a silicon atom, and each independently represents an alkoxy group, an aralkyloxy group, an acyloxy group, or a halogen atom.

x is 1 or 2, y is 0 or 1, and x+y≤2 is satisfied.

With regard to R⁴⁰², specific examples of the alkyl group, aryl group, aralkyl group, alkyl halide group, aryl halide group, aralkyl halide group, alkoxyalkyl group, alkoxyaryl group, alkoxyaralkyl group, alkenyl group, organic group having an optionally ring-opened epoxy group, organic group having an acryloyl group, organic group having a methacryloyl group, organic group having a mercapto group, and organic group having a cyano group, with regard to R⁴⁰³, specific examples of the alkoxy group, aralkyloxy group, acyloxy group, and halogen atom, substituents thereof, and the preferred number of carbon atoms thereof are the same as described above with regard to R¹ and R².

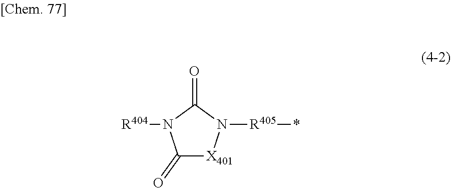

In Formula (4-2), each R⁴⁰⁴ independently represents a hydrogen atom, an optionally substituted alkyl group, an optionally substituted alkenyl group, or an organic group having an epoxy group or an organic group having a sulfonyl group, and each R⁴¹¹ independently represents an alkylene group, a hydroxyalkylene group, a sulfide bond (—S—), an ether bond (—O—), or an ester bond (—CO—O— or —O—CO—). Each asterisk * represents a bonding hand.

Note that with regard to R⁴⁰⁴, specific examples of the optionally substituted alkyl group, the optionally substituted alkenyl group, and the organic group having an epoxy group, and the preferred number of carbon atoms are the same as those described above with regard to R¹. In addition, the optionally substituted alkyl group of R⁴⁰⁴ is preferably an alkyl group in which a terminal hydrogen atom is substituted with a vinyl group, and specific examples thereof include an allyl group, a 2-vinylethyl group, a 3-vinylpropyl group, and a 4-vinylbutyl group.

The organic group having a sulfonyl group is not particularly limited as long as it contains a sulfonyl group, and examples thereof include an optionally substituted alkylsulfonyl group, an optionally substituted arylsulfonyl group, an optionally substituted aralkylsulfonyl group, an optionally substituted alkylsulfonyl halide group, an optionally substituted arylsulfonyl halide group, an optionally substituted aralkylsulfonyl halide group, an optionally substituted alkoxyalkylsulfonyl group, an optionally substituted alkoxyarylsulfonyl group, an optionally substituted alkoxyarylsulfonyl group, an optionally substituted alkoxyaralkylsulfonyl group, and an optionally substituted alkenylsulfonyl group.

Specific examples of the alkyl group, aryl group, aralkyl group, alkyl halide group, aryl halide group, aralkyl halide group, alkoxyalkyl group, alkoxyaryl group, alkoxyaralkyl group, and alkenyl group in these groups, substituents thereof, and the preferred number of carbon atoms thereof are the same as those described above with regard to R¹.

The alkylene group is a divalent group derived by further removing one hydrogen atom from the alkyl group, and may be linear, branched, or cyclic. Specific examples of the alkylene group are the same as those described above. The number of carbon atoms of the alkylene group is not particularly limited, but is preferably 40 or less, more preferably 30 or less, still more preferably 20 or less, and yet still more preferably 10 or less.

In addition, the alkylene group of R⁴⁰⁵ may have one or more types of bonds selected from a sulfide bond, an ether bond, and an ester bond at terminal ends or in the middle, and preferably in the middle.

Specific examples of the alkylene group include, but are not limited to, linear alkylene groups such as a methylene group, an ethylene group, a trimethylene group, a tetramethylene group, a pentamethylene group, a hexamethylene group, a heptamethylene group, an octamethylene group, a nonamethylene group and a decamethylene group; branched alkylene groups such as a methylethylene group, a 1-methyltrimethylene group, a 2-methyltrimethylene group, a 1,1-dimethylethylene group, a 1-methyltetramethylene group, a 2-methyltetramethylene group, a 1,1-dimethyltrimethylene group, a 1,2-dimethyltrimethylene group, a 2,2-dimethyltrimethylene group and a 1-ethyltrimethylene group; cyclic alkylene groups such as a 1,2-cyclopropanediyl group, a 1,2-cyclobutanediyl group, a 1,3-cyclobutanediyl group, a 1,2-cyclohexanediyl group and a 1,3-cyclohexanediyl group; and ether groups such as —CH₂OCH₂—, —CH₂CH₂OCH₂—, —CH₂CH₂OCH₂CH₂—, —CH₂CH₂CH₂OCH₂CH₂—, —CH₂CH₂OCH₂CH₂CH₂—, —CH₂CH₂CH₂OCH₂CH₂CH₂—, —CH₂SCH₂—, —CH₂CH₂SCH₂—, —CH₂CH₂SCH₂CH₂—, —CH₂CH₂CH₂SCH₂CH₂—, —CH₂CH₂SCH₂CH₂CH₂—, —CH₂CH₂CH₂SCH₂CH₂CH₂—, and —CH₂OCH₂CH₂SCH₂—.

The hydroxyalkylene group is a group in which at least one hydrogen atom of the above-described alkylene group is replaced with a hydroxy group. Specific examples of the hydroxyalkylene group include, but are not limited to, a hydroxymethylene group, a 1-hydroxyethylene group, a 2-hydroxyethylene group, a 1,2-dihydroxyethylene group, a 1-hydroxytrimethylene group, a 2-hydroxytrimethylene group, a 3-hydroxytrimethylene group, a 1-hydroxytetramethylene group, a 2-hydroxytetramethylene group, a 3-hydroxytetramethylene group, a 4-hydroxytetramethylene group, a 1,2-dihydroxytetramethylene group, a 1,3-dihydroxytetramethylene group, a 1,4-dihydroxytetramethylene group, a 2,3-dihydroxytetramethylene group, a 2,4-dihydroxytetramethylene group, and a 4,4-dihydroxytetramethylene group.

In Formula (4-2), each X₄₀₁ independently represents any one of groups represented by the following Formulae (4-3) to (4-5), and a carbon atom of a ketone group in the following Formulae (4-4) and (4-5) is bonded to a nitrogen atom to which R⁴⁰⁵ in Formula (4-2) is bonded.

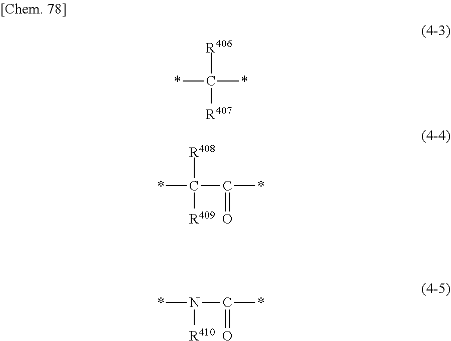

In Formulae (4-3) to (4-5), R⁴⁰⁶ to R⁴10 each independently represents a hydrogen atom, an optionally substituted alkyl group, an optionally substituted alkenyl group, or an organic group having an epoxy group or a sulfonyl group. Specific examples of the optionally substituted alkyl group, the optionally substituted alkenyl group, and the organic group having an epoxy group or a sulfonyl group, and the preferred number of carbon atoms thereof are the same as those described above with regard to R¹. Specific examples of the organic group having a sulfonyl group and the preferred number of carbon atoms are the same as those described above with regard to R⁴⁰⁴. Each asterisk * represents a bonding hand.

From the viewpoint of realizing excellent lithography characteristics with good reproducibility in the case of using the formed laminate in EUV lithography or electron beam lithography, X₄₀₁ is preferably a group represented by Formula (4-5) among the above Formulae.

From the viewpoint of realizing excellent lithography characteristics with good reproducibility in the case of using the formed laminate in EUV lithography or electron beam lithography, at least one of R⁴⁰⁴ and R⁴⁰⁶ to R⁴¹⁰ is preferably an alkyl group in which a terminal hydrogen atom is substituted with a vinyl group.

As the hydrolyzable organosilane represented by Formula (4-1), a commercially available product may be used. The hydrolyzable organosilane can also be synthesized by a known method described in WO 2011/102470 A or the like.

Hereinafter, specific examples of the hydrolyzable organosilane represented by Formula (4-1) include, but are not limited to, silanes represented by the following Formulae (4-1-1) to (4-1-29).

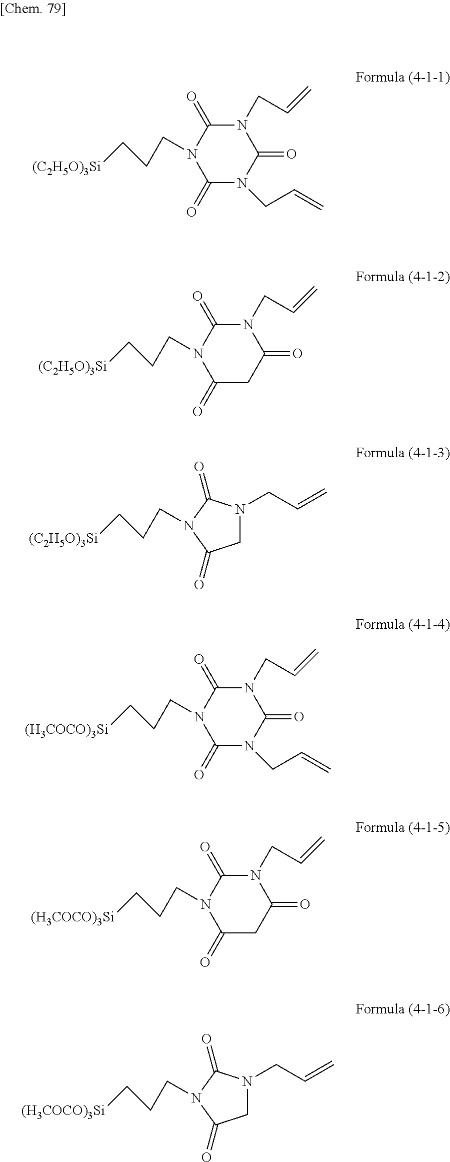

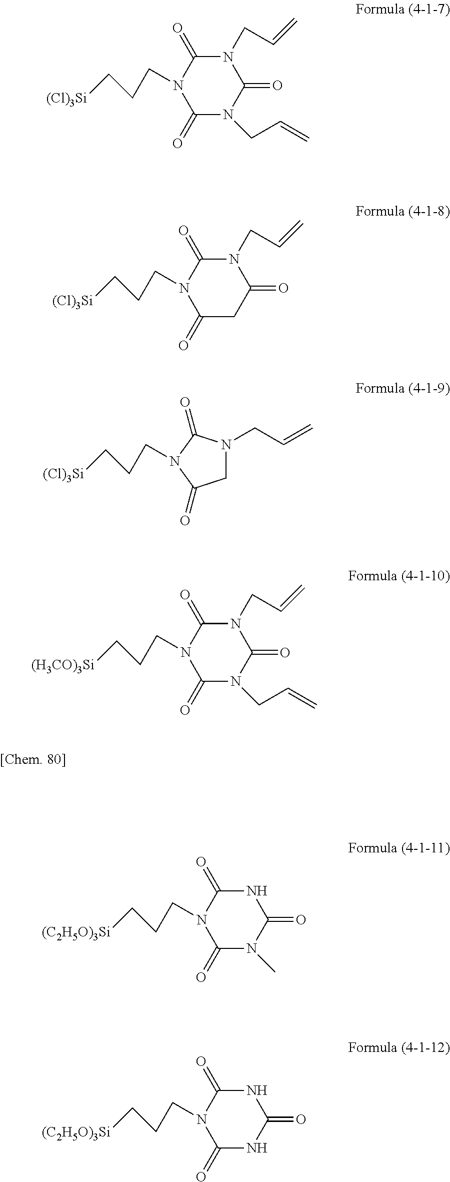

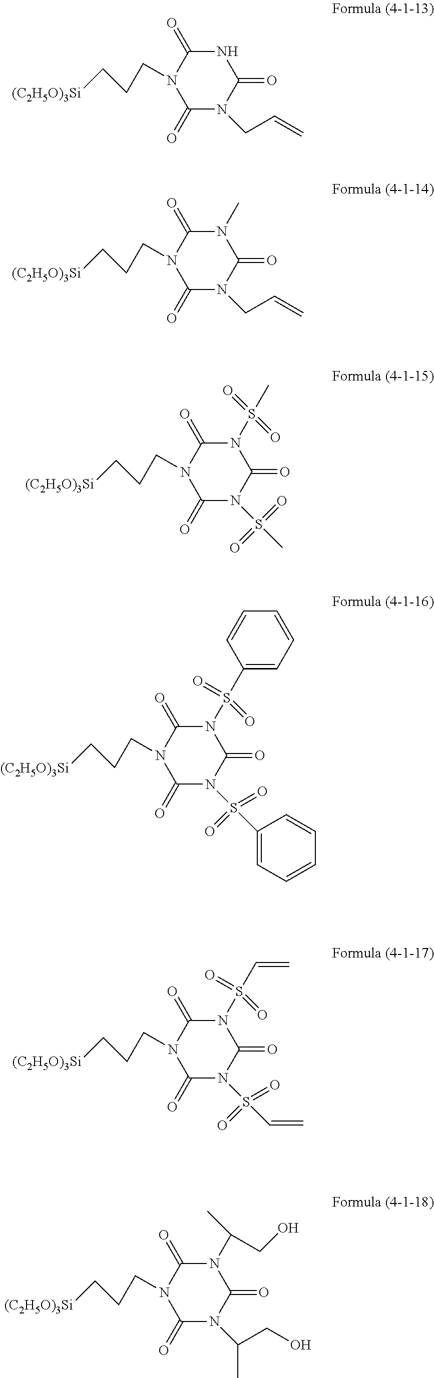

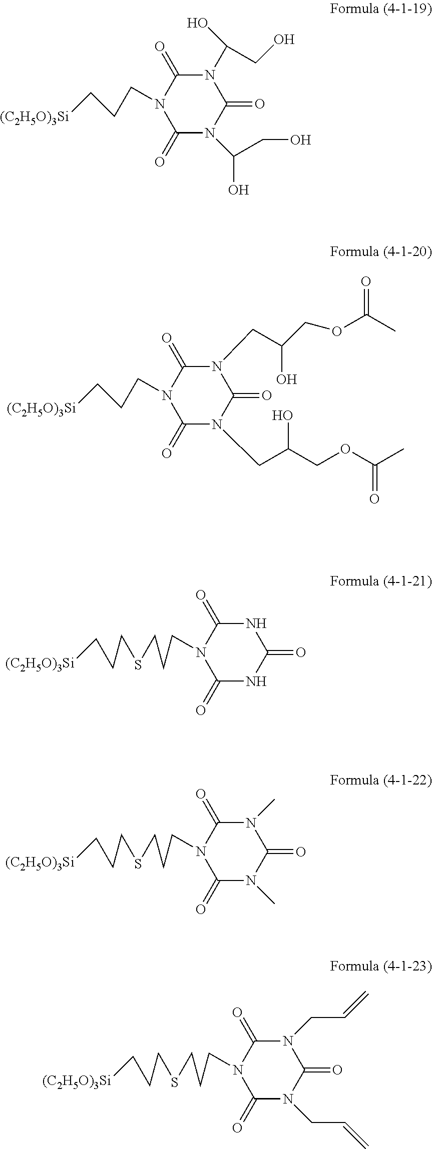

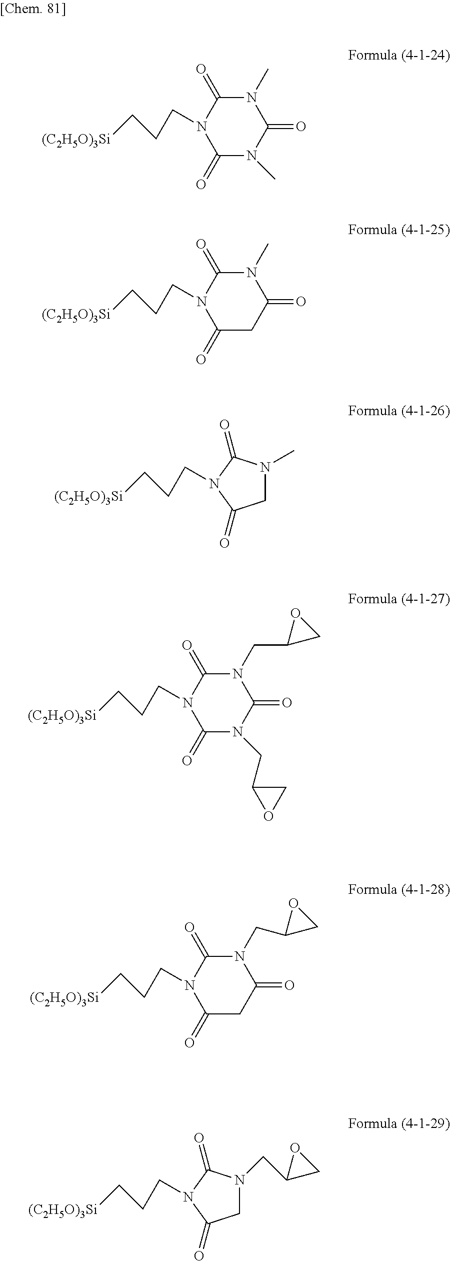

The polysiloxane may be a hydrolysis condensate of a hydrolyzable silane containing a silane compound other than those exemplified above as long as the effects of the present invention are not impaired.

As described above, as the polysiloxane, a modified polysiloxane in which at least some of silanol groups are modified can be used. For example, a modified polysiloxane in which some of silanol groups are alcohol-modified or acetal-protected can be used.

Examples of the polysiloxane as the modified product include a product prepared by a reaction between at least some of silanol groups of the above-described hydrolysis condensate of hydrolyzable silane and a hydroxy group of an alcohol, a product prepared by dehydration reaction between the condensate and an alcohol, and a modified product prepared by protection of at least some of silanol groups of the condensate with an acetal group.

As the alcohol, a monohydric alcohol can be used. Examples of the monohydric alcohol include methanol, ethanol, 2-propanol, 1-butanol, 2-butanol, isobutyl alcohol, tert-butyl alcohol, 1-pentanol, 2-pentanol, 3-pentanol, 1-heptanol, 2-heptanol, tert-amyl alcohol, neopentyl alcohol, 2-methyl-1-propanol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, and cyclohexanol.

For example, alkoxy group-containing alcohols such as 3-methoxybutanol, ethylene glycol monomethyl ether, ethylene glycol monoethyl ether, diethylene glycol monomethyl ether, diethylene glycol monoethyl ether, propylene glycol monomethyl ether (1-methoxy-2-propanol), propylene glycol monoethyl ether (1-ethoxy-2-propanol), and propylene glycol monobutyl ether (1-butoxy-2 propanol) can be used.

The reaction between silanol groups of the condensate and hydroxy groups of the alcohol is performed by bringing the polysiloxane in to contact with the alcohol. A modified polysiloxane containing capped silanol groups is prepared by performing the reaction at a temperature of 40 to 160° C. (e.g. 60° C.) for 0.1 to 48 hours (e.g. 24 hours). In this case, the alcohol serving as a capping agent may be used as a solvent in the composition containing the polysiloxane.

The product by dehydration reaction between the polysiloxane including the hydrolysis condensate of hydrolyzable silane and the alcohol can be produced by reacting the polysiloxane with the alcohol in the presence of an acid as a catalyst, capping silanol groups with the alcohol, and removing water generated through the dehydration to the outside of the reaction system.

The acid may be an organic acid having an acid dissociation constant (pka) of −1 to 5, preferably 4 to 5. Examples of the acid include trifluoroacetic acid, maleic acid, benzoic acid, isobutyric acid, and acetic acid. In particular, benzoic acid, isobutyric acid, and acetic acid can be exemplified.

As the acid, an acid having a boiling point of 70 to 160° C. may be used. Examples of the acid include trifluoroacetic acid, isobutyric acid, acetic acid, and nitric acid.

Preferably, the acid described above has either an acid dissociation constant (pka) of 4 to 5 or a boiling point of 70 to 160° C. That is, the acid to be used may be an acid having a weak acidity, or an acid having a strong acidity and a low boiling point.

Either of these properties: acid dissociation constant and boiling point of the acid may be utilized.

The acetal protection of silanol groups of the condensate can be performed with a vinyl ether; for example, a vinyl ether represented by the following Formula (5). Such a reaction can be performed to introduce a partial structure represented by the following Formula (6) into the polysiloxane.

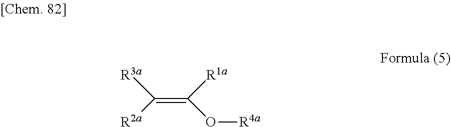

In Formula (5), R^{1a}, R^{2a}, and R^{3a} each represent a hydrogen atom or an alkyl group having 1 to 10 carbon atoms, R^{4a} represents an alkyl group having 1 to 10 carbon atoms, and R^{2a} and R^{4a} may be bonded together to form a ring. Examples of the alkyl group are the same as those described above.

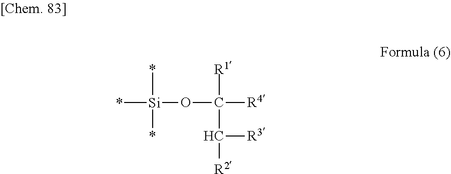

In Formula (6), R¹′, R²′, and R³′ each represent a hydrogen atom or an alkyl group having 1 to 10 carbon atoms, R⁴′ represents an alkyl group having 1 to 10 carbon atoms, and R²′ and R⁴′ may be bonded together to form a ring. In Formula (6), * represents a bond to an adjacent atom. The adjacent atom is, for example, an oxygen atom of a siloxane bond, an oxygen atom of a silanol group, or a carbon atom derived from R¹ of Formula (1). Examples of the alkyl group are the same as those described above.

As the vinyl ether represented by Formula (5), for example, aliphatic vinyl ether compounds, such as methyl vinyl ether, ethyl vinyl ether, isopropyl vinyl ether, normal butyl vinyl ether, 2-ethylhexyl vinyl ether, tert-butyl vinyl ether, and cyclohexyl vinyl ether; and cyclic vinyl ether compounds, such as 2,3-dihydrofuran, 4-methyl-2,3-dihydrofuran, and 3,4-dihydro-2H-pyran, may be used. In particular, ethyl vinyl ether, propyl vinyl ether, butyl vinyl ether, ethylhexyl vinyl ether, cyclohexyl vinyl ether, 3,4-dihydro-2H-pyran, or 2,3-dihydrofuran may be preferably used.

The acetal protection of silanol groups can be performed using a polysiloxane, a vinyl ether, and an aprotic solvent such as propylene glycol monomethyl ether acetate, ethyl acetate, dimethylformamide, tetrahydrofuran, or 1,4-dioxane as a solvent, and a catalyst such as pyridium p-toluenesulfonate, trifluoromethanesulfonic acid, p-toluenesulfonic acid, methanesulfonic acid, hydrochloric acid, or sulfuric acid.

The capping of silanol groups with an alcohol or the acetal protection of silanol groups may be performed simultaneously with the hydrolysis and condensation of the hydrolyzable silane described below.

In a preferred aspect of the present invention, the polysiloxane includes at least one of a hydrolysis condensate of a hydrolyzable silane and a modified product thereof, the hydrolyzable silane including a hydrolyzable silane represented by Formula (1) and, if desired, a hydrolyzable silane represented by Formula (2) and other hydrolyzable silanes.

In a preferred aspect, the polysiloxane includes a dehydration reaction product of a hydrolysis condensate and an alcohol.

The polysiloxane: the hydrolysis condensate of the hydrolyzable silane (which may also include a modified product) may have a weight-average molecular weight of, for example, 500 to 1,000,000. From the viewpoint of preventing the precipitation of the hydrolysis condensate in the composition, the weight-average molecular weight is preferably 500,000 or less, more preferably 250,000 or less, and still more preferably 100,000 or less. From the viewpoint of the compatibility between storage stability and application property, the weight-average molecular weight may be preferably 500 or more, more preferably 600 or more.

The weight-average molecular weight is determined by GPC analysis in terms of polystyrene. The GPC analysis can be performed under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (Shodex (registered trademark) manufactured by Showa Denko K.K.) as a standard sample.

The hydrolysis condensate of hydrolyzable silane is prepared by hydrolysis and condensation of the above-described silane compound (hydrolyzable silane).

The above-described silane compound (hydrolyzable silane) contains an alkoxy group, aralkyloxy group, acyloxy group, or halogen atom directly bonded to a silicon atom; i.e. an alkoxysilyl group, an aralkyloxysilyl group, an acyloxysilyl group, or a halogenated silyl group (hereinafter, such a group is referred to as “hydrolyzable group”).

For the hydrolysis of the hydrolyzable group, ordinarily 0.1 to 100 mol, for example, 0.5 to 100 mol, preferably 1 to 10 mol, of water is used per mol of the hydrolyzable group.

During hydrolysis and condensation, a hydrolysis catalyst may be used for the purpose of promoting the reaction. Alternatively, the hydrolysis and condensation may be performed without use of a hydrolysis catalyst. When a hydrolysis catalyst is used, the amount of the hydrolysis catalyst is ordinarily 0.0001 to 10 mol, preferably 0.001 to 1 mol per mol of the hydrolyzable group.

The reaction temperature for the hydrolysis and condensation is ordinarily equal to or higher than room temperature, or equal to or lower than the reflux temperature at normal pressure of an organic solvent usable for hydrolysis. The reaction temperature may be, for example, 20 to 110° C., or, for example, 20 to 80° C.

The hydrolysis may be performed completely; i.e. all hydrolyzable groups may be converted into silanol groups, or may be performed partially; i.e. unreacted hydrolyzable groups may remain.

Examples of the hydrolysis catalyst usable for the hydrolysis and condensation include a metal chelate compound, an organic acid, an inorganic acid, an organic base, and an inorganic base.

Examples of the metal chelate compound as the hydrolysis catalyst include, but are not limited to, titanium chelate compounds such as triethoxy-mono(acetylacetonate)titanium, tri-n-propoxy-mono(acetylacetonate)titanium, tri-i-propoxy-mono(acetylacetonate)titanium, tri-n-butoxy-mono(acetylacetonate)titanium, tri-sec-butoxy-mono(acetylacetonate)titanium, tri-t-butoxy-mono(acetylacetonate)titanium, diethoxy-bis(acetylacetonate)titanium, di-n-propoxy-bis(acetylacetonate)titanium, di-i-propoxy-bis(acetylacetonate)titanium, di-n-butoxy-bis(acetylacetonate)titanium, di-sec-butoxy-bis(acetylacetonate)titanium, di-t-butoxy-bis(acetylacetonate)titanium, monoethoxy-tris(acetylacetonate)titanium, mono-n-propoxy-tris(acetylacetonate)titanium, mono-i-propoxy-tris(acetylacetonate)titanium, mono-n-butoxy-tris(acetylacetonate)titanium, mono-sec-butoxy-tris(acetylacetonate)titanium, mono-t-butoxy-tris(acetylacetonate)titanium, tetrakis(acetylacetonate)titanium, triethoxy-mono(ethyl acetoacetate)titanium, tri-n-propoxy-mono(ethyl acetoacetate)titanium, tri-i-propoxy-mono(ethyl acetoacetate)titanium, tri-n-butoxy-mono(ethyl acetoacetate)titanium, tri-sec-butoxy-mono(ethyl acetoacetate)titanium, tri-t-butoxy-mono(ethyl acetoacetate)titanium, diethoxy-bis(ethyl acetoacetate)titanium, di-n-propoxy-bis(ethyl acetoacetate)titanium, di-i-propoxy-bis(ethyl acetoacetate)titanium, di-n-butoxy-bis(ethyl acetoacetate)titanium, di-sec-butoxy-bis(ethyl acetoacetate)titanium, di-t-butoxy-bis(ethyl acetoacetate)titanium, monoethoxy-tris(ethyl acetoacetate)titanium, mono-n-propoxy-tris(ethyl acetoacetate)titanium, mono-i-propoxy-tris(ethyl acetoacetate)titanium, mono-n-butoxy-tris(ethyl acetoacetate)titanium, mono-sec-butoxy-tris(ethyl acetoacetate)titanium, mono-t-butoxy-tris(ethyl acetoacetate)titanium, tetrakis(ethyl acetoacetate)titanium, mono(acetylacetonate)tris(ethyl acetoacetate)titanium, bis(acetylacetonate)bis(ethyl acetoacetate)titanium, and tris(acetylacetonate)mono(ethyl acetoacetate)titanium; zirconium chelate compounds such as triethoxy-mono(acetylacetonate)zirconium, tri-n-propoxy-mono(acetylacetonate)zirconium, tri-i-propoxy-mono(acetylacetonate)zirconium, tri-n-butoxy-mono(acetylacetonate)zirconium, tri-sec-butoxy-mono(acetylacetonate)zirconium, tri-t-butoxy-mono(acetylacetonate)zirconium, diethoxy-bis(acetylacetonate)zirconium, di-n-propoxy-bis(acetylacetonate)zirconium, di-i-propoxy-bis(acetylacetonate)zirconium, di-n-butoxy-bis(acetylacetonate)zirconium, di-sec-butoxy-bis(acetylacetonate)zirconium, di-t-butoxy-bis(acetylacetonate)zirconium, monoethoxy-tris(acetylacetonate)zirconium, mono-n-propoxy-tris(acetylacetonato)zirconium, mono-i-propoxy-tris(acetylacetonate)zirconium, mono-n-butoxy-tris(acetylacetonate)zirconium, mono-sec-butoxy-tris(acetylacetonate)zirconium, mono-t-butoxy-tris(acetylacetonate)zirconium, tetrakis(acetylacetonate)zirconium, triethoxy-mono(ethyl acetoacetate)zirconium, tri-n-propoxy-mono(ethyl acetoacetate)zirconium, tri-i-propoxy-mono(ethyl acetoacetate)zirconium, tri-n-butoxy-mono(ethyl acetoacetate)zirconium, tri-sec-butoxy-mono(ethyl acetoacetate)zirconium, tri-t-butoxy-mono(ethyl acetoacetate)zirconium, diethoxy-bis(ethyl acetoacetate)zirconium, di-n-propoxy-bis(ethyl acetoacetate)zirconium, di-i-propoxy-bis(ethyl acetoacetate)zirconium, di-n-butoxy-bis(ethyl acetoacetate)zirconium, di-sec-butoxy-bis(ethyl acetoacetate)zirconium, di-t-butoxy-bis(ethyl acetoacetate)zirconium, monoethoxy-tris(ethyl acetoacetate)zirconium, mono-n-propoxy-tris(ethyl acetoacetate)zirconium, mono-i-propoxy-tris(ethyl acetoacetate)zirconium, mono-n-butoxy-tris(ethyl acetoacetate)zirconium, mono-sec-butoxy-tris(ethyl acetoacetate)zirconium, mono-t-butoxy-tris(ethyl acetoacetate)zirconium, tetrakis(ethyl acetoacetate)zirconium, mono(acetylacetonate)tris(ethyl acetoacetate)zirconium, bis(acetylacetonate)bis(ethyl acetoacetate)zirconium, and tris(acetylacetonate)mono(ethyl acetoacetate)zirconium; and aluminum chelate compounds such as tris(acetylacetonate)aluminum and tris(ethyl acetoacetate)aluminum.

Examples of the organic acid as the hydrolysis catalyst include, but are not limited to, acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartaric acid.

Examples of the inorganic acid as the hydrolysis catalyst include, but are not limited to, hydrochloric acid, nitric acid, sulfuric acid, hydrofluoric acid, and phosphoric acid.

Examples of the organic base as the hydrolysis catalyst include, but are not limited to, pyridine, pyrrole, piperazine, pyrrolidine, piperidine, picoline, trimethylamine, triethylamine, monoethanolamine, diethanolamine, dimethylmonoethanolamine, monomethyldiethanolamine, triethanolamine, diazabicyclooctane, diazabicyclononane, diazabicycloundecene, tetramethylammonium hydroxide, tetraethylammonium hydroxide, tetrapropylammonium hydroxide, tetrabutylammonium hydroxide, trimethylphenylammonium hydroxide, benzyltrimethylammonium hydroxide, and benzyltriethylammonium hydroxide.

Examples of the inorganic base as the hydrolysis catalyst include, but are not limited to, ammonia, sodium hydroxide, potassium hydroxide, barium hydroxide, and calcium hydroxide.

Among these catalysts, a metal chelate compound, an organic acid, and an inorganic acid is preferred. These catalysts may be used singly or in combination of two or more kinds thereof.

In particular, nitric acid can be suitably used as a hydrolysis catalyst in the present invention. The use of nitric acid enables an improvement in the storage stability of a reaction solution after the hydrolysis and condensation, and particularly enables suppression of a change in the molecular weight of a hydrolysis condensate. It is known that the stability of the hydrolysis condensate contained in the reaction solution depends on the pH of the solution. As a result of intensive studies, it has been found that the pH of the reaction solution falls in a stable range by use of an appropriate amount of nitric acid.

As described above, nitric acid can also be used for preparation of a modified product of the hydrolysis condensate; for example, for capping of silanol groups with an alcohol. Thus, nitric acid is preferred from the viewpoint that it can contribute to the reactions of hydrolysis and condensation of the hydrolyzable silane, as well as the reaction of capping of the hydrolysis condensate with an alcohol.

When hydrolysis and condensation are performed, an organic solvent may be used as a solvent, and specific examples thereof include, but are not limited to aliphatic hydrocarbon solvents, such as n-pentane, i-pentane, n-hexane, i-hexane, n-heptane, i-heptane, 2,2,4-trimethylpentane, n-octane, i-octane, cyclohexane, and methylcyclohexane; aromatic hydrocarbon solvents, such as benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, and n-amylnaphthalene; monohydric alcohol solvents, such as methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, n-heptanol, sec-heptanol, 3-heptanol, n-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethylcarbinol, diacetone alcohol, and cresol; polyhydric alcohol solvents, such as ethylene glycol, propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, and glycerin; ketone solvents, such as acetone, methyl ethyl ketone, methyl-n-propyl ketone, methyl-n-butyl ketone, diethyl ketone, methyl-1-butyl ketone, methyl-n-pentyl ketone, ethyl-n-butyl ketone, methyl-n-hexyl ketone, di-i-butyl ketone, trimethylnonanone, cyclohexanone, methylcyclohexanone, 2,4-pentanedione, acetonylacetone, diacetone alcohol, acetophenone, and fenchone; ether solvents, such as ethyl ether, i-propyl ether, n-butyl ether, n-hexyl ether, 2-ethylhexyl ether, ethylene oxide, 1,2-propylene oxide, dioxolane, 4-methyldioxolane, dioxane, dimethyldioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethylbutyl ether, ethylene glycol dibutyl ether, diethylene glycol monomethyl ether, diethylene glycol monoethyl ether, diethylene glycol diethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (1-methoxy-2-propanol), propylene glycol monoethyl ether (1-ethoxy-2-propanol), propylene glycol monopropyl ether, propylene glycol monobutyl ether, propylene glycol monomethyl ether acetate (1-methoxy-2-propanol monoacetate), dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, and 2-methyltetrahydrofuran; ester solvents, such as diethyl carbonate, methyl acetate, ethyl acetate, γ-butyrolactone, γ-valerolactone, n-propyl acetate, i-propyl acetate, n-butyl acetate, i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethylene glycol diacetate, triethylene glycol methyl ether acetate, ethyl propionate, n-butyl propionate, i-amyl propionate, diethyl oxalate, di-n-butyl oxalate, methyl lactate, ethyl lactate, n-butyl lactate, n-amyl lactate, diethyl malonate, dimethyl phthalate, and diethyl phthalate; nitrogen-containing solvents, such as N-methylformamide, N,N-dimethylformamide, N,N-diethylformamide, acetamide, N-methylacetamide, N,N-dimethylacetamide, N-methylpropionamide, and N-methyl-2-pyrrolidone; and sulfur-containing solvents, such as dimethyl sulfide, diethyl sulfide, thiophene, tetrahydrothiophene, dimethyl sulfoxide, sulfolane, and 1,3-propanesultone. These solvents can be used singly or in combination of two or more kinds thereof.

After completion of the hydrolysis and condensation reactions, the reaction solution is used as is, or diluted or concentrated. The resultant reaction solution can be neutralized or treated with an ion exchange resin, and thus the hydrolysis catalyst, e.g. an acid or a base, used for the hydrolysis and condensation can be removed. Before or after such a treatment, alcohols: by-products, water, the used hydrolysis catalyst, and the like can be removed from the reaction solution, for example, by distillation under reduced pressure.

The thus-prepared hydrolysis condensate is in the form of a polysiloxane varnish dissolved in an organic solvent, and may be used as is for preparation of a surface modifier. That is, the reaction solution may be used as is (or diluted) for preparation of the surface modifier. In this case, the hydrolysis catalyst used for the hydrolysis and condensation, by-products, and the like may remain in the reaction solution, so long as the effects of the present invention is not impaired. For example, nitric acid used as a hydrolysis catalyst or used for capping of silanol groups with an alcohol may remain in the polymer varnish solution in an amount of about 100 ppm to 5,000 ppm.

The resultant polysiloxane varnish may be subjected to solvent replacement, or may be appropriately diluted with a solvent. In a case where the storage stability of the resultant polysiloxane varnish is not poor, the organic solvent may be distilled off to achieve a film-forming component concentration of 100%. The film-forming component refers to a component resulted from the removal of a solvent component from all the components of the composition.

The organic solvent used for solvent replacement, dilution, or the like of the polysiloxane varnish may be identical to or different from the organic solvent used for the hydrolysis and condensation reactions of the hydrolyzable silane. The solvent for dilution is not particularly limited, and one kind or two or more kinds of solvents may be arbitrarily selected and used.

### <<<Solvent>>>

As the solvent contained in the surface modifier, any solvent can be used without particular limitation as long as it is a solvent capable of dissolving and mixing the polymer (e.g. polysiloxane), and, if necessary, other components contained in the surface modifier.

The solvent is, for example, an organic solvent or water.

Examples of the solvent include alcohols, alkylene glycol alkyl ethers, alkylene glycol monoalkyl ether carboxylic acid esters, and water.

Examples of the alcohols include a monohydric alcohol solvent and a polyhydric alcohol solvent. Specific examples of the monohydric alcohol solvent and the polyhydric alcohol solvent include the monohydric alcohol solvents and polyhydric alcohol solvents described above as the solvents used for hydrolysis and condensation.

Examples of the alkylene glycol alkyl ethers include alkylene glycol monoalkyl ethers and alkylene glycol dialkyl ethers.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Examples of the alkylene glycol dialkyl ether include diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, and propylene glycol dibutyl ether.

Examples of the alkylene glycol monoalkyl ether carboxylic acid esters include alkylene glycol monoalkyl ether acetate.

Examples of the alkylene glycol monoalkyl ether acetate include methyl cellosolve acetate, ethyl cellosolve acetate, propylene glycol monomethyl ether acetate (1-methoxy-2-propanol monoacetate), propylene glycol monoethyl ether acetate, propylene glycol monopropyl ether acetate, propylene glycol monobutyl ether acetate, ethylene glycol monomethyl ether acetate, ethylene glycol monoethyl ether acetate, ethylene glycol monopropyl ether acetate, and ethylene glycol monobutyl ether acetate.

Specific examples of other solvents include toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, methyl propyl ketone, methyl butyl ketone, 2-heptanone, 3-heptanone, 4-heptanone, N,N-dimethylformamide, N-methylacetamide, N,N-dimethylacetamide, N-methyl-2-pyrrolidone, 4-methyl-2-pentanol, and γ-butyrolactone.

These solvents can be used singly or in combination of two or more kinds thereof.

The surface modifier may contain water as a solvent. When water is contained as the solvent, the content thereof may be, for example, 30 mass % or less, preferably 20 mass % or less, and still more preferably 15 mass % or less relative to the total mass of the solvent contained in the surface modifier.

### <<<Curing Catalyst>>>

The surface modifier may be a composition containing no curing catalyst. Alternatively, the surface modifier preferably contains a curing catalyst.

The curing catalyst may be, for example, an ammonium salt, a phosphine compound, a phosphonium salt, a sulfonium salt, an iodonium salts, and an oxonium salt. The salt described below as an example of a curing catalyst may be added in the form of a salt, or may be a compound that forms a salt in the composition (i.e. a compound that forms a salt in the system, but is in a form different from the salt during addition).

Examples of the ammonium salt include a quaternary ammonium salt having a structure represented by the following Formula (D-1):

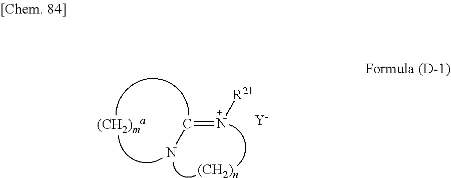

(where m^{a} represents an integer of 2 to 11, n^{a} represents an integer of 2 to 3, R²¹ represents an alkyl group, an aryl group, or an aralkyl group, and Y-represents an anion);
a quaternary ammonium salt having a structure represented by the following Formula (D-2):

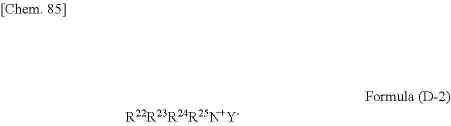

(where R²², R²³, R²⁴, and R²⁵ each independently represent an alkyl group, an aryl group, or an aralkyl group, Y− represents an anion, and R²², R²³, R²⁴, and R²⁵ are each bonded to a nitrogen atom);
a quaternary ammonium salt having a structure represented by the following Formula (D-3):

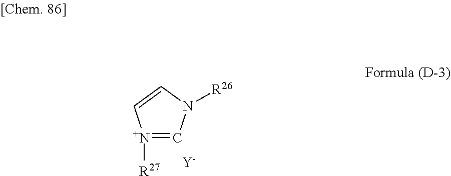

(where R²⁶ and R²⁷ each independently represent an alkyl group, an aryl group, or an aralkyl group, and Y-represents an anion);
a quaternary ammonium salt having a structure represented by the following Formula (D-4):

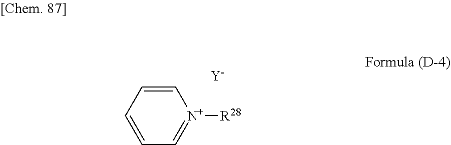

(where R²⁸ represents an alkyl group, an aryl group, or an aralkyl group, and Y− represents an anion);
a quaternary ammonium salt having a structure represented by the following Formula (D-5):

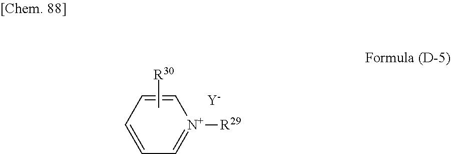

(where R²⁹ and R³⁰ each independently represent an alkyl group, an aryl group, or an aralkyl group, and Y-represents an anion);
a tertiary ammonium salt having a structure represented by the following Formula (D-6):

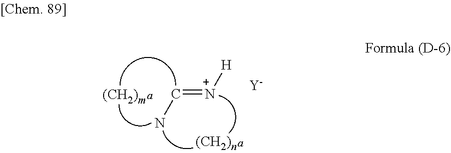

(where m^{a} represents an integer of 2 to 11, n^{a} represents an integer of 2 to 3, and Y− represents an anion).

Examples of the phosphonium salt include a quaternary phosphonium salt represented by the following Formula (D-7):

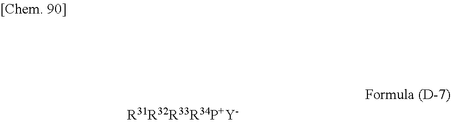

(where R³¹, R³², R³³, and R³⁴ each independently represent an alkyl group, an aryl group, or an aralkyl group, Y⁻ represents an anion, and each of R³¹, R³², R³³, and R³⁴ is bonded to the phosphorus atom).

Examples of the sulfonium salt include a tertiary sulfonium salt represented by the following Formula (D-8):

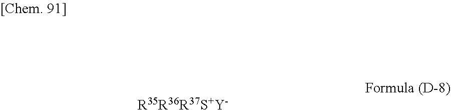

(where R³⁵, R³⁶, and R³⁷ each independently represent an alkyl group, an aryl group, or an aralkyl group, Y⁻ represents an anion, and each of R³⁵, R³⁶, and R³⁷ is bonded to the sulfur atom)

The compound of Formula (D-1) is a quaternary ammonium salt derived from an amine, where m^{a} represents an integer of 2 to 11, and n^{a} represents an integer of 2 to 3. R²¹ of the quaternary ammonium salt represents, for example, an alkyl group having 1 to 18 carbon atoms, preferably 2 to 10 carbon atoms, an aryl group having 6 to 18 carbon atoms, or an aralkyl group having 7 to 18 carbon atoms. Examples thereof include linear alkyl groups such as an ethyl group, a propyl group, and a butyl group; a benzyl group, a cyclohexyl group, a cyclohexylmethyl group, and a dicyclopentadienyl group. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O—).

The compound of Formula (D-2) is a quaternary ammonium salt represented by R²²R²³R²⁴R²⁵N⁺Y⁻. R²², R²³, R²⁴, and R²⁵ of the quaternary ammonium salt are each, for example, an alkyl group having 1 to 18 carbon atoms, such as ethyl group, propyl group, butyl group, cyclohexyl group, and cyclohexylmethyl group, an aryl group having 6 to 18 carbon atoms, such as phenyl group, or an aralkyl group having 7 to 18 carbon atoms, such as benzyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O—). The quaternary ammonium salt is commercially available, and examples of the quaternary ammonium salt include tetramethylammonium acetate, tetrabutylammonium acetate, triethylbenzylammonium chloride, triethylbenzylammonium bromide, trioctylmethylammonium chloride, tributylbenzylammonium chloride, and trimethylbenzylammonium chloride.

The compound of Formula (D-3) is a quaternary ammonium salt derived from 1-substituted imidazole. The number of carbon atoms of each of R²⁶ and R²⁷ is, for example, 1 to 18, and the total number of carbon atoms of R²⁶ and R²⁷ is preferably 7 or more. Examples of R²⁶ include alkyl groups, such as a methyl group, an ethyl group, and a propyl group, and aryl groups, such as a phenyl group. Examples of R²⁷ include aralkyl groups, such as a benzyl group, and alkyl groups, such as an octyl group and an octadecyl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between an imidazole compound (e.g. 1-methylimidazole or 1-benzylimidazole) and an aralkyl halide, an alkyl halide, or an aryl halide, such as benzyl bromide, methyl bromide, or benzene bromide.

The compound of Formula (D-4) is a quaternary ammonium salt derived from pyridine. R²⁸ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include a butyl group, an octyl group, a benzyl group, and a lauryl group. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between pyridine and an alkyl halide or an aryl halide, such as lauryl chloride, benzyl chloride, benzyl bromide, methyl bromide, or octyl bromide. Examples of this compound include N-laurylpyridinium chloride and N-benzylpyridinium bromide.

The compound of Formula (D-5) is a quaternary ammonium salt derived from a substituted pyridine, such as picoline. R²⁹ is, for example, an alkyl group having 1 to 18 carbon atoms, preferably 4 to 18 carbon atoms, an aryl group having 6 to 18 carbon atoms, or an aralkyl group having 7 to 18 carbon atoms. Examples thereof include a methyl group, an octyl group, a lauryl group, and a benzyl group. R³⁰ is, for example, an alkyl group having 1 to 18 carbon atoms, an aryl group having 6 to 18 carbon atoms, or an aralkyl group having 7 to 18 carbon atoms. For example, R³⁰ is a methyl group when the compound represented by Formula (D-5) is a quaternary ammonium derived from picoline. Examples of the anion (Y⁻) include halide ions such as a chlorine ion (Cl⁻), a bromine ion (Br⁻), and an iodine ion (I⁻), and acid groups such as carboxylate (—COO⁻), sulfonate (—SO₃⁻), and alcoholate (—O⁻). Although this compound is commercially available, the compound may be produced through, for example, reaction between a substituted pyridine (e.g. picoline) and an alkyl halide or an aryl halide, such as methyl bromide, octyl bromide, lauryl chloride, benzyl chloride, or benzyl bromide. Examples of this compound include N-benzylpicolinium chloride, N-benzylpicolinium bromide, and N-laurylpicolinium chloride.

The compound of Formula (D-6) is a tertiary ammonium salt derived from an amine, where m^{a} represents an integer of 2 to 11, and n^{a} represents 2 or 3. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). The compound may be produced through reaction between an amine and a weak acid, such as a carboxylic acid or phenol. Examples of the carboxylic acid include formic acid and acetic acid. When formic acid is used, the anion (Y⁻) is (HCOO⁻). When acetic acid is used, the anion (Y⁻) is (CH₃COO⁻). When phenol is used, the anion (Y⁻) is (C₆H₅O⁻).

The compound of Formula (D-7) is a quaternary phosphonium salt having a structure of R³¹R³²R³³R³⁴P⁺Y⁻. R³¹, R³², R³³, and R³⁴ are each, for example, an alkyl group having 1 to 18 carbon atoms, such as ethyl group, propyl group, butyl group, or cyclohexylmethyl, an aryl group having 6 to 18 carbon atoms, such as phenyl group, or an aralkyl group having 7 to 18 carbon atoms, such as benzyl group. Three of four substituents of R³¹ to R³⁴ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Further, examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), and alcoholate (—O⁻). This compound is commercially available, and examples of the compound include tetraalkylphosphonium halides, such as tetra-n-butylphosphonium halide and tetra-n-propylphosphonium halide; trialkylbenzylphosphonium halides, such as triethylbenzylphosphonium halide; triphenylmonoalkylphosphonium halides, such as triphenylmethylphosphonium halide and triphenylethylphosphonium halide; triphenylbenzylphosphonium halide; tetraphenylphosphonium halide; tritolylmonoarylphosphonium halide; or tritolylmonoalkylphosphonium halide (where the halogen atom is a chlorine atom or a bromine atom). Particularly preferred are triphenylmonoalkylphosphonium halides, such as triphenylmethylphosphonium halide and triphenylethylphosphonium halide; triphenylmonoarylphosphonium halides, such as triphenylbenzylphosphonium halide; tritolylmonoarylphosphonium halides, such as tritolylmonophenylphosphonium halide; and tritolylmonoalkylphosphonium halides, such as tritolylmonomethylphosphonium halide (where the halogen atom is a chlorine atom or a bromine atom).

Examples of the phosphine compound include primary phosphines, such as methylphosphine, ethylphosphine, propylphosphine, isopropylphosphine, isobutylphosphine, and phenylphosphine; secondary phosphines, such as dimethylphosphine, diethylphosphine, diisopropylphosphine, diisoamylphosphine, and diphenylphosphine; and tertiary phosphines, such as trimethylphosphine, triethylphosphine, triphenylphosphine, methyldiphenylphosphine, and dimethylphenylphosphine.

The compound of Formula (D-8) is a tertiary sulfonium salt having a structure of R³⁵R³⁶R³⁷S⁺Y⁻. R³⁵, R³⁶, and R³⁷ are each, for example, an alkyl group having 1 to 18 carbon atoms, such as an ethyl group, a propyl group, a butyl group, or a cyclohexylmethyl, an aryl group having 6 to 18 carbon atoms, such as a phenyl group, or an aralkyl group having 7 to 18 carbon atoms, such as a benzyl group. Two of three substituents of R³⁵ to R³⁷ are each preferably an unsubstituted phenyl group or a substituted phenyl group. Examples thereof include a phenyl group or a tolyl group. The remaining one substituent is an alkyl group having 1 to 18 carbon atoms, an aryl group having 6 to 18 carbon atoms, or an aralkyl group having 7 to 18 carbon atoms. Examples of the anion (Y⁻) include halide ions, such as chlorine ion (Cl⁻), bromine ion (Br⁻), and iodine ion (I⁻); and acid groups, such as carboxylate (—COO⁻), sulfonate (—SO₃⁻), alcoholate (—O⁻), maleate anion, and nitrate anion. This compound is commercially available, and examples of the compound include trialkylsulfonium halides, such as tri-n-butylsulfonium halide and tri-n-propylsulfonium halide; dialkylbenzylsulfonium halides, such as diethylbenzylsulfonium halide; diphenylmonoalkylsulfonium halides, such as diphenylmethylsulfonium halide and diphenylethylsulfonium halide; triphenylsulfonium halides (where the halogen atom is a chlorine atom or a bromine atom); trialkylsulfonium carboxylates, such as tri-n-butylsulfonium carboxylate and tri-n-propylsulfonium carboxylate; dialkylbenzylsulfonium carboxylates, such as diethylbenzylsulfonium carboxylate; diphenylmonoalkylsulfonium carboxylates, such as diphenylmethylsulfonium carboxylate and diphenylethylsulfonium carboxylate; and triphenylsulfonium carboxylate. Triphenylsulfonium halide and triphenylsulfonium carboxylate are preferably used.

In addition, a nitrogen-containing silane compound may be added as a curing catalyst. Examples of the nitrogen-containing silane compound include silane compounds containing an imidazole ring, such as N-(3-triethoxysilylpropyl)-4,5-dihydroimidazole.

The content of the curing catalyst in the surface modifier is preferably 0.01 to 30 parts by mass, more preferably 0.01 to 25 parts by mass, and still more preferably 0.01 to 20 parts by mass, relative to 100 parts by mass of the polymer.

### <<<Acid>>>

The surface modifier preferably contains an acid.

The acid may be added during preparation of the surface modifier. When the surface modifier contains a polysiloxane, acid may be used as a hydrolysis catalyst or used for capping of silanol groups with an alcohol in the production of the polysiloxane described above, and may remain in the resultant polysiloxane varnish.

Examples of the acid include an organic acid and an inorganic acid.

Examples of the organic acid acetic acid, propionic acid, butanoic acid, pentanoic acid, hexanoic acid, heptanoic acid, octanoic acid, nonanoic acid, decanoic acid, oxalic acid, maleic acid, methylmalonic acid, adipic acid, sebacic acid, gallic acid, butyric acid, mellitic acid, arachidonic acid, 2-ethylhexanoic acid, oleic acid, stearic acid, linoleic acid, linolenic acid, salicylic acid, benzoic acid, p-aminobenzoic acid, p-toluenesulfonic acid, benzenesulfonic acid, monochloroacetic acid, dichloroacetic acid, trichloroacetic acid, trifluoroacetic acid, formic acid, malonic acid, sulfonic acid, phthalic acid, fumaric acid, citric acid, and tartar.

Examples of the inorganic acid include hydrochloric acid, nitric acid, sulfuric acid, hydrofluoric acid, and phosphoric acid.

The amount of the acid (amount of residual acid) added may be, for example, 0.0001 mass % to 1 mass %, 0.001 mass % to 0.1 mass %, or 0.005 mass % to 0.05 mass % relative to the total mass of the surface modifier.

### <<<Amine and Hydroxide>>>

The surface modifier may contain at least one selected from an amine and a hydroxide.

Examples of the amine include ammonia; primary amines such as monomethanolamine, monoethanolamine, monopropanolamine, methylamine, ethylamine, propylamine, and butylamine; secondary amines such as dimethylamine, ethylmethylamine, and diethylamine; tertiary amines such as trimethylamine, triethylamine, tripropylamine, dimethylethylamine, methyldiisopropylamine, diisopropylethylamine, diethylethanolamine, and triethanolamine; amines such as ethylenediamine and tetramethylethylenediamine; and cyclic amines such as pyridine and morpholine.

Examples of the hydroxide include an inorganic alkali hydroxide and an organic alkali hydroxide.

Examples of the inorganic alkali hydroxide include sodium hydroxide and potassium hydroxide.

Examples of the organic alkali hydroxide include tetraalkylammonium hydroxide, triarylsulfonium hydroxide, and diaryliodonium hydroxide. Examples of the tetraalkylammonium hydroxide include tetramethylammonium hydroxide, tetraethylammonium hydroxide, and tetrabutylammonium hydroxide. Examples of the triarylsulfonium hydroxide include triphenylsulfonium hydroxide and tris(t-butylphenyl)sulfonium hydroxide. Examples of the diaryliodonium hydroxide include diphenyliodonium hydroxide and bis(t-butylphenyl)iodonium hydroxide.

The contents of the amine and the hydroxide in the surface modifier are not particularly limited, but can be preferably 0.05 to 20 parts by mass, more preferably 0.1 to 15 parts by mass, and still more preferably 0.5 to 10 parts by mass relative to 100 parts by mass of the polysiloxane.

### <<<Additional Additives>>>

Various additives can be added to the surface modifier depending on the intended use of the composition.

Examples of the additives include known additives incorporated in materials (compositions) for forming various films (e.g. resist underlayer film, anti-reflective coating, and pattern reversing film) that can be used in the production of a semiconductor device, such as a crosslinking agent, a crosslinking catalyst, a stabilizer (e.g. an organic acid, water, or an alcohol), an organic polymer, an acid generator, a surfactant (e.g. a nonionic surfactant, an anionic surfactant, a cationic surfactant, a silicon-based surfactant, a fluorine-based surfactant, or an UV-curable surfactant), a pH adjuster, a metal oxide, a rheology controlling agent, and an adhesion aid.

Hereinafter, various additives will be exemplified, but the additives are not limited thereto.

### —Stabilizer—

When the surface modifier contains a polysiloxane, the stabilizer may be added for the purpose of stabilizing the hydrolysis condensate of the hydrolyzable silane mixture, or the like. Specific example of the stabilizer that include an organic acid, water, alcohol, or a combination thereof.

Examples of the organic acid include oxalic acid, malonic acid, methylmalonic acid, succinic acid, maleic acid, malic acid, tartaric acid, phthalic acid, citric acid, glutaric acid, lactic acid, and salicylic acid. Among these organic acids, oxalic acid and maleic acid are preferred. When the organic acid is added, the amount of the organic acid added is 0.1 to 5.0 mass % relative to the mass of the hydrolysis condensate of the hydrolyzable silane mixture. These organic acids may also serve as pH adjusters.

As the water, pure water, ultrapure water, ion exchanged water, or the like may be used. When pure water, ultrapure water, or ion exchanged water is used, the amount of the water added can be 0.1 to 20 parts by mass relative to 100 parts by mass of the surface modifier.

The alcohol is preferably an alcohol that is easily scattered by heating after the application, and examples of the alcohol include methanol, ethanol, propanol, i-propanol, and butanol. When an alcohol is added, the amount of the alcohol added may be 0.1 to 20 parts by mass relative to 100 parts by mass of the surface modifier.

### —Organic Polymer—

In a case where the surface modifier contains a polysiloxane, addition of an organic polymer to the surface modifier enables adjustment of the dry etching rate (amount of reduction in film thickness per unit time), attenuation coefficient, refractive index, and the like of the surface-modified layer formed from the surface modifier can be adjusted by adding an organic polymer to the surface modifier. The organic polymer is not particularly limited, and is appropriately selected from various organic polymers (polycondensation polymer and addition polymerization polymer) depending on the purpose of addition thereof.

Specific examples of the organic polymer include addition polymerization polymers and polycondensation polymers, such as polyester, polystyrene, polyimide, acrylic polymer, methacrylic polymer, polyvinyl ether, phenol novolac, naphthol novolac, polyether, polyamide, and polycarbonate.

In the present invention, an organic polymer having an aromatic or heteroaromatic ring that functions as a light-absorbing moiety (e.g. a benzene ring, a naphthalene ring, an anthracene ring, a triazine ring, a quinoline ring, or a quinoxaline ring) can also be suitably used in the case where such a function is required. Specific examples of such an organic polymer include, but are not limited to, addition polymerization polymers containing, as structural units, addition polymerizable monomers, such as benzyl acrylate, benzyl methacrylate, phenyl acrylate, naphthyl acrylate, anthryl methacrylate, anthryl methyl methacrylate, styrene, hydroxystyrene, benzyl vinyl ether, and N-phenylmaleimide, and condensation polycondensation polymers, such as phenol novolac and naphthol novolac.

When an addition polymerization polymer is used as an organic polymer, the polymer may be either a homopolymer or a copolymer.

An addition polymerizable monomer is used for the production of the addition polymerization polymer. Specific examples of the addition polymerizable monomer include, but are not limited to, acrylic acid, methacrylic acid, an acrylate ester compound, a methacrylate ester compound, an acrylamide compound, a methacrylamide compound, a vinyl compound, a styrene compound, a maleimide compound, maleic anhydride, and acrylonitrile.

Specific examples of the acrylate ester compound include, but are not limited to, methyl acrylate, ethyl acrylate, normal hexyl acrylate, i-propyl acrylate, cyclohexyl acrylate, benzyl acrylate, phenyl acrylate, anthrylmethyl acrylate, 2-hydroxyethyl acrylate, 3-chloro-2-hydroxypropyl acrylate, 2-hydroxypropyl acrylate, 2,2,2-trifluoroethyl acrylate, 2,2,2-trichloroethyl acrylate, 2-bromoethyl acrylate, 4-hydroxybutyl acrylate, 2-methoxyethyl acrylate, tetrahydrofurfuryl acrylate, 2-methyl-2-adamantyl acrylate, 5-acryloyloxy-δ-hydroxynorbornene-2-carboxylic-δ-lactone, 3-acryloxypropyltriethoxysilane, and glycidyl acrylate.

Specific examples of the methacrylate ester compound include, but are not limited to, methyl methacrylate, ethyl methacrylate, normal hexyl methacrylate, i-propyl methacrylate, cyclohexyl methacrylate, benzyl methacrylate, phenyl methacrylate, anthrylmethyl methacrylate, 2-hydroxyethyl methacrylate, 2-hydroxypropyl methacrylate, 2,2,2-trifluoroethyl methacrylate, 2,2,2-trichloroethyl methacrylate, 2-bromoethyl methacrylate, 4-hydroxybutyl methacrylate, 2-methoxyethyl methacrylate, tetrahydrofurfuryl methacrylate, 2-methyl-2-adamantyl methacrylate, 5-methacryloyloxy-6-hydroxynorbornene-2-carboxylic-6-lactone, 3-methacryloxypropyltriethoxysilane, glycidyl methacrylate, 2-phenylethyl methacrylate, hydroxyphenyl methacrylate, and bromophenyl methacrylate.

Specific examples of the acrylamide compound include, but are not limited to, acrylamide, N-methylacrylamide, N-ethylacrylamide, N-benzylacrylamide, N-phenylacrylamide, N,N-dimethylacrylamide, and N-anthrylacrylamide.

Specific examples of the methacrylamide compound include, but are not limited to, methacrylamide, N-methylmethacrylamide, N-ethylmethacrylamide, N-benzylmethacrylamide, N-phenylmethacrylamide, N,N-dimethylmethacrylamide, and N-anthrylmethacrylamide.

Specific examples of the vinyl compound include, but are not limited to, vinyl alcohol, 2-hydroxyethyl vinyl ether, methyl vinyl ether, ethyl vinyl ether, benzyl vinyl ether, vinyl acetic acid, vinyltrimethoxysilane, 2-chloroethyl vinyl ether, 2-methoxyethyl vinyl ether, vinylnaphthalene, and vinylanthracene.

Specific examples of the styrene compound include, but are not limited to, styrene, hydroxystyrene, chlorostyrene, bromostyrene, methoxystyrene, cyanostyrene, and acetylstyrene.

Examples of the maleimide compound include, but are not limited to, maleimide, N-methylmaleimide, N-phenylmaleimide, N-cyclohexylmaleimide, N-benzylmaleimide, and N-hydroxyethylmaleimide.

When a polycondensation polymer is used as the polymer, the polymer is, for example, a polycondensation polymer composed of a glycol compound and a dicarboxylic acid compound. Examples of the glycol compound include diethylene glycol, hexamethylene glycol, and butylene glycol. Examples of the dicarboxylic acid compound include succinic acid, adipic acid, terephthalic acid, and maleic anhydride. Further, examples of the polymer include, but are not limited to, polyesters, polyamides, and polyimides, such as polypyromellitimide, poly(p-phenyleneterephthalamide), polybutylene terephthalate, and polyethylene terephthalate.

When the organic polymer contains a hydroxy group, the hydroxy group may be crosslinked with a hydrolysis condensate, or the like.

The organic polymer may ordinarily have a weight-average molecular weight of 1,000 to 1,000,000. From the viewpoint of sufficiently achieving the effect of the polymer function and preventing the precipitation of the polymer in the composition, the weight-average molecular weight of the organic polymer to be added may be, for example, 3,000 to 300,000, 5,000 to 300,000, or 10,000 to 200,000.

The organic polymer may be used singly or in combination of two or more kinds thereof.

When the surface modifier contains an organic polymer in addition to the polysiloxane, the content of the organic polymer cannot be univocally determined, since the content should be appropriately determined in consideration of the function of the organic polymer or the like. Ordinarily, the content may be 1 to 200 mass % relative to the polysiloxane. From the viewpoint of preventing the precipitation of the organic polymer in the composition and the like, the content may be, for example, 100 mass % or less, preferably 50 mass % or less, and more preferably 30 mass % or less. From the viewpoint of sufficiently achieving the effect of the polymer and the like, the content may be, for example, 5 mass % or more, preferably 10 mass % or more, more preferably 30 mass % or more.

### —Acid Generator—

Examples of the acid generator include a thermal acid generator and a photoacid generator, and a photoacid generator may be preferably used.

Examples of the photoacid generator include, but are not limited to, an onium salt compound such as a sulfonium salt, a phosphonium salt, an ammonium salt, an iodonium salt, or an oxonium salt, a sulfonimide compound, and a disulfonyldiazomethane compound. The photoacid generator may also function as a curing catalyst depending on the type thereof, for example, a nitrate salt, a carboxylate salt (e.g. maleate), or a hydrochloride salt of an onium salt compound described below.

Examples of the thermal acid generator include, but are not limited to, tetramethylammonium nitrate.

Specific examples of the onium salt compound include, but are not limited to, iodonium salt compounds, such as diphenyliodonium hexafluorophosphate, diphenyliodonium trifluoromethanesulfonate, diphenyliodonium nonafluoro normal butanesulfonate, diphenyliodonium perfluoro normal octanesulfonate, diphenyliodonium camphorsulfonate, bis(4-t-butylphenyl)iodonium camphorsulfonate, and bis(4-t-butylphenyl)iodonium trifluoromethanesulfonate; and sulfonium salt compounds, such as triphenylsulfonium hexafluoroantimonate, triphenylsulfonium nonafluoro normal butanesulfonate, triphenylsulfonium camphorsulfonate, triphenylsulfonium trifluoromethanesulfonate, triphenylsulfonium nitrate, triphenylsulfonium trifluoroacetate, triphenylsulfonium maleate, and triphenylsulfonium chloride.

Specific examples of the sulfonimide compound include, but are not limited to, N-(trifluoromethanesulfonyloxy)succinimide, N-(nonafluoro normal butane sulfonyloxy)succinimide, N-(camphorsulfonyloxy)succinimide, and N-(trifluoromethanesulfonyloxy)naphthalimide.

Specific examples of the disulfonyldiazomethane compound include, but are not limited to, bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

When the surface modifier contains an acid generator, the content of the acid generator cannot be univocally determined, since the amount should be appropriately determined in consideration of the type of the acid generator and the like. Ordinarily, the content of the acid generator is 0.01 to 5 mass % relative to the mass of the polymer. From the viewpoint of preventing the precipitation of the acid generator in the composition and the like, the content is preferably 3 mass % or less, more preferably 1 mass % or less. From the viewpoint of sufficiently achieving the effect of the acid generator and the like, the content is preferably 0.1 mass % or more, more preferably 0.5 mass % or more.

The acid generators may be used singly or in combination of two or more kinds thereof. A photoacid generator and a thermal acid generator may be used in combination.

### —Surfactant—

When the surface modifier is applied to a substrate, a surfactant is effective in prevention of formation of pinholes, striations, and the like. Examples of the surfactant include a nonionic surfactant, an anionic surfactant, a cationic surfactant, a silicon-based surfactant, a fluorine-based surfactant, and a UV-curable surfactant. More specific examples of the surfactant include, but are not limited to, nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkylaryl ethers, such as polyoxyethylene octylphenol ether and polyoxyethylene nonylphenol ether, polyoxyethylene-polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine-based surfactants, such as trade names EFTOP (registered trademark) EF301, EF303, and EF352 (manufactured by Mitsubishi Materials Electronic Chemicals Co., Ltd. (former Tohkem Products Corporation)), trade names MEGAFACE (registered trademark) F171, F173, R-08, R-30, R-30N, and R-40LM (manufactured by DIC Corporation), Fluorad FC430 and FC431 (manufactured by 3M Japan Limited), trade name AsahiGuard (registered trademark) AG710 (manufactured by AGC Inc.), and trade names SURFLON (registered trademark) S-382, SC101, SC102, SC103, SC104, SC105, and SC106 (manufactured by AGC Seimi Chemical Co., Ltd.); and Organosiloxane Polymer KP341 (manufactured by Shin-Etsu Chemical Co., Ltd.).

The surfactants may be used singly or in combination of two or more kinds thereof.

When the surface modifier contains a surfactant, the content thereof is ordinarily 0.0001 to 5 mass %, preferably 0.001 to 4 mass %, and more preferably 0.01 to 3 mass % relative to the mass of the polymer.

### —Rheology Controlling Agent—

The rheology controlling agent is added mainly for the purpose of improving the fluidity of the surface modifier, particularly in a baking process, improving the uniformity of the film thickness of a film to be formed, or improving the fillability of the composition into holes. Specific examples of the rheology controlling agent include phthalic acid derivatives, such as dimethyl phthalate, diethyl phthalate, di-i-butyl phthalate, dihexyl phthalate, and butyl-i-decyl phthalate; adipic acid derivatives, such as di-normal butyl adipate, di-i-butyl adipate, di-i-octyl adipate, and octyl decyl adipate; maleic acid derivatives, such as di-normal butyl maleate, diethyl maleate, and dinonyl maleate; oleic acid derivatives, such as methyl oleate, butyl oleate, and tetrahydrofurfuryl oleate; and stearic acid derivatives, such as normal butyl stearate and glyceryl stearate.

When such a rheology controlling agent is used, the amount of the rheology controlling agent added is ordinarily less than 30 mass % relative to all film-forming components of the surface modifier.

### —Adhesion Aid—

The adhesion aid is added for the purpose of mainly improving the adhesion between a substrate or a resist and a film (surface-modified layer) formed from the surface modifier, in particular, suppressing or preventing the peeling of the resist during development. Specific examples of the adhesion aid include chlorosilanes, such as trimethylchlorosilane, dimethylvinylchlorosilane, methyldiphenylchlorosilane, and chloromethyldimethylchlorosilane; alkoxysilanes, such as trimethylmethoxysilane, dimethyldiethoxysilane, methyldimethoxysilane, and dimethylvinylethoxysilane; silazanes, such as hexamethyldisilazane, N,N′-bis(trimethylsilyl)urea, dimethyltrimethylsilylamine, and trimethylsilyl imidazole; other silanes, such as γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, mercaptopyrimidine; and urea or thiourea compounds, such as 1,1-dimethylurea and 1,3-dimethylurea.

When such an adhesion aid is used, the amount of the adhesion aid added is ordinarily less than 5 mass %, preferably less than 2 mass %, relative to the film-forming components of the surface modifier.

### —pH Adjuster—

In addition, the pH adjuster may be an acid having one or two or more carboxylic acid groups, for example, an organic acid described above in <<Stabilizer>>. When a pH adjuster is used, the amount of the pH adjuster added may be 0.01 to 20 parts by mass, 0.01 to 10 parts by mass, or 0.01 to 5 parts by mass relative to 100 parts by mass of the polymer.

### —Metal Oxide—

Examples of the metal oxide that may be added to the surface modifier include, but are not limited to, oxides of a combination of one or more selected from among metals, such as tin (Sn), titanium (Ti), aluminum (Al), zirconium (Zr), zinc (Zn), niobium (Nb), tantalum (Ta), and W (tungsten), and semimetals, such as boron (B), silicon (Si), germanium (Ge), arsenic (As), antimony (Sb), and tellurium (Te).

The concentration of the film-forming component in the surface modifier may be, for example, 0.01 to 50 mass %, 0.01 to 30 mass %, 0.01 to 25 mass %, or 0.01 to 20.0 mass % relative to the total mass of the composition.

The content of the polymer in the film-forming component is ordinarily 20 mass % to 100 mass %. From the viewpoint of achieving the effects of the present invention at high reproducibility or the like, the lower limit of the content is preferably 50 mass %, more preferably 60 mass %, still more preferably 70 mass %, and yet still more preferably 80 mass %. The upper limit of the content is preferably 99 mass %. The balance may be an additive described above.

Further, the surface modifier preferably has a pH of 1 to 5, more preferably a pH of 2 to 4.

The surface modifier can be produced by mixing a polymer, a solvent, and, if desired, an additional component. In this case, a solution containing the polymer (e.g. polysiloxane) may be prepared in advance, and this solution may be mixed with a solvent or an additional component.

During preparation of the surface modifier, the components may be appropriately heated so long as the components are not decomposed or denatured.

During the production of the surface modifier, or after all the components have been mixed, filtration may be performed using a submicrometer-order filter or the like. The type of the material of the filter used at this time is not limited. For example, a polyethylene filter, a nylon filter, a fluororesin filter, a polyimide filter, or the like can be used.

### <Second Step>

The second step is a step of bringing the surface-modified layer precursor into contact with a thinning liquid to thin the surface-modified layer precursor and to form a surface-modified layer having a film thickness of 5 nm or less.

In the second step, the method of bringing the surface-modified layer precursor into contact with the thinning liquid is not particularly limited. Spin coating is preferred from the viewpoint that the thickness can be uniformly thinned and the degree of thinning can be easily controlled with high accuracy. That is, the second step is preferably a step of spin-coating the surface-modified layer precursor with a thinning liquid to thin the surface-modified layer precursor and to form a surface-modified layer having a film thickness of 5 nm or less.

The conditions for spin coating are not particularly limited, and include, for example, an application treatment of applying a thinning liquid to the surface-modified layer precursor of the semiconductor substrate on which the surface-modified layer precursor is formed, and a rotation treatment of rotating the semiconductor substrate.

In the application treatment, for example, when the thinning liquid is applied to the surface-modified layer precursor, the semiconductor substrate is not rotated or rotated at a low speed (e.g. 1000 rpm or less). In the application treatment, the thinning liquid is brought into contact with the surface-modified layer precursor, and thus the components in the surface-modified layer precursor are transferred to the thinning liquid.

In the rotation treatment, for example, the semiconductor substrate is rotated at a high speed (e.g. more than 1,000 rpm and 5,000 rpm or less), and the thinning liquid is removed from the semiconductor substrate with the surface-modified layer precursor.

As a result of this process, the surface-modified layer precursor is thinned to the extent that the components in the surface-modified layer precursor are transferred to the thinning liquid. Consequently, a surface-modified layer having a film thickness of 5 nm or less is formed.

The time required for the application treatment is, for example, 10 seconds to 2 minutes.

The time required for the rotation treatment is, for example, 5 seconds to 1 minute.

At the time of rotation, for example, an axis orthogonal to the surface of the semiconductor substrate is set as a rotation axis.

In the second step, the film thickness of the surface-modified layer precursor is preferably reduced by 0.5 nm or more and 10 nm or less, more preferably reduced by 1 nm or more and 5 nm or less.

### <<Thinning Liquid>>

The thinning liquid is not particularly limited as long as it is a liquid in which the surface-modified layer precursor is brought into contact with the thinning liquid to thin the surface-modified layer precursor, and examples thereof include an organic solvent, water, an acidic solution, and an alkaline aqueous solution. Alternatively, a thinner used in a reducing resist consumption (RRC) step or an edge bead removing (EBR) step can be used. These materials can be used singly or in combination of two or more kinds thereof.

Examples of the organic solvent include alcohols, alkylene glycol alkyl ethers, and alkylene glycol monoalkyl ether carboxylic acid esters.

Examples of the alcohols include a monohydric alcohol solvent and a polyhydric alcohol solvent. Specific examples of the monohydric alcohol solvent and the polyhydric alcohol solvent include the monohydric alcohol solvents and polyhydric alcohol solvents described above as the solvents used for hydrolysis and condensation.

Examples of the alkylene glycol alkyl ethers include alkylene glycol monoalkyl ethers and alkylene glycol dialkyl ethers.

Examples of the alkylene glycol monoalkyl ether include ethylene glycol monomethyl ether, ethylene glycol monoethyl ether, ethylene glycol monopropyl ether, ethylene glycol monobutyl ether, propylene glycol monomethyl ether (1-methoxy-2-propanol), propylene glycol monoethyl ether (1-ethoxy-2-propanol), methyl isobutyl carbinol, and propylene glycol monobutyl ether.

Examples of the alkylene glycol dialkyl ether include diethylene glycol dimethyl ether, diethylene glycol diethyl ether, diethylene glycol dipropyl ether, diethylene glycol dibutyl ether, propylene glycol monomethyl ether, propylene glycol dimethyl ether, propylene glycol diethyl ether, propylene glycol dipropyl ether, and propylene glycol dibutyl ether.

Examples of the alkylene glycol monoalkyl ether carboxylic acid esters include alkylene glycol monoalkyl ether acetate.

Examples of the alkylene glycol monoalkyl ether acetate include methyl cellosolve acetate, ethyl cellosolve acetate, propylene glycol monomethyl ether acetate (1-methoxy-2-propanol monoacetate), propylene glycol monoethyl ether acetate, propylene glycol monopropyl ether acetate, propylene glycol monobutyl ether acetate, ethylene glycol monomethyl ether acetate, ethylene glycol monoethyl ether acetate, ethylene glycol monopropyl ether acetate, and ethylene glycol monobutyl ether acetate.

Specific examples of other organic solvents include toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl lactate, propyl lactate, isopropyl lactate, butyl lactate, isobutyl lactate, methyl formate, ethyl formate, propyl formate, isopropyl formate, butyl formate, isobutyl formate, amyl formate, isoamyl formate, methyl acetate, ethyl acetate, amyl acetate, isoamyl acetate, hexyl acetate, methyl propionate, ethyl propionate, propyl propionate, isopropyl propionate, butyl propionate, isobutyl propionate, methyl butyrate, ethyl butyrate, propyl butyrate, isopropyl butyrate, butyl butyrate, isobutyl butyrate, ethyl hydroxyacetate, ethyl 2-hydroxy-2-methylpropionate, methyl 3-methoxy-2-methylpropionate, methyl 2-hydroxyisobutyrate, methyl 3-hydroxyisobutyrate, methyl 2-hydroxy-3-methylbutyrate, ethyl methoxyacetate, ethyl ethoxyacetate, methyl 3-methoxypropionate, ethyl 3-ethoxypropionate, ethyl 3-methoxypropionate, 3-methoxybutyl acetate, 3-methoxypropyl acetate, 3-methyl-3-methoxybutyl acetate, 3-methyl-3-methoxybutyl propionate, 3-methyl-3-methoxybutyl butyrate, methyl acetoacetate, methyl propyl ketone, methyl butyl ketone, 2-heptanone, 3-heptanone, 4-heptanone, N,N-dimethylformamide, N-methylacetamide, N,N-dimethylacetamide, N-methyl-2-pyrrolidone, 4-methyl-2-pentanol, and γ-butyrolactone.

Examples of the acidic solution include an inorganic acid aqueous solution, an organic acid aqueous solution, and an organic acid solution. Examples of the inorganic acid aqueous solution include a hydrochloric acid aqueous solution, a nitric acid aqueous solution, a phosphoric acid aqueous solution, a sulfuric acid aqueous solution, and a perchloric acid aqueous solution. Examples of the organic acid aqueous solution include an acetic acid aqueous solution, a trifluoroacetic acid aqueous solution, a camphorsulfonic acid aqueous solution, a p-toluenesulfonic acid aqueous solution, and a trifluoromethanesulfonic acid aqueous solution. Examples of the organic acid solution include a solution prepared by replacing water in the organic acid aqueous solution with an organic solvent. Examples of the organic solvent include alkylene glycol alkyl ethers and alkylene glycol monoalkyl ether carboxylic acid esters.

Examples of the alkaline aqueous solution include developers used in a lithography process.

Examples of the alkaline aqueous solution include an inorganic alkaline aqueous solution and an organic alkaline aqueous solution. Examples of the inorganic alkaline aqueous solution include a potassium hydroxide aqueous solution, a sodium hydroxide aqueous solution, a sodium carbonate aqueous solution, a potassium carbonate aqueous solution, a sodium hydrogen carbonate aqueous solution, a potassium bicarbonate aqueous solution, a sodium phosphate aqueous solution, and a potassium phosphate aqueous solution. Examples of the organic alkaline aqueous solution include a tetramethylammonium hydroxide aqueous solution, a tetraethylammonium hydroxide aqueous solution, a tetrabutylammonium hydroxide aqueous solution, a monoethanolamine aqueous solution, a diethanolamine aqueous solution, and a triethanolamine aqueous solution.

The concentration of the alkali in the alkaline aqueous solution is not particularly limited.

The reducing resist consumption (RRC) step is a step for reducing the amount of photoresist used, and is a process for treating the surface of a substrate with a thinner before applying the photoresist to uniformly apply a small amount of photoresist to the entire surface of the substrate.

The edge bead removing (EBR) step is a step for removing residues of unnecessary photoresist applied to the end portion or the rear surface portion of the substrate in the application process and other contaminants.

Examples of the thinner used in the RRC step and the EBR step include propylene glycol monomethyl ether, propylene glycol monomethyl ether acetate, propylene glycol monoethyl ether, cyclohexanone, ethyl lactate, γ-butyrolactone, ethyl 3-ethoxypropionate, methyl hydroxyisobutyrate, and mixtures thereof.

In an embodiment of the present invention, in the laminate, an organic underlayer film may be provided between the semiconductor substrate and the surface-modified layer.

The organic underlayer film used here is not particularly limited, and may be arbitrarily selected from organic underlayer films commonly used in the lithography process.

In one aspect, the organic underlayer film is formed on the substrate, and the surface-modified layer is formed on the organic underlayer film, followed by formation of a resist film as described below on the surface-modified layer. This can narrow the pattern width of a resist film. Thus, even when the resist film is formed thinly for preventing pattern collapse, the substrate can be processed through selection of an appropriate etching gas described below. For example, the resist underlayer film can be processed by using, as the etching gas, a fluorine-containing gas having a sufficiently fast etching rate for the resist film, the organic underlayer film can be processed by using, as the etching gas, an oxygen-containing gas having a sufficiently fast etching rate for the resist underlayer film, and the substrate can be processed by using, as the etching gas, a fluorine-containing gas having a sufficiently fast etching rate for the organic underlayer film.

The substrate and application method usable in this process are the same as those described above.

### (Method for Producing Semiconductor Element)

The method for producing a semiconductor element of the present invention includes the steps of: forming a resist film on the laminate formed by the method for producing a laminate of the present invention; and exposing and developing the resist film to form a resist pattern.

For example, a layer (resist film) of a photoresist material is formed on a surface-modified layer. The resist film can be formed by a well-known method. Specifically, the resist film can be formed by applying a coating-type resist material (e.g. a composition for forming a resist film) onto the surface-modified layer, and baking the resist material.

The resist film has a film thickness of, for example, 10 nm to 10,000 nm, or 100 nm to 2,000 nm, or 200 nm to 1,000 nm, or 30 nm to 200 nm.

The photoresist material used for the resist film formed on the surface-modified layer is not particularly limited as long as it is sensitive to light used for exposure (e.g. a KrF excimer laser or an ArF excimer laser), and both a negative photoresist material and a positive photoresist material can be used. Examples of the photoresist include a positive photoresist material formed of a novolac resin and 1,2-naphthoquinone diazide sulfonic acid ester; a chemically amplified photoresist material formed of a binder having a group that is decomposed by an acid to increase an alkali dissolution rate and a photoacid generator; a chemically amplified photoresist material formed of a low molecular weight compound that is decomposed by an acid to increase an alkali dissolution rate of the photoresist material, an alkali-soluble binder, and a photoacid generator; a chemically amplified photoresist material formed of a binder having a group that is decomposed by an acid to increase an alkali dissolution rate, a low molecular weight compound having a group that is decomposed by an acid to increase an alkali dissolution rate of the photoresist material, and photoacid generator.

Specific examples of commercially available products thereof include, but are not limited to, APEX-E (trade name, manufactured by Shipley Company L.L.C), PAR710 (trade name, manufactured by Sumitomo Chemical Co., Ltd.), AR2772JN (trade name, manufactured by JSR Corporation), and SEPR430 (trade name, manufactured by Shin-Etsu Chemical Co., Ltd.). Further, examples of the photoresist include a fluorine-containing atomic polymer-based photoresist material as described in Proc. SPIE, Vol. 3999, 330-334 (2000), Proc. SPIE, Vol. 3999, 357-364 (2000), or Proc. SPIE, Vol. 3999, 365-374 (2000).

As the resist film formed on the surface-modified layer, a resist film for electron beam lithography (also referred to as an electron beam resist film) or a resist film for EUV lithography (also referred to as an EUV resist film) can be used instead of the photoresist film.

As the electron beam resist material for forming the electron beam resist film, both a negative type material and a positive type material can be used. Specific examples of the negative type material and the positive type material include: a chemically amplified resist material containing an acid generator and a binder having a group that is decomposed by an acid to change the alkali dissolution rate; a chemically amplified resist material containing an alkali-soluble binder, an acid generator, and a low molecular weight compound that is decomposed by an acid to change the alkali dissolution rate of the resist material; a chemically amplified resist material containing an acid generator, a binder having a group that is decomposed by an acid to change the alkali dissolution rate, and a low molecular weight compound that is decomposed by an acid to change the alkali dissolution rate of the resist material; a non-chemically amplified resist material containing a binder having a group that is decomposed by an electron beam to change the alkali dissolution rate; and a non-chemically amplified resist material containing a binder having a moiety that is cleaved by an electron beam to change the alkali dissolution rate. Even when these electron beam resist materials are used, a resist film pattern can be formed similarly to a case in which a photoresist material is used with an electron beam being used as an irradiation source.

As the EUV resist material for forming the EUV resist film, a methacrylate resin-based resist material, a polyhydroxystyrene resin-based resist material, and a methacrylate-polyhydroxystyrene hybrid resin-based resist material can be used.

The resist film may be a metal-containing resist film.

The metal-containing resist film is not particularly limited, and preferably has at least one element of Si, Ge, Sn, Ti, Zr, Hf, Al, and Co.

The metal-containing resist film is formed of, for example, a metal-containing resist.

The metal-containing resist is also called a metal oxide resist (metal oxide resist (MOR)), and typical examples thereof include a tin oxide-based resist.

The material of the metal oxide resist is, for example, a coating composition containing a metal oxo-hydroxo network having an organic ligand through a metal carbon bond and/or a metal carboxylate bond described in JP 2019-113855 A.

In an example of the metal-containing resist, a peroxo ligand is used as a radiation-sensitive stabilizing ligand. Details of the peroxo based metal oxo-hydroxo compounds are described, for example, in paragraph[0011] of JP 2019-532489 A: Patent Literature. Examples of the Patent Literature include U.S. Pat. No. 9,176,377 B2, US 2013/0224652 A1, U.S. Pat. No. 9,310,684 B2, US 2016/0116839 A1, and U.S. Ser. No. 15/291,738 A.

Other examples of the metal-containing resist include compositions described in JP 2011-253185 A, WO2015/026482 A, WO2016/065120 A, WO2017/066319 A, WO2017/156388 A, WO2018/031896 A, JP 2020-122959 A, JP 2020-122960 A, WO2019/099981 A, WO2019/199467 A, WO2019/195522 A, WO2019/195522 A, WO2020/210660 A, WO2021/011367 A, and WO2021/016229 A.

These contents are incorporated herein to the same extent as all the contents are specified.

The method for forming the metal-containing resist film from the metal-containing resist is not particularly limited, and examples thereof include a method in which a coating-type resist material (a composition for forming a metal-containing resist film) as the metal-containing resist is applied and baked.

The metal-containing resist film may be formed by vapor deposition. The method for forming the metal-containing resist film by vapor deposition is, for example, a method described in JP 2017-116923 A. The contents of JP 2017-116923 A are incorporated herein to the same extent as all the contents are specified. In JP 2017-116923 A, the metal-containing resist film in the present invention is referred to as a metal oxide-containing film.

Subsequently, light exposure is performed on the resist film formed above the surface-modified layer through a predetermined mask (reticle). The light exposure may be performed using a KrF excimer laser (wavelength: 248 nm), an ArF excimer laser (wavelength: 193 nm), an F₂ excimer laser (wavelength: 157 nm), EUV (wavelength: 13.5 nm), electron beams, or the like.

After the light exposure, post exposure bake may be performed as necessary. The post exposure bake is performed under appropriately selected conditions: a heating temperature of 70° C. to 150° C. and a heating time of 0.3 minutes to 10 minutes.

Next, development is performed with a developer (e.g. an alkaline developer). When, for example, a positive photoresist film is used, an exposed portion of the photoresist film is removed, and thus a pattern of the photoresist film is formed.

Examples of the developer (alkaline developer) include alkaline aqueous solutions (alkaline developers) such as: aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous amine solutions such as ethanolamine, propylamine, and ethylenediamine. Furthermore, a surfactant or the like may be added to these developers. Development conditions are appropriately selected from a temperature of 5 to 50° C., and a time of 10 seconds to 600 seconds.

In the present invention, an organic solvent can be used as a developer. Development is performed with a developer (solvent) after light exposure. When, for example, a negative photoresist film is used, an unexposed portion of the photoresist film is removed, and thus a pattern of the photoresist film is formed.

Examples of the developer (organic solvent) include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Furthermore, a surfactant or the like may be added to these developers. Development conditions are appropriately selected from a temperature of 5° C. to 50° C., and a time of 10 seconds to 600 seconds.

For example, the surface-modified layer is removed using the pattern of the resist film (upper layer) thus formed as a protective film, and then the substrate is processed using the patterned resist film and the patterned surface-modified layer as protective films.

The surface-modified layer is removed (patterned) through dry etching by using the patterned resist film (upper layer) as a protective film. The dry etching can be performed using any of gases, such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride, chlorine trifluoride, chlorine, trichloroborane, and dichloroborane.

The dry etching of the surface-modified layer is preferably performed using a halogen-containing gas. The resist film (photoresist film) made of an organic material is basically less likely to be removed by dry etching with a halogen-containing gas. In contrast, the surface-modified layer containing numerous silicon atoms is quickly removed by a halogen-containing gas. Accordingly, a reduction in the film thickness of the photoresist film in associated with the dry etching of the surface-modified layer can be suppressed. As a result, the photoresist film can be used in the form of thin film. Thus, the dry etching of the surface-modified layer is preferably performed using a fluorine-containing gas. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂).

Thereafter, the patterned surface-modified layer is used as a protective film to process (pattern) the (semiconductor) substrate. The (semiconductor) substrate is preferably processed (patterned) by dry etching with a fluorine-containing gas.

Examples of the fluorine-containing gas include tetrafluoromethane (CF₄), perfluorocyclobutane (C₄F₈), perfluoropropane (C₃F₈), trifluoromethane, and difluoromethane (CH₂F₂).

After processing (patterning) of the substrate, the surface-modified layer may be removed. The surface-modified layer may be removed by dry etching or wet etching.

The dry etching of the surface-modified layer is preferably performed with a fluorine-containing gas as described in the patterning. Examples of the fluorine-containing gas include, but are not limited to, tetrafluoromethane (CF₄), perfluorocyclobutane (C₄F₈), perfluoropropane (C₃F₈), trifluoromethane, and difluoromethane (CH₂F₂) Examples of the chemical used for wet etching of the surface-modified layer include alkaline solutions, such as dilute hydrofluoric acid (hydrofluoric acid), buffered hydrofluoric acid (mixed solution of HF and NH₄F), an aqueous solution containing hydrochloric acid and hydrogen peroxide (SC-2 chemical), an aqueous solution containing sulfuric acid and hydrogen peroxide (SPM chemical), an aqueous solution containing hydrofluoric acid and hydrogen peroxide (FPM chemical), and an aqueous solution containing ammonia and hydrogen peroxide (SC-1 chemical). Further, examples of the alkaline solution include an aqueous solution containing 1 to 99 mass % of ammonia, tetramethylammonium hydroxide (TMAH), tetraethylammonium hydroxide, tetrapropylammonium hydroxide, tetrabutylammonium hydroxide, choline hydroxide, benzyltrimethylammonium hydroxide, benzyltriethylammonium hydroxide, DBU (diazabicycloundecene), DBN (diazabicyclononene), hydroxylamine, 1-butyl-1-methylpyrrolidinium hydroxide, 1-propyl-1-methylpyrrolidinium hydroxide, 1-butyl-1-methylpiperidinium hydroxide, 1-propyl-1-methylpiperidinium hydroxide, mepiquat hydroxide, trimethylsulfonium hydroxide, a hydrazine compound, an ethylenediamine compound, or guanidine, in addition to the ammonia-hydrogen peroxide mixture prepared by mixing ammonia, hydrogen peroxide water, and water described above (SC-1 chemical). These chemicals may be used in the form of mixture.

### EXAMPLES

Hereinafter, the present invention will be described more specifically with reference to Synthesis Examples and Examples, but the present invention is not limited to only the following Examples.

In the Examples, apparatuses and conditions used for analysis of the physical properties of samples are as follows.

### (1) Measurement of Molecular Weight

The molecular weight of the polysiloxane used in the present invention is determined by GPC analysis in terms of polystyrene.

The GPC analysis can be performed, for example, under the following conditions: GPC apparatus (trade name: HLC-8220GPC, manufactured by Tosoh Corporation), GPC columns (trade name: Shodex (registered trademark) KF803L, KF802, and KF801, manufactured by Showa Denko K.K.), column temperature of 40° C., tetrahydrofuran as an eluent (elution solvent), flow amount (flow rate) of 1.0 mL/min, and polystyrene (manufactured by Showa Denko K.K.) as a standard sample.

### (2) ¹H-NMR

The evaluation was performed using a nuclear magnetic resonance apparatus ¹H-NMR (400 MHz), manufactured by JEOL Ltd., and d6-Acetone as a solvent.

### (3) Amount of Residual Nitric Acid

The amount of nitric acid remaining in the system was measured through ion chromatography evaluation.

### (4) AFM Observation

An area of 10 μm×10 μm was observed using AFM5500M manufactured by Hitachi High-Tech Corporation, and the roughness of the surface was evaluated.

### (5) Film Thickness Measurement

The film thickness of each material was measured using an Ellipsometric Film Thickness Measurement System RE-3100 (manufactured by SCREEN Semiconductor Solutions Co., Ltd.).

The film thickness of the surface-modified layer precursor was measured as described below. The film thickness of a SiO₂ oxide film formed on a substrate was measured in advance, then a surface modifier was applied to the substrate to form the surface-modified layer precursor, the film thickness was measured. A difference between the film thickness before application of the modifier and the film thickness after application of the modifier was taken as the film thickness of the surface-modified layer precursor.

The film thickness of the surface-modified layer was measured as described below. The film thickness of a SiO₂ oxide film formed on a substrate was measured in advance, a surface modifier was applied to the substrate and thinned, the film thickness was then measured. A difference between the film thickness before application of the modifier and the film thickness after application of the modifier and thinning was taken as the film thickness of the surface-modified layer.

### [1] Synthesis of Polymer (Hydrolysis Condensate)

### Synthesis Example 1

A 300 mL flask was charged with 31.89 g of phenyltrimethoxysilane and 47.83 g of propylene glycol monoethyl ether. While the resultant mixed solution was stirred with a magnetic stirrer, 20.28 g of 0.01M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 900 as determined by GPC in terms of polystyrene. The amount of Si atoms capped by the propylene glycol monoethyl ether was determined through ¹H-NMR to be 5 mol %. The amount of residual nitric acid in the polymer solution was 0.006%.

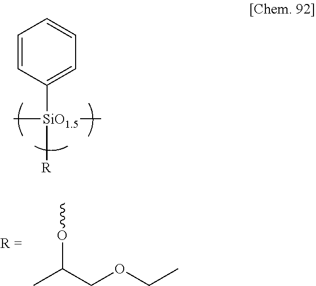

### Synthesis Example 2

A 300 mL flask was charged with 35.65 g of diallyl isocyanurate propyltriethoxysilane, 53.48 g of propylene glycol monoethyl ether. While the resultant mixed solution was stirred with a magnetic stirrer, 10.87 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2300 as determined by GPC in terms of polystyrene. The amount of Si atoms capped by the propylene glycol monoethyl ether was determined through ¹H-NMR to be 6 mol %. The amount of residual nitric acid in the polymer solution was 0.07%.

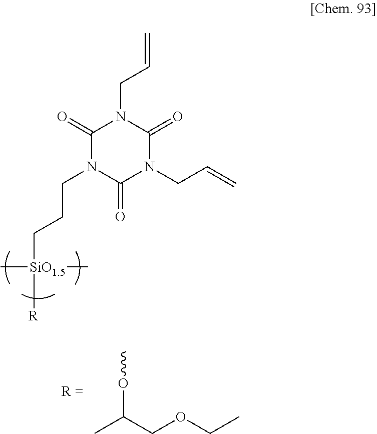

### Synthesis Example 3

A 300 mL flask was charged with 33.42 g of [bicyclo[2.2.1]hepto-5-ene-2-yl]triethoxysilane and 50.13 g of propylene glycol monoethyl ether. While the resultant mixed solution was stirred with a magnetic stirrer, 16.44 g of 1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1200 as determined by GPC in terms of polystyrene. The amount of Si atoms capped by the propylene glycol monoethyl ether was determined through ¹H-NMR to be 5 mol %. The amount of residual nitric acid in the polymer solution was 0.8%.

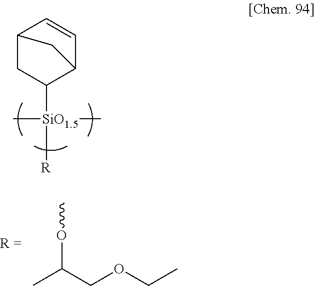

### Synthesis Example 4

A 300 mL flask was charged with 33.57 g of thiocyanatepropyltriethoxysilane and 50.36 g of propylene glycol monomethyl ether acetate. While the resultant mixed solution was stirred with a magnetic stirrer, 16.07 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monomethyl ether acetate was added to the resultant solution to achieve a solvent proportion of propylene glycol monomethyl ether acetate of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1800 as determined by GPC in terms of polystyrene. The amount of Si atoms capped by the propylene glycol monoalkyl ether was determined through ¹H-NMR to be 0 mol %. The amount of residual nitric acid in the polymer solution was 0.08%.

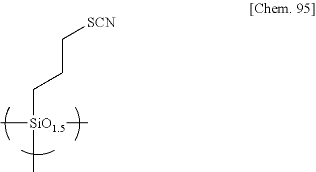

### Synthesis Example 5

A 300 mL flask was charged with 34.89 g of triethoxy((2-methoxy-4-(methoxymethyl)phenoxy)methyl)silane and 52.33 g of propylene glycol monoethyl ether. While the resultant mixed solution was stirred with a magnetic stirrer, 12.78 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1800 as determined by GPC in terms of polystyrene. The amount of Si atoms capped by the propylene glycol monoethyl ether was determined through ¹H-NMR to be 6 mol %. The amount of residual nitric acid in the polymer solution was 0.08%.

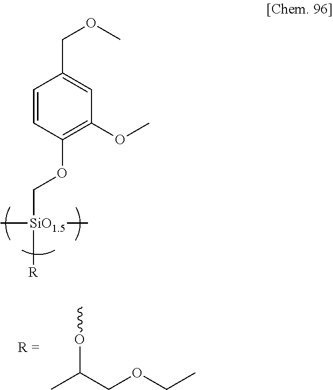

### Synthesis Example 6

A 300 mL flask was charged with 33.11 g of 4-methoxybenzyltrimethoxysilane and 49.66 g of propylene glycol monoethyl ether. While the resultant mixed solution was stirred with a magnetic stirrer, 17.23 g of 0.1M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1800 as determined by GPC in terms of polystyrene. The amount of Si atoms capped by the propylene glycol monoethyl ether was determined through ¹H-NMR to be 7 mol %. The amount of residual nitric acid in the polymer solution was 0.07%.

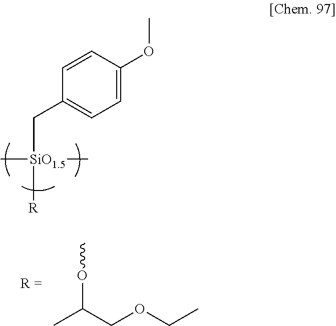

### Synthesis Example 7

A 300 mL flask was charged with 34.92 g of phenylsulfonylpropyltriethoxysilane and 52.37 g of propylene glycol monoethyl ether. While the resultant mixed solution was stirred with a magnetic stirrer, 12.71 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1500 as determined by GPC in terms of polystyrene. The amount of Si atoms capped by the propylene glycol monoethyl ether was determined through ¹H-NMR to be 5 mol %. The amount of residual nitric acid in the polymer solution was 0.07%.

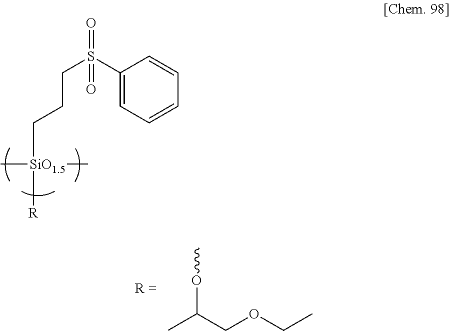

### Synthesis Example 8

A 300 mL flask was charged with 35.27 g of 4-methoxyphenylphenylsulfonylpropyltriethoxysilane and 52.91 g of propylene glycol monoethyl ether. While the resultant mixed solution was stirred with a magnetic stirrer, 11.82 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1400 as determined by GPC in terms of polystyrene. The amount of Si atoms capped by the propylene glycol monoethyl ether was determined through ¹H-NMR to be 6 mol %. The amount of residual nitric acid in the polymer solution was 0.08%.

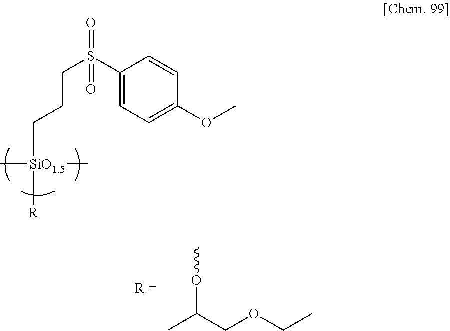

### Synthesis Example 9

A 300 mL flask was charged with 35.10 g of phenylsulfonylamidopropyltriethoxysilane and 52.65 g of propylene glycol monoethyl ether. While the resultant mixed solution was stirred with a magnetic stirrer, 12.25 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1600 as determined by GPC in terms of polystyrene. The amount of Si atoms capped by the propylene glycol monoethyl ether was determined through ¹H-NMR to be 4 mol %. The amount of residual nitric acid in the polymer solution was 0.08%.

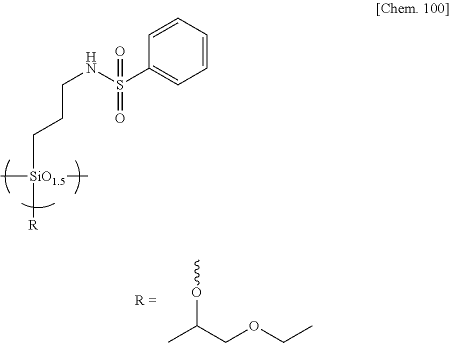

### Synthesis Example 10

A 300 mL flask was charged with 35.41 g of 4-methoxyphenylsulfonylamidopropyltriethoxysilane and 53.12 g of propylene glycol monoethyl ether. While the resultant mixed solution was stirred with a magnetic stirrer, 11.47 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1800 as determined by GPC in terms of polystyrene. The amount of Si atoms capped by the propylene glycol monoethyl ether was determined through ¹H-NMR to be 4 mol %. The amount of residual nitric acid in the polymer solution was 0.08%.

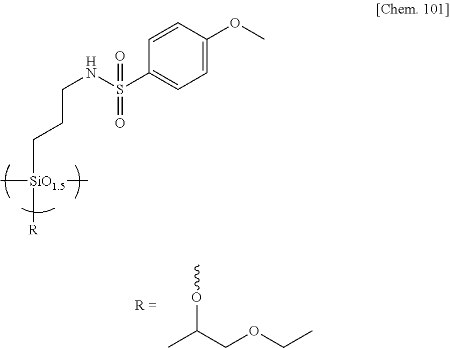

### Synthesis Example 11

A 300 mL flask was charged with 35.21 g of p-nitrobenzamide propyltriethoxysilane and 52.81 g of propylene glycol monoethyl ether. While the resultant mixed solution was stirred with a magnetic stirrer, 11.99 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1400 as determined by GPC in terms of polystyrene. The amount of Si atoms capped by the propylene glycol monoethyl ether was determined through ¹H-NMR to be 5 mol %. The amount of residual nitric acid in the polymer solution was 0.08%.

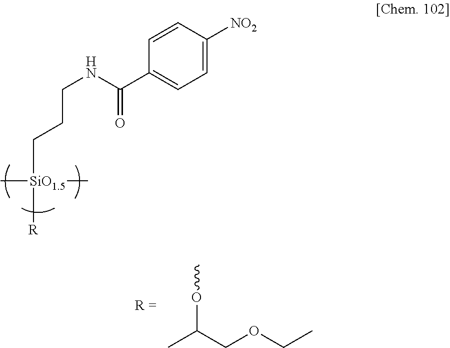

### Synthesis Example 12

A 300 mL flask was charged with 34.89 g of pentafluorophenyl methyltriethoxysilane and 52.33 g of propylene glycol monomethyl ether acetate. While the resultant mixed solution was stirred with a magnetic stirrer, 12.78 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monomethyl ether acetate was added to the resultant solution to achieve a solvent proportion of propylene glycol monomethyl ether acetate of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1100 as determined by GPC in terms of polystyrene. The amount of Si atoms capped by the propylene glycol monoalkyl ether was determined through ¹H-NMR to be 0 mol %. The amount of residual nitric acid in the polymer solution was 0.08%.

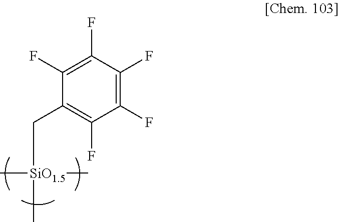

### Synthesis Example 13

A 300 mL flask was charged with 34.07 g of iodopropyltrimethoxysilane and 51.11 g of propylene glycol monoethyl ether. While the resultant mixed solution was stirred with a magnetic stirrer, 14.81 g of 0.1M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1300 as determined by GPC in terms of polystyrene. The amount of Si atoms capped by the propylene glycol monoethyl ether was determined through ¹H-NMR to be 6 mol %. The amount of residual nitric acid in the polymer solution was 0.07%.

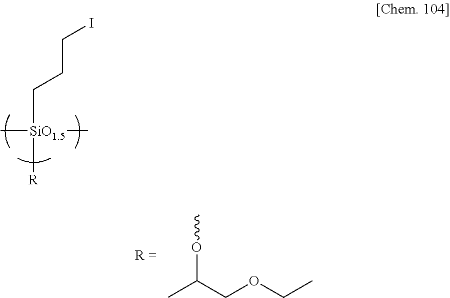

### Synthesis Example 14

A 300 mL flask was charged with 34.31 g of succinic anhydride propyltriethoxysilane and 51.47 g of propylene glycol monoethyl ether. While the resultant mixed solution was stirred with a magnetic stirrer, 14.22 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1600 as determined by GPC in terms of polystyrene. The amount of Si atoms capped by the propylene glycol monoethyl ether was determined through ¹H-NMR to be 6 mol %. The amount of residual nitric acid in the polymer solution was 0.08%.

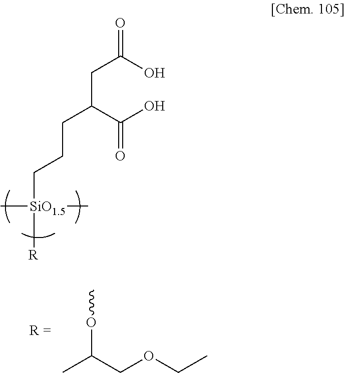

### Synthesis Example 15

A 300 mL flask was charged with 32.96 g of glycidyloxypropyltrimethoxysilane and 49.44 g of propylene glycol monoethyl ether. While the resultant mixed solution was stirred with a magnetic stirrer, 17.59 g of 1M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1600 as determined by GPC in terms of polystyrene. The amount of Si atoms capped by the propylene glycol monoethyl ether was determined through ¹H-NMR to be 7 mol %. The amount of residual nitric acid in the polymer solution was 0.8%.

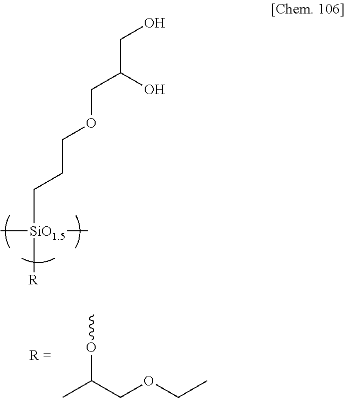

### Synthesis Example 16

A 300 mL flask was charged with 31.25 g of mercaptopropyltrimethoxysilane and 46.88 g of propylene glycol monoethyl ether. While the resultant mixed solution was stirred with a magnetic stirrer, 21.87 g of 0.1M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2500 as determined by GPC in terms of polystyrene. The amount of Si atoms capped by the propylene glycol monoethyl ether was determined through ¹H-NMR to be 5 mol %. The amount of residual nitric acid in the polymer solution was 0.08%.

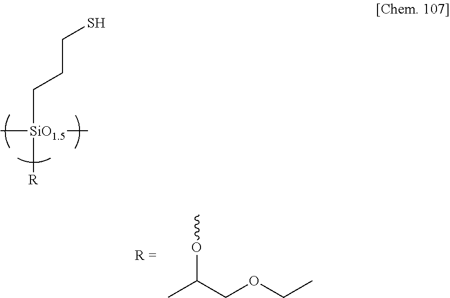

### Synthesis Example 17

A 300 mL flask was charged with 31.75 g of hydroxymethyltriethoxysilane and 47.63 g of propylene glycol monoethyl ether. While the resultant mixed solution was stirred with a magnetic stirrer, 20.61 g of 0.01M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2800 as determined by GPC in terms of polystyrene. The amount of Si atoms capped by the propylene glycol monoethyl ether was determined through ¹H-NMR to be 4 mol %. The amount of residual nitric acid in the polymer solution was 0.008%.

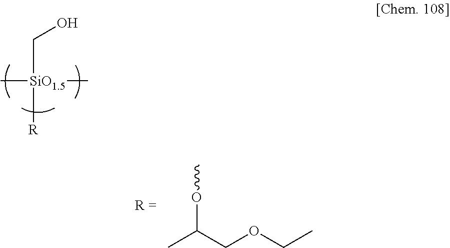

### Synthesis Example 18

A 300 mL flask was charged with 32.92 g of methylaminopropyltrimethoxysilane and 49.37 g of propylene glycol monoethyl ether. While the resultant mixed solution was stirred with a magnetic stirrer, 17.71 g of 0.1M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1000 as determined by GPC in terms of polystyrene. The amount of Si atoms capped by the propylene glycol monoethyl ether was determined through ¹H-NMR to be 5 mol %. The amount of residual nitric acid in the polymer solution was 0.08%.

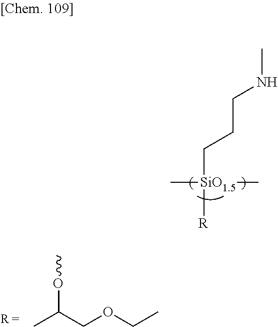

### Synthesis Example 19

A 300 mL flask was charged with 32.46 g of cyanoethyltriethoxysilane and 48.70 g of propylene glycol monoethyl ether. While the resultant mixed solution was stirred with a magnetic stirrer, 18.84 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1500 as determined by GPC in terms of polystyrene. The amount of Si atoms capped by the propylene glycol monoethyl ether was determined through ¹H-NMR to be 6 mol %. The amount of residual nitric acid in the polymer solution was 0.08%.

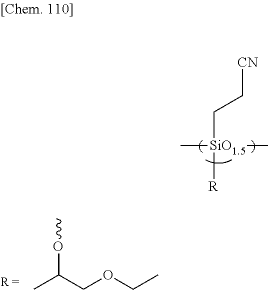

### Synthesis Example 20

A 300 mL flask was charged with 33.25 g of methacryloxypropyltrimethoxysilane and 49.87 g of propylene glycol monoethyl ether. While the resultant mixed solution was stirred with a magnetic stirrer, 16.89 g of 0.1M nitric acid aqueous solution was added dropwise to the mixed solution.

After the dropwise addition, the flask was transferred to an oil bath set at 120° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2400 as determined by GPC in terms of polystyrene. The amount of Si atoms capped by the propylene glycol monoethyl ether was determined through ¹H-NMR to be 5 mol %. The amount of residual nitric acid in the polymer solution was 0.08%.

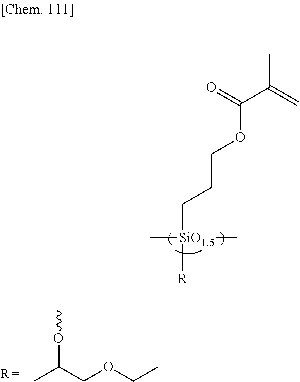

### Synthesis Example 21

A 300 mL flask was charged with 34.30 g of O-(propargyl)-N-(triethoxysilylpropyl)carbamate and 51.44 g of propylene glycol monoethyl ether. While the resultant mixed solution was stirred with a magnetic stirrer, 14.26 g of 0.1M nitric acid aqueous solution was added dropwise to the mixed solution.

After the dropwise addition, the flask was transferred to an oil bath set at 120° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1400 as determined by GPC in terms of polystyrene. The amount of Si atoms capped by the propylene glycol monoethyl ether was determined through ¹H-NMR to be 6 mol %. The amount of residual nitric acid in the polymer solution was 0.08%.

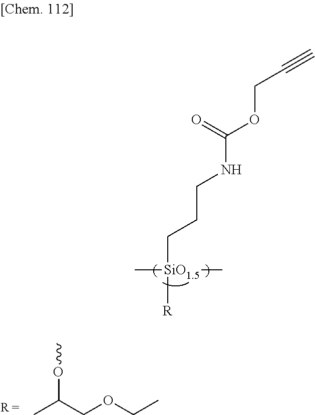

### Synthesis Example 22

A 300 mL flask was charged with 15.49 g of diallyl isocyanurate propyltriethoxysilane, 18.21 g of tetraethoxysilane, and 50.55 g of propylene glycol monoethyl ether. While the resultant mixed solution was stirred with a magnetic stirrer, 15.75 g of 0.1M nitric acid aqueous solution was added dropwise to the mixed solution.

After the dropwise addition, the flask was transferred to an oil bath set at 60° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2500 as determined by GPC in terms of polystyrene. The amount of Si atoms capped by the propylene glycol monoethyl ether was determined through ¹H-NMR to be 8 mol %. The amount of residual nitric acid in the polymer solution was 0.08%.

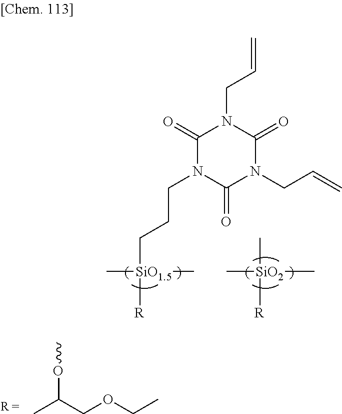

### Synthesis Example 23

A 300 mL flask was charged with 17.76 g of (3-triethoxysilyl)propylsuccinic anhydride, 16.37 g of triphenylsulfonium hydroxide, and 51.17 g of propylene glycol monoethyl ether. While the resultant mixed solution was stirred with a magnetic stirrer, 14.72 g of 0.1M nitric acid aqueous solution was added dropwise to the mixed solution.

After the dropwise addition, the flask was transferred to an oil bath set at 100° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1200 as determined by GPC in terms of polystyrene. The amount of Si atoms capped by the propylene glycol monoethyl ether was determined through ¹H-NMR to be 3 mol %. The amount of residual nitric acid in the polymer solution was 0.07%.

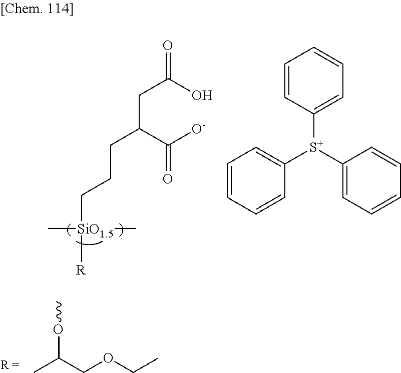

### Synthesis Example 24

A 300 mL flask was charged with 12.89 g of 3-(trihydroxysilyl)-1-propanesulfonic acid, 20.68 g of triphenylsulfonium hydrogencarbonate, and 50.35 g of propylene glycol monoethyl ether. While the resultant mixed solution was stirred with a magnetic stirrer, 16.08 g of 0.1M nitric acid aqueous solution was added dropwise to the mixed solution.

After the dropwise addition, the flask was transferred to an oil bath set at 100° C. and the mixed solution was reacted for 20 hours. Thereafter, a reaction by-product: water was distilled off under reduced pressure for concentration to obtain a hydrolysis condensate (polymer)

### Solution

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1800 as determined by GPC in terms of polystyrene. The amount of Si atoms capped by the propylene glycol monoethyl ether was determined through ¹H-NMR to be 5 mol %. The amount of residual nitric acid in the polymer solution was 0.08%.

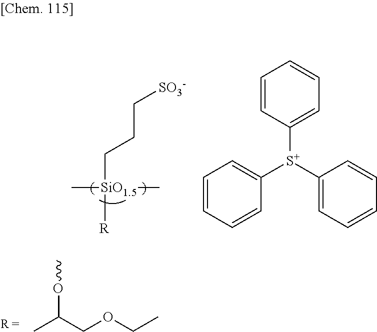

### Synthesis Example 25

A 300 mL flask was charged with 37.38 g of 2-(((2-hydroxy-5-(2-trimethoxysilyl)ethylcyclohexyl)oxy)carbonyl)phenyl phenyl iodonium trifluoromethanesulfonate and 56.07 g of propylene glycol monoethyl ether. While the resultant mixed solution was stirred with a magnetic stirrer, 6.54 g of 0.1M nitric acid aqueous solution was added dropwise to the mixed solution.

After the dropwise addition, the flask was transferred to an oil bath set at 100° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1500 as determined by GPC in terms of polystyrene. The amount of Si atoms capped by the propylene glycol monoethyl ether was determined through ¹H-NMR to be 4 mol %. The amount of residual nitric acid in the polymer solution was 0.06%.

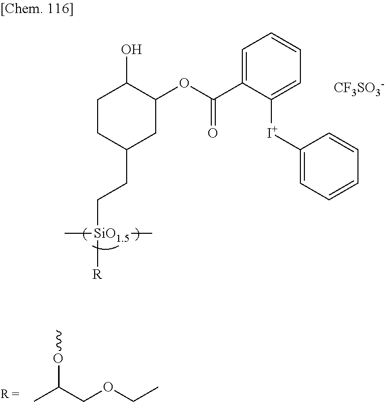

### Synthesis Example 26

A 300 mL flask was charged with 37.74 g of (3-((2-hydroxy-5-(2-(trimethoxysilyl)ethyl)cyclohexyl)oxy)phenyl) (4-hydroxyphenyl) (phenyl)sulfonium nonafluorobutanesulfonate, and 56.60 g of propylene glycol monoethyl ether. While the resultant mixed solution was stirred with a magnetic stirrer, 5.66 g of 0.1M nitric acid aqueous solution was added dropwise to the mixed solution.

After the dropwise addition, the flask was transferred to an oil bath set at 100° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2200 as determined by GPC in terms of polystyrene. The amount of Si atoms capped by the propylene glycol monoalkyl ether was determined through ¹H-NMR to be 3 mol %. The amount of residual nitric acid in the polymer solution was 0.08%.

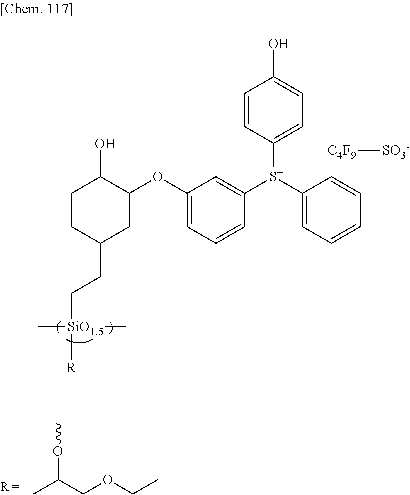

### Synthesis Example 27

A 300 mL flask was charged with 16.69 g of (3-triethoxysilyl)propylsuccinic anhydride, 17.77 g of diphenyliodonium-2-carboxylate, and 51.70 g of propylene glycol monoethyl ether. While the resultant mixed solution was stirred with a magnetic stirrer, 12.78 g of 0.1M nitric acid aqueous solution was added dropwise to the mixed solution.

After the dropwise addition, the flask was transferred to an oil bath set at 100° C. and the mixed solution was reacted for 20 hours. Thereafter, ethanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1500 as determined by GPC in terms of polystyrene. The amount of Si atoms capped by the propylene glycol monoethyl ether was determined through ¹H-NMR to be 6 mol %. The amount of residual nitric acid in the polymer solution was 0.08%.

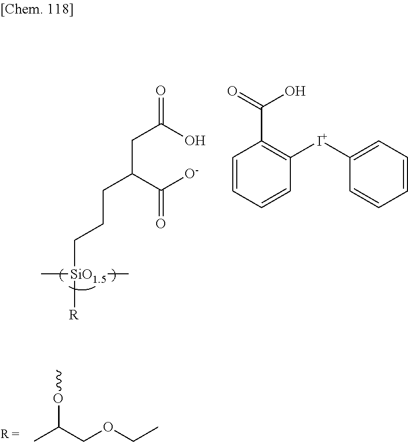

### Synthesis Example 28

A 300 mL flask was charged with 12.90 g of 3-(trihydroxysilyl)-1-propanesulfonic acid, 20.67 g of diphenyliodonium-2-carboxylate, and 50.35 g of propylene glycol monoethyl ether. While the resultant mixed solution was stirred with a magnetic stirrer, 16.09 g of 0.1M nitric acid aqueous solution was added dropwise to the mixed solution.

After the dropwise addition, the flask was transferred to an oil bath set at 100° C. and the mixed solution was reacted for 20 hours. Thereafter, a reaction by-product: water was distilled off under reduced pressure for concentration to obtain a hydrolysis condensate (polymer)

### Solution

Further, propylene glycol monoethyl ether was added to the resultant solution to achieve a solvent proportion of propylene glycol monoethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2000 as determined by GPC in terms of polystyrene. The amount of Si atoms capped by the propylene glycol monoethyl ether was determined through ¹H-NMR to be 3 mol %. The amount of residual nitric acid in the polymer solution was 0.06%.

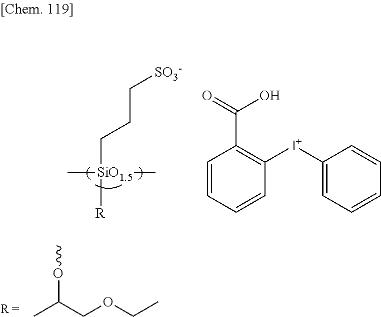

### Synthesis Example 29

A 300 mL flask was charged with 5.99 g of N-(3-trihydroxysilylpropyl)-4,5-dihydroimidazole, 3.77 g of p-toluenesulfonic acid, and 87.87 g of propylene glycol monoethyl ether. While the resultant mixed solution was stirred with a magnetic stirrer, 2.37 g of 0.1M nitric acid aqueous solution was added dropwise to the mixed solution.

After the dropwise addition, the flask was transferred to an oil bath set at 60° C. and the mixed solution was reacted for 20 hours. Thereafter, a reaction by-product: water was distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 5 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 1000 as determined by GPC in terms of polystyrene. The amount of Si atoms capped by the propylene glycol monoethyl ether was determined through ¹H-NMR to be 3 mol %. The amount of residual nitric acid in the polymer solution was 0.07%.

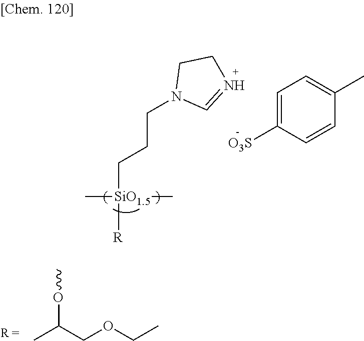

### Synthesis Example 30

A 300 mL flask was charged with 38.4 g of 2-(((2-hydroxy-5-(2-(trimethoxysilyl)ethyl)cyclohexyl)oxy)carbonyl)-3,4,5,6-tetraiodobenzene sulfonate triphenylsulfonium and 57.6 g of propylene glycol monoethyl ether. While the resultant mixed solution was stirred with a magnetic stirrer, 3.99 g of 0.1M nitric acid aqueous solution was added dropwise to the mixed solution.

After the dropwise addition, the flask was transferred to an oil bath set at 100° C. and the mixed solution was reacted for 20 hours. Thereafter, methanol, and water, i.e. reaction by-products, were distilled off under reduced pressure for concentration to obtain a hydrolysis condensate (polymer) solution.

Further, propylene glycol monoethyl ether was added to the resultant solution to achieve a solvent proportion of propylene glycol monoethyl ether of 100% and a concentration of 5 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 2200 as determined by GPC in terms of polystyrene. The amount of Si atoms capped by the propylene glycol monoethyl ether was determined through ¹H-NMR to be 4 mol %. The amount of residual nitric acid in the polymer solution was 0.07%.

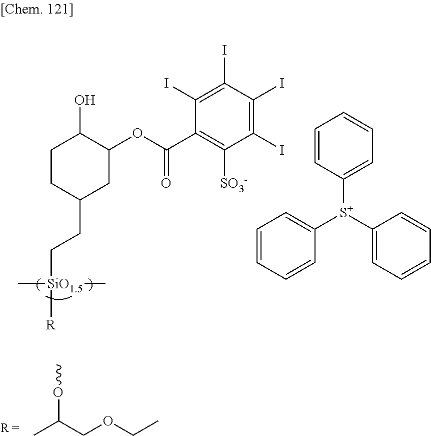

### Comparative Synthesis Example 1

A 300 mL flask was charged with 32.20 g of tetraethoxysilane and 48.3 g of propylene glycol monoethyl ether. While the resultant mixed solution was stirred with a magnetic stirrer, 19.5 g of nitric acid aqueous solution (0.1 mol/L) was added dropwise to the mixed solution.

After the dropwise addition, the flask was transferred to an oil bath set at 60° C. and the mixed solution was refluxed for 20 hours. Thereafter, ethanol, and water, i.e. reaction by-products, were distilled off under reduced pressure for concentration to obtain a hydrolysis condensate (polymer) solution.

Further, propylene glycol monomethyl ether was added to the solution to achieve a solvent proportion of propylene glycol monomethyl ether of 100% and a concentration of 20 mass % in terms of solid residue at 140° C. The resultant solution was subjected to filtration with a nylon-made filter (pore size: 0.1 μm).

The resultant polymer was found to contain a polysiloxane including a structure represented by the following Formula, and to have a weight-average molecular weight Mw of 5,800 as determined by GPC in terms of polystyrene. The amount of Si atoms capped by the propylene glycol monomethyl ether was determined through 1H-NMR to be 9 mol %. The amount of residual nitric acid in the polymer solution was 0.08%.

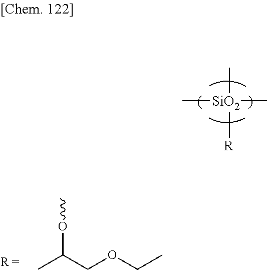

### [2] Preparation of Surface Modifier (Application Liquid)

The polysiloxane (polymer) produced in each of the Synthesis Examples, an acid (additive 1), a photoacid generator and a curing catalyst (additive 2), and a solvent were mixed in proportions shown in Table 1-1, Table 1-2, or Table 1-3. The resultant mixture was filtered through a 0.1 μm fluororesin filter to prepare each surface modifier (application liquid). In Tables 1-1 to 1-3, the amount of each component added is shown by part(s) by mass.

Although the composition was prepared from the solution containing the hydrolysis condensate (polymer) produced in each Synthesis Example, the amount of each polymer shown in Tables 1-1 to 1-3 corresponds not to the amount of the polymer solution, but to the amount of the polymer itself.

The meanings of the abbreviations in Tables 1-1 to 1-3 are shown below.

### <Solvent>

DIW: ultrapure water
PGEE: propylene glycol monoethyl ether
PGME: propylene glycol monomethyl ether
PGMEA: propylene glycol monomethyl ether acetate

### <Additive 1>

MA: maleic acid

### <Additive 2>

TPSNO3: triphenylsulfonium nitrate
TPSML: triphenylsulfonium maleate
TPSTfAc: triphenylsulfonium trifluoroacetate
TPSAc: triphenylsulfonium acetate
BTEAC: benzyltriethylammonium chloride salt
ImidTEOS: N-(3-triethoxysilylpropyl)-4,5-dihydroimidazole
DAICATEOS: diallyl isocyanurate propyltriethoxysilane

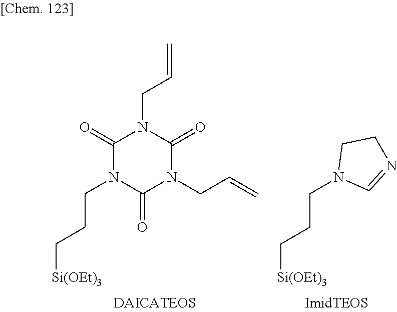

TABLE 1-1

| | Polymer | Additive 1 | Additive 2 | Solvent | | |
|---|---|---|---|---|---|---|
| Application | Synthesis | MA | TPSN03 | PGEE | PGME | DIW |
| liquid 1 | Example 1 | | | | | |
| (Parts by | 0.25 | 0.0025 | 0.0025 | 80 | 8 | 12 |
| mass) | | | | | | |
| Application | Synthesis | MA | TPSML | PGEE | PGME | DIW |
| liquid 2 | Example 2 | | | | | |
| (Parts by | 0.25 | 0.0025 | 0.0025 | 80 | 8 | 12 |
| mass) | | | | | | |
| Application | Synthesis | MA | TPSTfAc | PGEE | PGME | DIW |
| liquid 3 | Example 3 | | | | | |
| (Parts by | 0.25 | 0.0025 | 0.0025 | 80 | 8 | 12 |
| mass) | | | | | | |
| Application | Synthesis | MA | TPSN03 | PGEE | PGMEA | DIW |
| liquid 4 | Example 4 | | | | | |
| (Parts by | 0.25 | 0.0025 | 0.0025 | 80 | 8 | 12 |
| mass) | | | | | | |
| Application | Synthesis | MA | TPSAc | PGEE | PGME | DIW |
| liquid 5 | Example 5 | | | | | |
| (Parts by | 0.25 | 0.0025 | 0.0025 | 80 | 8 | 12 |
| mass) | | | | | | |
| Application | Synthesis | MA | BTEAC | PGEE | PGME | DIW |
| liquid 6 | Example 6 | | | | | |
| (Parts by | 0.25 | 0.0025 | 0.0025 | 80 | 8 | 12 |
| mass) | | | | | | |
| Application | Synthesis | MA | — | PGEE | PGME | DIW |
| liquid 7 | Example 7 | | | | | |
| (Parts by | 0.25 | 0.0025 | — | 80 | 8 | 12 |
| mass) | | | | | | |
| Application | Synthesis | MA | TPSN03 | PGEE | PGME | DIW |
| liquid 8 | Example 8 | | | | | |
| (Parts by | 0.25 | 0.0025 | 0.0025 | 80 | 8 | 12 |
| mass) | | | | | | |
| Application | Synthesis | MA | TPSML | PGEE | PGME | DIW |
| liquid 9 | Example 9 | | | | | |
| (Parts by | 0.25 | 0.0025 | 0.0025 | 80 | 8 | 12 |
| mass) | | | | | | |
| Application | Synthesis | MA | TPSTfAc | PGEE | PGME | DIW |
| liquid 10 | Example 10 | | | | | |
| (Parts by | 0.25 | 0.0025 | 0.0025 | 80 | 8 | 12 |
| mass) | | | | | | |
| Application | Synthesis | MA | — | PGEE | PGME | DIW |
| liquid 11 | Example 11 | | | | | |
| (Parts by | 0.25 | 0.0025 | — | 80 | 8 | 12 |
| mass) | | | | | | |
| Application | Synthesis | MA | TPSAc | PGEE | PGMEA | DIW |
| liquid 12 | Example 12 | | | | | |
| (Parts by | 0.25 | 0.0025 | 0.0025 | 80 | 8 | 12 |
| mass) | | | | | | |
| Application | Synthesis | MA | BTEAC | PGEE | PGME | DIW |
| liquid 13 | Example 13 | | | | | |
| (Parts by | 0.25 | 0.0025 | 0.0025 | 80 | 8 | 12 |
| mass) | | | | | | |

TABLE 1-2

| | Polymer | Additive 1 | Additive 2 | Solvent | | |
|---|---|---|---|---|---|---|
| Application | Synthesis | MA | TPSN03 | PGEE | PGME | DIW |
| liquid 14 | Example 14 | | | | | |
| (Parts by | 0.25 | 0.0025 | 0.0025 | 80 | 8 | 12 |
| mass) | | | | | | |
| Application | Synthesis | MA | TPSN03 | PGEE | PGME | DIW |
| liquid 15 | Example 15 | | | | | |
| (Parts by | 0.25 | 0.0025 | 0.0025 | 80 | 8 | 12 |
| mass) | | | | | | |
| Application | Synthesis | MA | TPSML | PGEE | PGME | DIW |
| liquid 16 | Example 16 | | | | | |
| (Parts by | 0.25 | 0.0025 | 0.0025 | 80 | 8 | 12 |
| mass) | | | | | | |
| Application | Synthesis | MA | TPSTfAc | PGEE | PGMEA | DIW |
| liquid 17 | Example 17 | | | | | |
| (Parts by | 0.25 | 0.0025 | 0.0025 | 80 | 8 | 12 |
| mass) | | | | | | |
| Application | Synthesis | MA | TPSN03 | PGEE | PGME | DIW |
| liquid 18 | Example 18 | | | | | |
| (Parts by | 0.25 | 0.0025 | 0.0025 | 80 | 8 | 12 |
| mass) | | | | | | |
| Application | Synthesis | MA | — | PGEE | PGME | DIW |
| liquid 19 | Example 19 | | | | | |
| (Parts by | 0.25 | 0.0025 | — | 80 | 8 | 12 |
| mass) | | | | | | |
| Application | Synthesis | MA | BTEAC | PGEE | PGME | DIW |
| liquid 20 | Example 20 | | | | | |
| (Parts by | 0.25 | 0.0025 | 0.0025 | 80 | 8 | 12 |
| mass) | | | | | | |
| Application | Synthesis | MA | TPSN03 | PGEE | PGME | DIW |
| liquid 21 | Example 21 | | | | | |
| (Parts by | 0.25 | 0.0025 | 0.0025 | 80 | 8 | 12 |
| mass) | | | | | | |
| Application | Synthesis | MA | TPSN03 | PGEE | PGME | DIW |
| liquid 22 | Example 22 | | | | | |
| (Parts by | 0.25 | 0.0025 | 0.0025 | 80 | 8 | 12 |
| mass) | | | | | | |
| Comparative | Comparative | MA | BTEAC | PGEE | PGME | DIW |
| application | Synthesis | | | | | |
| liquid 1 | Example 1 | | | | | |
| (Parts by | 0.25 | 0.0025 | 0.0025 | 80 | 8 | 12 |
| mass) | | | | | | |
| Comparative | Comparative | MA | TPSAc | PGEE | PGME | DIW |
| application | Synthesis | | | | | |
| liquid 2 | Example 1 | | | | | |
| (Parts by | 0.1 | 0.001 | 0.001 | 80 | 8 | 12 |
| mass) | | | | | | |
| Comparative | DAICATEOS | MA | ImidTEOS | PGEE | PGMEA | DIW |
| application | | | | | | |
| liquid 3 | | | | | | |
| (Parts by | 0.1 | 0.01 | 0.00005 | 87 | 5 | 8 |
| mass) | | | | | | |

TABLE 1-3

| | Polymer | Additive 1 | Additive 2 | Solvent | | |
|---|---|---|---|---|---|---|
| Application | Synthesis | MA | — | PGEE | PGME | — |
| liquid 101 | Example 23 | | | | | |
| (Parts by | 0.25 | 0.0025 | — | 80 | 20 | — |
| mass) | | | | | | |
| Application | Synthesis | MA | — | PGEE | PGME | DIW |
| liquid 102 | Example 24 | | | | | |
| (Parts by | 0.25 | 0.0025 | — | 80 | 8 | 12 |
| mass) | | | | | | |
| Application | Synthesis | MA | — | PGEE | PGME | DIW |
| liquid 103 | Example 25 | | | | | |
| (Parts by | 0.25 | 0.0025 | — | 80 | 8 | 12 |
| mass) | | | | | | |
| Application | Synthesis | MA | — | PGEE | PGMEA | — |
| liquid 104 | Example 26 | | | | | |
| (Parts by | 0.25 | 0.0025 | — | 80 | 20 | — |
| mass) | | | | | | |
| Application | Synthesis | MA | — | PGEE | PGME | DIW |
| liquid 105 | Example 27 | | | | | |
| (Parts by | 0.25 | 0.0025 | — | 80 | 8 | 12 |
| mass) | | | | | | |
| Application | Synthesis | MA | — | PGEE | PGME | DIW |
| liquid 106 | Example 28 | | | | | |
| (Parts by | 0.25 | 0.0025 | — | 80 | 8 | 12 |
| mass) | | | | | | |
| Application | Synthesis | MA | — | PGEE | PGME | DIW |
| liquid 107 | Example 29 | | | | | |
| (Parts by | 0.25 | 0.0025 | — | 80 | 8 | 12 |
| mass) | | | | | | |
| Application | Synthesis | MA | — | PGEE | PGME | DIW |
| liquid 108 | Example 30 | | | | | |
| (Parts by | 0.25 | 0.0025 | — | 80 | 8 | 12 |
| mass) | | | | | | |
| Comparative | Comparative | MA | — | PGEE | PGME | DIW |
| application | Synthesis | | | | | |
| liquid 101 | Example 1 | | | | | |
| (Parts by | 0.25 | 0.0025 | — | 80 | 8 | 12 |
| mass) | | | | | | |

Application liquids 1 to 22 and 101 to 108 and comparative application liquids 1 to 2 and 101 further contain nitric acid contained in the polymer solution prepared in each of Synthesis Examples 1 to 30 and Comparative Synthesis Example 1. The comparative application liquid 3 contains no nitric acid.

### [3-1] Thinning Test

The prepared application liquids 1 to 22 and the comparative application liquids 1 to 3 were applied onto silicon wafers using a spinner. The resultant wafers were heated on a hot plate at 120° C. or 215° C. for 1 minute to form surface-modified layer precursors. Thereafter, a mixed solvent of propylene glycol monomethyl ether/propylene glycol monomethyl ether acetate (7/3 (V/V) thinning liquid) was applied onto each of the surface-modified layer precursors, and then left to stand for 60 seconds. Thereafter, each of the wafers were rotated to shake off the solvent, baked at 100° C. for 30 seconds, and dried. The film thickness of each of the surface-modified layers after application of the thinning liquid was measured. The surface modifier in which the film thickness was reduced to 50 Å or less was evaluated as “good”, the surface modifier in which the film thickness was more than 50 Å and could not be thinned was evaluated as “non-thinned”, and the surface modifier in which AFM observation showed non-uniformity in film thickness evaluated as “non-uniformity in film thickness”. The results are shown in Table 2-1.

TABLE 2-1

| | Application | Baking | Film |
|---|---|---|---|
| | liquid | temperature | formability |
| Example 1 | Application | 215° C. | Good |
| | liquid 1 | | |
| Example 2 | Application | 215° C. | Good |
| | liquid 2 | | |
| Example 3 | Application | 120° C. | Good |
| | liquid 3 | | |
| Example 4 | Application | 215° C. | Good |
| | liquid 4 | | |
| Example 5 | Application | 120° C. | Good |
| | liquid 5 | | |
| Example 6 | Application | 215° C. | Good |
| | liquid 6 | | |
| Example 7 | Application | 215° C. | Good |
| | liquid 7 | | |
| Example 8 | Application | 215° C. | Good |
| | liquid 8 | | |
| Example 9 | Application | 215° C. | Good |
| | liquid 9 | | |
| Example 10 | Application | 215° C. | Good |
| | liquid 10 | | |
| Example 11 | Application | 215° C. | Good |
| | liquid 11 | | |
| Example 12 | Application | 215° C. | Good |
| | liquid 12 | | |
| Example 13 | Application | 215° C. | Good |
| | liquid 13 | | |
| Example 14 | Application | 120° C. | Good |
| | liquid 14 | | |
| Example 15 | Application | 120° C. | Good |
| | liquid 15 | | |
| Example 16 | Application | 120° C. | Good |
| | liquid 16 | | |
| Example 17 | Application | 120° C. | Good |
| | liquid 17 | | |
| Example 18 | Application | 120° C. | Good |
| | liquid 18 | | |
| Example 19 | Application | 215° C. | Good |
| | liquid 19 | | |
| Example 20 | Application | 120° C. | Good |
| | liquid 20 | | |
| Example 21 | Application | 215° C. | Good |
| | liquid 21 | | |
| Example 22 | Application | 120° C. | Good |
| | liquid 22 | | |
| Comparative | Comparative | 120° C. | Non-thinned |
| Example 1 | application | | |
| | liquid 1 | | |
| Comparative | Comparative | 215° C. | Non-uniformity |
| Example 2 | application | | in film |
| | liquid 2 | | thickness |
| Comparative | Comparative | 215° C. | Non-uniformity |
| Example 3 | application | | in film |
| | liquid 3 | | thickness |

In Comparative Examples 2 and 3, non-uniformity in film thickness was observed, and no surface-modified layer was formed.

### [3-2] Thinning Test

The prepared application liquids 101 to 108 and the comparative application liquid 101 were applied onto silicon wafers using a spinner. The resultant wafers were heated on a hot plate at each baking temperature described in Table 2-2 for 1 minute to form surface-modified layer precursors. Thereafter, a mixed solvent of propylene glycol monomethyl ether/propylene glycol monomethyl ether acetate (7/3 (V/V): thinning liquid) was applied onto each of the surface-modified layer precursors, and then spin-dried. The film thickness of each of the surface-modified layers after application of the thinning liquid was measured. The surface modifier in which the film thickness was reduced to 30 Å or less was evaluated as “good”, the surface modifier in which the film thickness was more than 30 Å and could not be thinned was evaluated as “not thinned”, and the surface modifier in which AFM observation showed non-uniformity in application evaluated as “non-uniformity in application”. The results are shown in Table 2-2.

TABLE 2-2

| | Application | Baking | Film |
|---|---|---|---|
| | liquid | temperature | formability |
| Example 101 | Application | 215° C. | Good |
| | liquid 101 | | |
| Example 102 | Application | 160° C. | Good |
| | liquid 102 | | |
| Example 103 | Application | 215° C. | Good |
| | liquid 103 | | |
| Example 104 | Application | 215° C. | Good |
| | liquid 104 | | |
| Example 105 | Application | 215° C. | Good |
| | liquid 105 | | |
| Example 106 | Application | 160° C. | Good |
| | liquid 106 | | |
| Example 107 | Application | 160° C. | Good |
| | liquid 107 | | |
| Example 108 | Application | 160° C. | Good |
| | liquid 108 | | |
| Comparative | Comparative | 215° C. | Non-thinned |
| Example 101 | application | | |
| | liquid 101 | | |

### [4] Substrate Surface Modification Property Test

Each of the application liquids 1 to 22 and 101 to 108 and the comparative application liquids 1, 2, and 101 was applied to a Bare-Si substrate. Specifically, 1 ml of each of the application liquids 1 to 22 and 101 to 108 and the comparative application liquids 1, 2, and 101 was applied to a wafer using CLEANTRACK (registered trademark) ACT8 (Tokyo Electron Ltd.), and the resultant wafer was spin-coated at 1500 rpm for 60 seconds, and then baked at each baking temperature described in Table 3-1 or Table 3-2. Thereafter, a mixed solvent of propylene glycol monomethyl ether/propylene glycol monomethyl ether acetate (7/3 (V/V)) was applied onto each of the surface-modified precursor layers, and then spin-dried to form surface-modified layers having a film thickness of 30 Å or less. After that, measurement was performed on the contact angle of water with respect to the Bare-Si substrate on which the surface-modified layer of each of the application liquids 1 to 22 and 101 to 108 and the comparative application liquids 1, 2, and 101 was formed. After liquid dropping in a volume of 3 μl, the dropping was stopped for 5 seconds, and then the water contact angle was measured in a constant temperature and humidity environment (23° C.±2° C., 45% RH±5%) using a fully automatic contact angle meter DM-701 (manufactured by Kyowa Interface Science Co., Ltd.). The water contact angle of the Bare-Si substrate was 20 degrees or less. Thus, a water contact angle of less than 30 degrees was determined as “poor” because the surface was not modified, and a water contact angle of 30 degrees or more was determined as “good” because the surface was modified. The measurement results are described in Table 3-1 and Table 3-2 below.

TABLE 3-1

| | | | | Surface |
|---|---|---|---|---|
| | | | | modification |
| | | | | property |
| | | | | (water contact |
| | | Application | Baking | angle: 30 |
| | Substrate | liquid | temperature | degrees or more) |
| Example 23 | Bare-Si | Application | 215° C. | Good |
| | | liquid 1 | | |
| Example 24 | Bare-Si | Application | 215° C. | Good |
| | | liquid 2 | | |
| Example 25 | Bare-Si | Application | 120° C. | Good |
| | | liquid 3 | | |
| Example 26 | Bare-Si | Application | 215° C. | Good |
| | | liquid 4 | | |
| Example 27 | Bare-Si | Application | 120° C. | Good |
| | | liquid 5 | | |
| Example 28 | Bare-Si | Application | 215° C. | Good |
| | | liquid 6 | | |
| Example 29 | Bare-Si | Application | 215° C. | Good |
| | | liquid 7 | | |
| Example 30 | Bare-Si | Application | 215° C. | Good |
| | | liquid 8 | | |
| Example 31 | Bare-Si | Application | 215° C. | Good |
| | | liquid 9 | | |
| Example 32 | Bare-Si | Application | 215° C. | Good |
| | | liquid 10 | | |
| Example 33 | Bare-Si | Application | 215° C. | Good |
| | | liquid 11 | | |
| Example 34 | Bare-Si | Application | 215° C. | Good |
| | | liquid 12 | | |
| Example 35 | Bare-Si | Application | 215° C. | Good |
| | | liquid 13 | | |
| Example 36 | Bare-Si | Application | 120° C. | Good |
| | | liquid 14 | | |
| Example 37 | Bare-Si | Application | 120° C. | Good |
| | | liquid 15 | | |
| Example 38 | Bare-Si | Application | 120° C. | Good |
| | | liquid 16 | | |
| Example 39 | Bare-Si | Application | 120° C. | Good |
| | | liquid 17 | | |
| Example 40 | Bare-Si | Application | 120° C. | Good |
| | | liquid 18 | | |
| Example 41 | Bare-Si | Application | 215° C. | Good |
| | | liquid 19 | | |
| Example 42 | Bare-Si | Application | 120° C. | Good |
| | | liquid 20 | | |
| Example 43 | Bare-Si | Application | 215° C. | Good |
| | | liquid 21 | | |
| Example 44 | Bare-Si | Application | 120° C. | Good |
| | | liquid 22 | | |
| Comparative | Bare-Si | Comparative | 120° C. | Poor |
| Example 4 | | application | | |
| | | liquid 1 | | |
| Comparative | Bare-Si | Comparative | 215° C. | Poor |
| Example 5 | | application | | |
| | | liquid 2 | | |

TABLE 3-2

| | | | | Surface |
|---|---|---|---|---|
| | | | | modification |
| | | | | property |
| | | | | (water contact |
| | | Application | Baking | angle: 30 |
| | Substrate | liquid | temperature | degrees or more) |
| Example 109 | Bare-Si | Application | 215° C. | Good |
| | | liquid 101 | | |
| Example 110 | Bare-Si | Application | 160° C. | Good |
| | | liquid 102 | | |
| Example 111 | Bare-Si | Application | 215° C. | Good |
| | | liquid 103 | | |
| Example 112 | Bare-Si | Application | 215° C. | Good |
| | | liquid 104 | | |
| Example 113 | Bare-Si | Application | 215° C. | Good |
| | | liquid 105 | | |
| Example 114 | Bare-Si | Application | 160° C. | Good |
| | | liquid 106 | | |
| Example 115 | Bare-Si | Application | 160° C. | Good |
| | | liquid 107 | | |
| Example 116 | Bare-Si | Application | 160° C. | Good |
| | | liquid 108 | | |
| Comparative | Bare-Si | Comparative | 120° C. | Poor |
| Example 102 | | application | | |
| | | liquid 101 | | |

### [5] Formation of Resist Pattern by EUV Exposure: Positive Solvent Development

Each Bare-Si substrate was spin-coated with the application liquid 1 and heated at 215° C. for 1 minute. Thereafter, a mixed solvent of propylene glycol monomethyl ether/propylene glycol monomethyl ether acetate (7/3 (V/V)) was applied onto the coated film, and spin-dried to form surface-modified layers (1 to 3 nm) having a film thickness of 30 Å or less.

Further, an EUV resist solution (methacrylate-PHS-based resist) was applied onto each of the surface-modified layers by spin coating, and heated at 110° C. for 1 minute to form an EUV resist layer (C). Thereafter, the EUV resist layer (C) was exposed to light by using an EUV exposure apparatus (NXE3400), manufactured by ASML, under the following conditions: NA=0.33, σ=0.63/0.84, and Quadropole.

After the light exposure, post exposure bake (PEB, at 105° C., for 1 minute) was performed, and then the resist layer was cooled on a cooling plate to room temperature, followed by development with a 2.38% TMAH developer for 30 seconds and rinsing treatment to form a resist pattern.

Similarly to the above procedure, a resist pattern was formed using a substrate having a surface-modified layer prepared from each of the application liquids 2 to 22 and 101 to 108 and the comparative application liquids 1, 2, and 101. Alternatively, as Comparative Example 8, a resist pattern was formed on a Bare-Si wafer to which no surface modifier was applied. The heating temperature (baking temperature) after spin-coating of each of the application liquids was set to each baking temperature shown in Table 4-1 or 4-2. In Example 67, a Si substrate on which SiON (50 nm) was formed was used as a substrate.

For each of the resultant patterns, whether or not a line pattern having a space of 14 nm and a pitch of 28 nm could be formed was evaluated by confirming the pattern shape observed by observation of the pattern cross-section.

In the observation of the pattern shape, a state in which the shape was found to be between a footing and an undercut and no significant residue was found in the space portion was evaluated as “good”, and an unfavorable state in which the resist pattern fell down was evaluated as “collapse”. The obtained results are shown in Tables 4-1 and 4-2.

TABLE 4-1

| | | Application | Baking | Resist pattern |
|---|---|---|---|---|
| | Substrate | liquid | temperature | shape |
| Example 45 | Bare-Si | Application | 215° C. | Good |
| | | liquid 1 | | |
| Example 46 | Bare-Si | Application | 215° C. | Good |
| | | liquid 2 | | |
| Example 47 | Bare-Si | Application | 120° C. | Good |
| | | liquid 3 | | |
| Example 48 | Bare-Si | Application | 215° C. | Good |
| | | liquid 4 | | |
| Example 49 | Bare-Si | Application | 120° C. | Good |
| | | liquid 5 | | |
| Example 50 | Bare-Si | Application | 215° C. | Good |
| | | liquid 6 | | |
| Example 51 | Bare-Si | Application | 215° C. | Good |
| | | liquid 7 | | |
| Example 52 | Bare-Si | Application | 215° C. | Good |
| | | liquid 8 | | |
| Example 53 | Bare-Si | Application | 215° C. | Good |
| | | liquid 9 | | |
| Example 54 | Bare-Si | Application | 215° C. | Good |
| | | liquid 10 | | |
| Example 55 | Bare-Si | Application | 215° C. | Good |
| | | liquid 11 | | |
| Example 56 | Bare-Si | Application | 215° C. | Good |
| | | liquid 12 | | |
| Example 57 | Bare-Si | Application | 215° C. | Good |
| | | liquid 13 | | |
| Example 58 | Bare-Si | Application | 120° C. | Good |
| | | liquid 14 | | |
| Example 59 | Bare-Si | Application | 120° C. | Good |
| | | liquid 15 | | |
| Example 60 | Bare-Si | Application | 120° C. | Good |
| | | liquid 16 | | |
| Example 61 | Bare-Si | Application | 120° C. | Good |
| | | liquid 17 | | |
| Example 62 | Bare-Si | Application | 120° C. | Good |
| | | liquid 18 | | |
| Example 63 | Bare-Si | Application | 215° C. | Good |
| | | liquid 19 | | |
| Example 64 | Bare-Si | Application | 120° C. | Good |
| | | liquid 20 | | |
| Example 65 | Bare-Si | Application | 215° C. | Good |
| | | liquid 21 | | |
| Example 66 | Bare-Si | Application | 120° C. | Good |
| | | liquid 22 | | |
| Example 67 | SiON | Application | 215° C. | Good |
| | | liquid 2 | | |
| Comparative | Bare-Si | Comparative | 120° C. | Fallen |
| Example 6 | | application | | |
| | | liquid 1 | | |
| Comparative | Bare-Si | Comparative | 215° C. | Collapse |
| Example 7 | | application | | |
| | | liquid 2 | | |
| Comparative | Bare-Si | Not | No bake | Collapse |
| Example 8 | | contained | | |

TABLE 4-2

| | | Application | Baking | Resist pattern |
|---|---|---|---|---|
| | Substrate | liquid | temperature | shape |
| Example 117 | Bare-Si | Application | 215° C. | Good |
| | | liquid 101 | | |
| Example 118 | Bare-Si | Application | 160° C. | Good |
| | | liquid 102 | | |
| Example 119 | Bare-Si | Application | 215° C. | Good |
| | | liquid 103 | | |
| Example 120 | Bare-Si | Application | 215° C. | Good |
| | | liquid 104 | | |
| Example 121 | Bare-Si | Application | 215° C. | Good |
| | | liquid 105 | | |
| Example 122 | Bare-Si | Application | 160° C. | Good |
| | | liquid 106 | | |
| Example 123 | Bare-Si | Application | 160° C. | Good |
| | | liquid 107 | | |
| Example 124 | Bare-Si | Application | 160° C. | Good |
| | | liquid 108 | | |

### [6] Formation of Resist Pattern by EUV Exposure: Metal Resist Negative Solvent Development

Each Bare-Si substrate was spin-coated with the application liquid 101 and heated at 215° C. for 1 minute. Thereafter, a mixed solvent of propylene glycol monomethyl ether/propylene glycol monomethyl ether acetate (7/3 (V/V)) was applied onto the coated film, and spin-dried to form surface-modified layers (1 to 3 nm) having a film thickness of 30 Å or less.

Further, an EUV metal resist solution (metal oxide-based resist) was applied onto each of the surface-modified layers by spin coating, and heated at 100° C. for 1 minute to form an EUV metal resist layer (C). Thereafter, the EUV metal resist layer (C) was exposed to light by using an EUV exposure apparatus (NXE3400), manufactured by ASML, under the following conditions: NA=0.33, σ=0.35/0.88, and Dipole 90X.

After the light exposure, post exposure bake (PEB, at 180° C., for 1 minute) was performed, and then the resist layer was cooled on a cooling plate to room temperature, followed by development with an organic solvent-based developer for 30 seconds, rinsing treatment, and baking at 250° C. for 60 seconds to form a resist pattern.

Similarly to the above procedure, a resist pattern was formed using a substrate having a surface-modified layer prepared from each of the application liquids 102 to 108 and the comparative application liquid 101. The heating temperature (baking temperature) after spin-coating of each of the application liquids was set to each baking temperature shown in Table 5.

For each of the resultant patterns, whether or not a line pattern having a space of 16 nm and a pitch of 32 nm could be formed was evaluated by confirming the pattern shape observed by observation of the pattern cross-section.

In the observation of the pattern shape, a state in which the shape was found to be between a footing and an undercut and no significant residue was found in the space portion was evaluated as “good”, and an unfavorable state in which the resist could not be applied well and holes were partially formed was evaluated as “pinholes”. The obtained results are shown in Table 5.

TABLE 5

| | | Application | Baking | Resist pattern |
|---|---|---|---|---|
| | Substrate | liquid | temperature | shape |
| Example 125 | Bare-Si | Application | 215° C. | Good |
| | | liquid 101 | | |
| Example 126 | Bare-Si | Application | 160° C. | Good |
| | | liquid 102 | | |
| Example 127 | Bare-Si | Application | 215° C. | Good |
| | | liquid 103 | | |
| Example 128 | Bare-Si | Application | 215° C. | Good |
| | | liquid 104 | | |
| Example 129 | Bare-Si | Application | 215° C. | Good |
| | | liquid 105 | | |
| Example 130 | Bare-Si | Application | 160° C. | Good |
| | | liquid 106 | | |
| Example 131 | Bare-Si | Application | 160° C. | Good |
| | | liquid 107 | | |
| Example 132 | Bare-Si | Application | 160° C. | Good |
| | | liquid 108 | | |
| Comparative | Bare-Si | Comparative | 215° C. | Pinholes |
| Example 103 | | application | | |
| | | liquid 101 | | |

1. A method for producing a laminate having a surface-modified layer and a semiconductor substrate,
the method comprising:
applying a surface modifier containing a polymer and a solvent to the semiconductor substrate, and then baking the semiconductor substrate to cross-link the polymer and to form a surface-modified layer precursor; and
bringing the surface-modified layer precursor into contact with a thinning liquid to thin the surface-modified layer precursor and to form a surface-modified layer having a film thickness of 5 nm or less.

2. The method for producing a laminate according to claim 1, wherein the polymer is a polysiloxane.

3. The method for producing a laminate according to claim 2, wherein the polysiloxane contains a modified polysiloxane in which at least some of silanol groups are alcohol-modified or acetal-protected.

4. The method for producing a laminate according to claim 2, wherein the polysiloxane contains at least one structure selected from a hydrocarbon group having 1 to 8 carbon atoms optionally substituted with a halogen atom, an aromatic ring having 6 to 30 carbon atoms optionally substituted with a halogen atom, an alkenyl group, an alkynyl group, a norbornene ring, a phenol group, a protected phenol group, an amino group, an amide group, a cyclic amide group, an imide group, a cyclic imide group, a sulfonyl group, a sulfonamide group, a nitro group, a cyano group, a thiocyanate group, an isocyanate group, a halogen group, a carboxylic acid group, a carboxylic acid ester group, a sulfonic acid group, a sulfonic acid ester group, a phosphoric acid group, a phosphoric acid ester group, an ammonium group, a phosphonium group, a sulfonium group, an epoxy group, a glycidoxy group, a cyclohexylepoxy group, a ring-opened epoxy group, a ring-opened glycidoxy group, a ring-opened cyclohexylepoxy group, a hydroxy group, a mercapto group, an acryloyloxy group, or a methacryloyloxy group.

5. The method for producing a laminate according to claim 2, wherein the polysiloxane contains a group bonded to a silicon atom and having an ionic bond.

6. The method for producing a laminate according to claim 5, wherein
the group having an ionic bond has an anionic group which is a group bonded to a silicon atom and a cation,
an anion in the anionic group is a sulfonate anion, a carboxylate anion, or a phosphate anion, and
the cation is a sulfonium cation, an iodonium cation, a phosphonium cation, a dihydroimidazole cation, or an ammonium cation.

7. The method for producing a laminate according to claim 5, wherein
the group having an ionic bond has a cationic group which is a group bonded to a silicon atom and an anion,
a cation in the cationic group is a sulfonium cation, an iodonium cation, a phosphonium cation, a dihydroimidazole cation, or an ammonium cation, and
the anion is a sulfonate anion, a carboxylate anion, or a phosphate anion.

8. The method for producing a laminate according to claim 2, wherein the polysiloxane contains a Q unit.

9. The method for producing a laminate according to claim 1, wherein the solvent contains at least one selected from the group consisting of alcohols, alkylene glycol alkyl ethers, alkylene glycol monoalkyl ether carboxylic acid esters, and water.

10. The method for producing a laminate according to claim 1, wherein the surface modifier contains an acid.

11. The method for producing a laminate according to claim 1, wherein the surface modifier contains an acid generator.

12. The method for producing a laminate according to claim 1, wherein the thinning liquid is at least one selected from the group consisting of an organic solvent, water, an acidic solution, an alkaline aqueous solution, and a thinner used in a reducing resist consumption (RRC) or an edge bead removing (EBR).

13. The method for producing a laminate according to claim 1, wherein the semiconductor substrate is a substrate of an inorganic or organic material or a substrate having a film of an inorganic or organic material.

14. The method for producing a laminate according to claim 13, wherein the inorganic material is at least one selected from the group consisting of a metal, a metal oxide, a metal nitride, a metal carbide, a metal oxynitride, a metal oxycarbide, and a metal carbonitride.

15. The method for producing a laminate according to claim 13, wherein the organic material is at least one selected from the group consisting of amorphous carbon, graphite, fullerene, carbon nanotube, diamond, diamond-like carbon, polyimide, and an organic film in which any one of them is doped or partially substituted with boron, oxygen, nitrogen, phosphorus, silicon, sulfur, or halogen.

16. The method for producing a laminate according to claim 1, wherein the laminate further includes a silicon-containing resist underlayer film.

17. The method for producing a laminate according to claim 1, wherein the bringing the surface-modified layer precursor into contact with a thinning liquid comprises spin-coating the surface-modified layer precursor with the thinning liquid.

18. The method for producing a laminate according to claim 1, wherein the bringing the surface-modified layer precursor into contact with a thinning liquid to thin the surface-modified layer precursor comprises thinning the surface-modified layer precursor together with an RRC or an EBR to form the surface-modified layer having the film thickness of 5 nm or less.

19. The method for producing a laminate according to claim 1, wherein the laminate is used in EUV lithography or electron beam lithography.

20. A method for producing a semiconductor element, comprising:
forming a resist film on the laminate formed by the method for producing a laminate according to claim 1; and
exposing and developing the resist film to form a resist pattern.

21. A laminate comprising:
a semiconductor substrate; and
a surface-modified layer containing a cross-linked polymer and having a film thickness of 5 nm or less.

22. The laminate according to claim 21, which is used in EUV lithography or electron beam lithography.

23. The laminate according to claim 21, wherein the polymer is a polysiloxane.

24. The laminate according to claim 23, wherein the polysiloxane contains a Q unit.

25. A surface modifier comprising: a polymer; and a solvent, wherein the surface modifier is used in the method for producing a laminate according to claim 1.
